(19) United States
(12) Patent Application Publication
(10) Pub. No.: US 2024/0251582 A1
(43) Pub. Date: Jul. 25, 2024

(54) ORGANOMETALLIC COMPOUND, LIGHT-EMITTING DEVICE INCLUDING THE ORGANOMETALLIC COMPOUND, AND ELECTRONIC APPARATUS INCLUDING THE LIGHT-EMITTING DEVICE

(71) Applicant: Samsung Display Co., Ltd., Yongin-si (KR)

(72) Inventors: Eunyoung Lee, Yongin-si (KR); Iljoon Kang, Yongin-si (KR); Sungbum Kim, Yongin-si (KR); Eunsoo Ahn, Yongin-si (KR); Jaesung Lee, Yongin-si (KR); Junghoon Han, Yongin-si (KR)

(73) Assignee: Samsung Display Co., Ltd., Yongin-si (KR)

(21) Appl. No.: 18/472,518

(22) Filed: Sep. 22, 2023

(30) Foreign Application Priority Data
Jan. 10, 2023 (KR) 10-2023-0003602

(51) Int. Cl. H10K 50/12; C07F 15/00; C09K 11/06; H10K 50/15; H10K 50/16; H10K 85/30

(52) U.S. Cl. CPC H10K 50/12; C07F 15/0086; C09K 11/06; H10K 50/15; H10K 50/16; H10K 85/346

(57) ABSTRACT

Embodiments provide an organometallic compound, a light-emitting device including the organometallic compound, and an electronic apparatus including the light-emitting device. The light-emitting device includes a first electrode, a second electrode facing the first electrode, an organic layer between the first electrode and the second electrode and comprising an emission layer, and at least one organometallic compound, which is represented by Formula 1, wherein Formula 1 is explained in the specification:

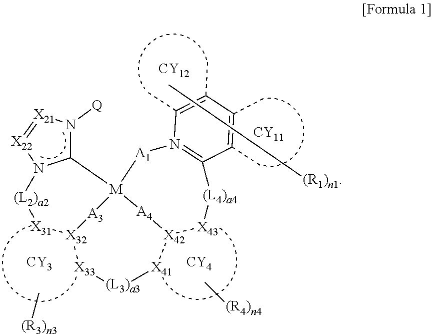

### CROSS-REFERENCE TO RELATED APPLICATION(S)

This application claims priority to and benefits of Korean Patent Application No. 10-2023-0003602 under 35 U.S.C. § 119, filed on Jan. 10, 2023, in the Korean Intellectual Property Office, the entire contents of which are incorporated herein by reference.

### BACKGROUND

### 1. Technical Field

Embodiments relate to an organometallic compound, a light-emitting device including the organometallic compound, and an electronic apparatus including the light-emitting device.

### 2. Description of the Related Art

Among light-emitting devices, organic light-emitting devices (OLEDs) are self-emission devices that, as compared with devices in the art, have wide viewing angles, high contrast ratios, short response times, and excellent characteristics in terms of brightness, driving voltage, and response speed.

OLEDs may include a first electrode on a substrate, and a hole transport region, an emission layer, an electron transport region, and a second electrode sequentially stacked on the first electrode. Holes provided from the first electrode may move toward the emission layer through the hole transport region, and electrons provided from the second electrode may move toward the emission layer through the electron transport region. Carriers, such as holes and electrons, recombine in the emission layer to produce excitons. These excitons transition from an excited state to a ground state, thereby generating light.

This is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments relate to a novel organometallic compound with excellent structural stability and improved color-coordinate. Embodiments relate to a light-emitting device including the organometallic compound and having high luminance, high efficiency, and long lifespan. Embodiments relate to a high-quality electronic apparatus including the light-emitting device.

Additional aspects will be set forth in part in the description which follows and, in part, will be apparent from the description, or may be learned by practice of the embodiments of the disclosure.

According to embodiments, a light-emitting device may include a first electrode, a second electrode facing the first electrode, an organic layer between the first electrode and the second electrode and including an emission layer, and at least one organometallic compound represented by Formula 1:

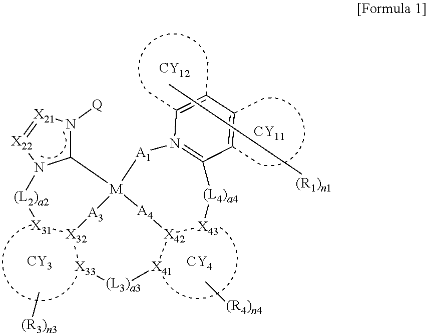

In Formula 1,

M may be a transition metal,

ring CY₁₁ and ring CY₁₂ may each independently be a C₆-C₆₀ aromatic ring or a C₁-C₆₀ heteroaromatic ring,

ring CY₃ and ring CY₄ may each independently be a C₆-C₆₀ carbocyclic group or a C₁-C₆₀ heterocyclic group,

A₁, A₃, and A₄ may each independently be a direct bond, O, or S,

L₂, L₃, and L₄ may each independently be a direct bond, O, or S,

a2, a3, and a4 may each independently be an integer from 1 to 4,

when L₂ is a direct bond, a2 may be 1; when L₃ is a direct bond, a3 may be 1; and when L₄ is a direct bond, a4 may be 1,

when a2 is 2 or greater, at least two L₂(s) may be identical to or different from each other; when a3 is 2 or greater, at least two L₃(s) may be identical to or different from each other; and when a4 is 2 or greater, at least two L₄(s) may be identical to or different from each other,

X₂₁ and X₂₂ may each independently be C(R) or N,

X₃₁, X₃₂, X₃₃, X₄₁, X₄₂, and X₄₃ may each independently be C or N,

R and Q may each independently be hydrogen, deuterium, —F, —Cl, —Br, —I, a hydroxyl group, a cyano group, a nitro group, a C₁-C₆₀ alkyl group unsubstituted or substituted with at least one R₂, a C₂-C₆₀ alkenyl group unsubstituted or substituted with at least one R₂, a C₂-C₆₀ alkynyl group unsubstituted or substituted with at least one R₂, a C₁-C₆₀ alkoxy group unsubstituted or substituted with at least one R₂, a C₃-C₆₀ carbocyclic group unsubstituted or substituted with at least one R₂, a C₁-C₆₀ heterocyclic group unsubstituted or substituted with at least one R₂, a C₆-C₆₀ aryloxy group unsubstituted or substituted with at least one R₂, a C₆-C₆₀ arylthio group unsubstituted or substituted with at least one R₂, a C₇-C₆₀ aryl alkyl group unsubstituted or substituted with at least one R₂, a C₂-C₆₀ heteroaryl alkyl group unsubstituted or substituted with at least one R₂,

R(s) may optionally be bound to each other to form a C₃-C₆₀ carbocyclic group unsubstituted or substituted with at least one R₂ or a C₁-C₆₀ heterocyclic group unsubstituted or substituted with at least one R₂,

R₁, R₂, R₃, and R₄ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ aryl alkyl group unsubstituted or substituted with at least one R₁₀ₐ, a C₂-C₆₀ heteroaryl alkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),

n1 may be an integer from 0 to 20,

when n1 is 2 or greater, at least two R₁(s) may be identical to or different from each other,

n3 and n4 may each independently be an integer from 0 to 10,

when n3 is 2 or greater, at least two R₃(s) may be identical to or different from each other,

when n4 is 2 or greater, at least two R₄(s) may be identical to or different from each other,

R₁₀ₐ may be:

deuterium, —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and

wherein Q₁ to Q₃, Q₁₁ to Q₁₃, Q₂₁ to Q₂₃, and Q₃₁ to Q₃₃ may each independently be:

hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group; or

a C₃-C₆₀ carbocyclic group, a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

In an embodiment, the emission layer may include the organometallic compound.

In an embodiment, the emission layer may include a host and a dopant, and the dopant may include the organometallic compound.

In an embodiment, the emission layer may emit light having a maximum emission wavelength in a range of about 490 nm to about 530 nm.

In an embodiment, the first electrode may be an anode; the second electrode may be a cathode; the organic layer may further include a hole transport region between the first electrode and the emission layer, and an electron transport region between the emission layer and the second electrode; the hole transport region may include a hole injection layer, a hole transport layer, an electron blocking layer, a buffer layer, or a combination thereof; and the electron transport region may include a hole blocking layer, an electron transport layer, an electron injection layer, or a combination thereof.

According to embodiments, an electronic apparatus may include the light-emitting device.

In an embodiment, the electronic apparatus may further include: a thin-film transistor; and a color filter, a color-conversion layer, a touchscreen layer, a polarizing layer, or a combination thereof, wherein the thin-film transistor may include a source electrode and a drain electrode; and the first electrode of the light-emitting device may be electrically connected to the source electrode or the drain electrode.

According to embodiments, an electronic equipment may include the light-emitting device, wherein the electronic equipment may be a flat panel display, a curved display, a computer monitor, a medical monitor, a television, an advertisement board, an indoor light, an outdoor light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a 3D display, a virtual reality display, an augmented reality display, a vehicle, a video wall comprising multiple displays tiled together, a theater screen, a stadium screen, a phototherapy device, or a sign.

According to embodiments, an organometallic compound may be represented by Formula 1, which is explained herein.

In an embodiment, M may be iridium (Ir), platinum (Pt), osmium (Os), titanium (Ti), zirconium (Zr), hafnium (Hf), europium (Eu), terbium (Tb), thulium (Tm), rhodium (Rh), palladium (Pd), or gold (Au).

In an embodiment, ring CY₁₁, ring CY₁₂, ring CY₃, and ring CY₄ may each independently be: a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzotriazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group.

In an embodiment, the organometallic compound may be represented by any one of Formulae 1-1 to 1-3, which are explained below.

In an embodiment, the organometallic compound may be represented by Formula 2, which is explained below.

In an embodiment, the organometallic compound may be represented by Formula 2-1, which is explained below.

In an embodiment, Q may be a moiety represented by

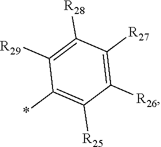

which is explained below.

In an embodiment, R₂₅ to R₂₉ may each independently be hydrogen, deuterium, a C₁-C₂₀ alkyl group unsubstituted or substituted with at least one R₁₀ₐ or a C₁-C₂₀ aryl group unsubstituted or substituted with at least one R₁₀ₐ.

In an embodiment, ring CY₃ may be a moiety represented by

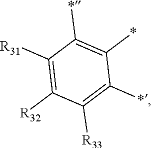

which is explained below.

In an embodiment, ring CY₄ may be a moiety represented by

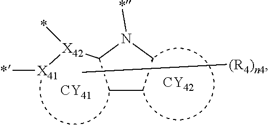

which is explained below.

In an embodiment, ring CY₄ may be a moiety represented by

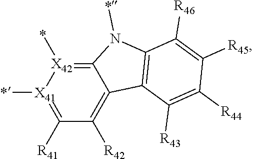

which is explained below.

In an embodiment, the organometallic compound may be one of Compounds 1 to 47, which are explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The above and other aspects, and features of the disclosure will be more apparent by describing in detail embodiments thereof with reference to the accompanying drawings, in which:

FIG. 1 is a schematic cross-sectional view of a light-emitting device according to an embodiment;

FIG. 2 is a schematic cross-sectional view of a light-emitting apparatus according to an embodiment;

FIG. 3 is a schematic cross-sectional view of a light-emitting apparatus according to an embodiment;

FIG. 4 is a schematic perspective view of an electronic equipment including the light-emitting device according to an embodiment;

FIG. 5 is a schematic view of an exterior of a vehicle as an electronic equipment including a light-emitting device according to an embodiment; and

FIGS. 6A to 6C are each a schematic diagram of an interior of a vehicle according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within +20%, 10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

According to embodiments, a light-emitting device may include: a first electrode; a second electrode facing the first electrode; an organic layer between the first electrode and the second electrode and including an emission layer; and at least one organometallic compound represented by Formula 1. Formula 1 will be described hereinafter.

In an embodiment, the emission layer may include the organometallic compound.

In an embodiment, the emission layer may include a host and a dopant, and the dopant may include the organometallic compound. For example, the organometallic compound may serve as a dopant.

In an embodiment, the emission layer may emit red light, green light, blue light, and/or white light. In embodiments, the emission layer may emit green light. The green light may have a maximum emission wavelength in a range of about 470 nanometers (nm) to about 550 nm. For example, the green light may have a maximum emission wavelength in a range of about 490 nm to about 540 nm. For example, the green light may have a maximum emission wavelength in a range of about 490 nm to about 530 nm. For example, the green light may have a maximum emission wavelength in a range of about 510 nm to about 530 nm.

In embodiments, the first electrode may be an anode; the second electrode may be a cathode; and the organic layer may further include a hole transport region between the first electrode and the emission layer, and an electron transport region between the emission layer and the second electrode; wherein the hole transport region may include a hole injection layer, a hole transport layer, an electron blocking layer, a buffer layer, or a combination thereof; and the electron transport region may include a hole blocking layer, an electron transport layer, an electron injection layer, or a combination thereof.

In embodiments, the light-emitting device may include a capping layer located outside the first electrode or outside the second electrode.

According to embodiments, an organometallic compound may be represented by Formula 1:

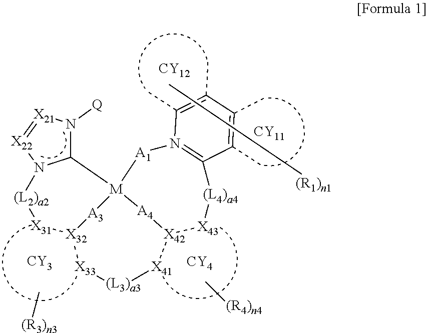

In Formula 1,

A₁, A₃, and A₄ may each independently be a direct bond, O, or S,

L₂, L₃, and L₄ may each independently be a direct bond, O, or S,

a2, a3, and a4 may each independently be an integer from 1 to 4,

when L₂ is a direct bond, a2 may be 1; when L₃ is a direct bond, a3 may be 1; and when L₄ is a direct bond, a4 may be 1, and

when a2 is 2 or greater, at least two L₂(s) may be identical to or different from each other; when a3 is 2 or greater, at least two L₃(s) may be identical to or different from each other; and when a4 is 2 or greater, at least two L₄(s) may be identical to or different from each other.

In Formula 1, M may be a transition metal.

In embodiments, M may be iridium (Ir), platinum (Pt), osmium (Os), titanium (Ti), zirconium (Zr), hafnium (Hf), europium (Eu), terbium (Tb), thulium (Tm), rhodium (Rh), palladium (Pd), or gold (Au).

In Formula 1, ring CY₁₁ and ring CY₁₂ may each independently be a C₆-C₆₀ aromatic ring or a C₁-C₆₀ heteroaromatic ring; and ring CY₃ and ring CY₄ may each independently be a C₆-C₆₀ carbocyclic group or a C₁-C₆₀ heterocyclic group.

In an embodiment, ring CY₃ and ring CY₄ may each independently be a C₆-C₃₀ aromatic ring or a C₁-C₃₀ heteroaromatic ring.

In an embodiment, ring CY₁₁, ring CY₁₂, ring CY₃, and ring CY₄ may each independently be a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzotriazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group.

In embodiments, ring CY₁₁ and ring CY₁₂ may each independently be a benzene group, a naphthalene group, an anthracene group, or a phenanthrene group.

In an embodiment, the organometallic compound may be represented by any one of Formulae 1-1 to 1-3:

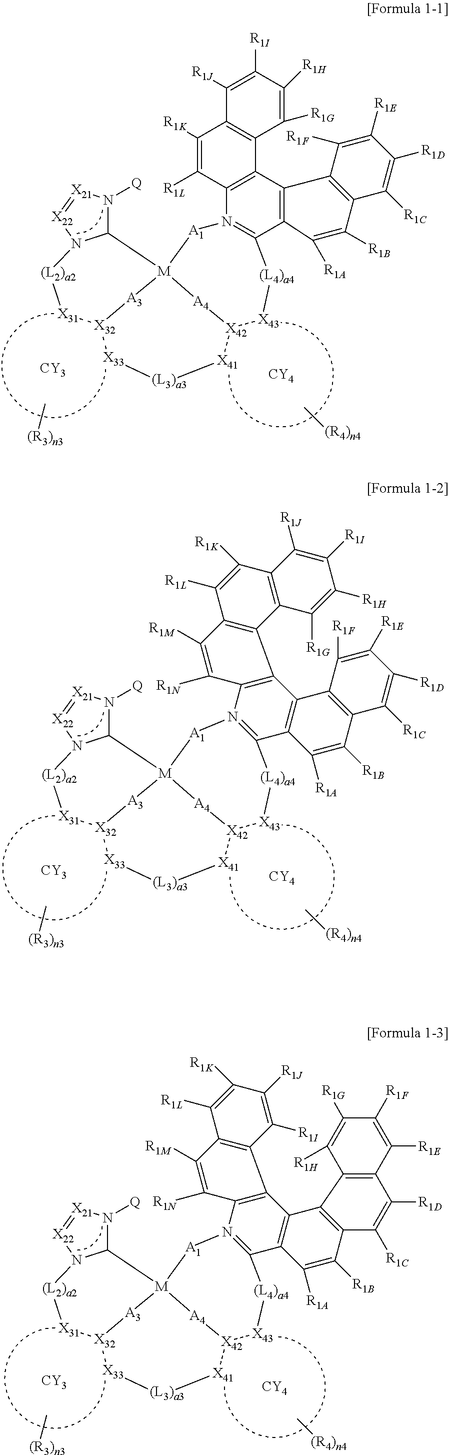

In Formulae 1-1 to 1-3,

M, ring CY₃, ring CY₄, A₁, A₃, A₄, L₂, L₃, L₄, a2, a3, a4, X₂₁, X₂₂, X₃₁, X₃₂, X₃₃, X₄₁, X₄₂, X₄₃, Q, R₃, R₄, n3, and n4 may each be as described herein, and

R_{1A} to R_{1N} may each independently be the same as defined in connection with R₁ described herein.

In Formula 1,

X₂₁ and X₂₂ may each independently be C(R) or N,

X₃₁, X₃₂, X₃₃, X₄₁, X₄₂, and X₄₃ may each independently be C or N,

R and Q may each independently be hydrogen, deuterium, —F, —Cl, —Br, —I, a hydroxyl group, a cyano group, a nitro group, a C₁-C₆₀ alkyl group unsubstituted or substituted with at least one R₂, a C₂-C₆₀ alkenyl group unsubstituted or substituted with at least one R₂, a C₂-C₆₀ alkynyl group unsubstituted or substituted with at least one R₂, a C₁-C₆₀ alkoxy group unsubstituted or substituted with at least one R₂, a C₃-C₆₀ carbocyclic group unsubstituted or substituted with at least one R₂, a C₁-C₆₀ heterocyclic group unsubstituted or substituted with at least one R₂, a C₁-C₆₀ aryloxy group unsubstituted or substituted with at least one R₂, a C₁-C₆₀ arylthio group unsubstituted or substituted with at least one R₂, a C₇-C₆₀ aryl alkyl group unsubstituted or substituted with at least one R₂, a C₂-C₆₀ heteroaryl alkyl group unsubstituted or substituted with at least one R₂,

R(s) may optionally be bound to each other to form a C₃-C₆₀ carbocyclic group unsubstituted or substituted with at least one R₂ or a C₁-C₆₀ heterocyclic group unsubstituted or substituted with at least one R₂,

R₁, R₂, R₃, and R₄ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ aryl alkyl group unsubstituted or substituted with at least one R₁₀ₐ, a C₂-C₆₀ heteroaryl alkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),

n1 may be an integer from 0 to 20,

when n1 is 2 or greater, at least two R₁(s) may be identical to or different from each other,

n3 and n4 may each independently be an integer from 0 to 10,

when n3 is 2 or greater, at least two R₃(s) may be identical to or different from each other,

when n4 is or greater, at least two R₄(s) may be identical to or different from each other,

R₁₀ₐ may be:

deuterium, —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and

wherein Q₁ to Q₃, Q₁₁ to Q₁₃, Q₂₁ to Q₂₃, and Q₃₁ to Q₃₃ may each independently be:

hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group; or

a C₃-C₆₀ carbocyclic group, a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

In an embodiment, X₃₁, X₃₂, X₃₃, X₄₁, and X₄₂ may each be C.

In an embodiment, X₄₃ may be N.

In an embodiment, X₂₁ and X₂₂ may each independently be C(R), and R(s) may form a C₅-C₃₀ aromatic ring unsubstituted or substituted with at least one R₂ or a C₁-C₃₀ heteroaromatic ring unsubstituted or substituted with at least one R₂.

In an embodiment, the organometallic compound may be represented by Formula 2:

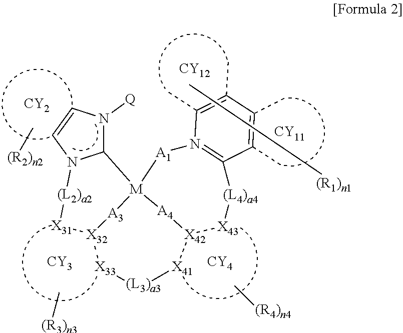

In Formula 2,

M, ring CY₁₁, ring CY₁₂, ring CY₃, ring CY₄, A₁, A₃, A₄, L₂, L₃, L₄, a2, a3, a4, X₃₁, X₃₂, X₃₃, X₄₁, X₄₂, X₄₃, Q, R₁, R₃, R₄, n1, n3, and n4 may each be as described herein,

ring CY₂ may be a C₆-C₃₀ aromatic ring or a C₁-C₃₀ heteroaromatic ring,

R₂ may be understood by referring to the description of R₂ provided herein, and

n2 may be an integer from 0 to 10.

In embodiments, in Formula 2, ring CY₂ may be a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzotriazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group.

In an embodiment, the organometallic compound may be represented by Formula 2-1:

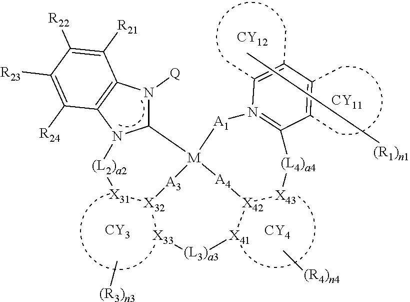

In Formula 2-1,

M, ring CY₁₁, ring CY₁₂, ring CY₃, ring CY₄, A₁, A₃, A₄, L₂, L₃, L₄, a2, a3, a4, X₃₁, X₃₂, X₃₃, X₄₁, X₄₂, X₄₃, Q, R₁, R₃, R₄, n1, n3, and n4 may be each as described herein, and

R₂₁ to R₂₄ may each independently be the same as defined in connection with R₂ described herein.

In an embodiment, Q may be a C₆-C₃₀ aryl group unsubstituted or substituted with at least one R₂ or a C₁-C₃₀ heteroaryl group unsubstituted or substituted with at least one R₂.

In an embodiment, Q may be a moiety represented by

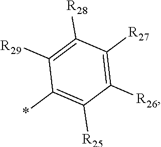

wherein R₂₅ to R₂₉ may each independently be the same as defined in connection with R₂ described herein, and * indicates a binding site to a nitrogen atom.

In an embodiment, R₂₅ to R₂₉ may each independently be hydrogen, deuterium, a C₁-C₂₀ alkyl group unsubstituted or substituted with at least one R₁₀ₐ or a C₁-C₂₀ aryl group unsubstituted or substituted with at least one R₁₀ₐ, wherein R₁₀ₐ is the same as described herein.

In an embodiment, ring CY₃ may be a moiety represented by

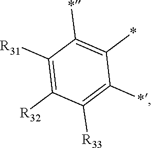

wherein R₃₁, R₃₂, and R₃₃ may each independently be the same as defined in connection with R₃ described herein, * indicates a binding site to A₃, *′ indicates a binding site to L₃, and *″ indicates a binding site to L₂.

For example, R₃₁, R₃₂, and R₃₃ may each independently be hydrogen, deuterium, a C₁-C₂₀ alkyl group unsubstituted or substituted with at least one R₁₀ₐ or a C₁-C₂₀ aryl group unsubstituted or substituted with at least one R₁₀ₐ.

In an embodiment, ring CY₄ may be a moiety represented by

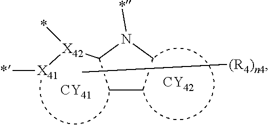

wherein R₄, n4, X₄₁, and X₄₂ may each be as described herein, ring CY₄₁ and ring CY₄₂ may each independently be a C₆-C₃₀ aromatic ring or a C₁-C₃₀ heteroaromatic ring, *′ indicates a binding site to A₄, indicates a binding site to L₃, and *″ indicates a binding site to L₄.

In an embodiment, ring CY₄ may be a moiety represented by

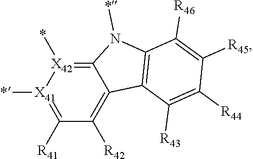

wherein X₄₁ and X₄₂ may each be as described herein, R₄₁ to R₄₆ may each independently be the same as defined in connection with R₄ described herein, * indicates a binding site to A₄, *′ indicates a binding site to L₃, and *″ indicates a binding site to L₄.

In an embodiment, the organometallic compound may be one of Compounds 1 to 47:

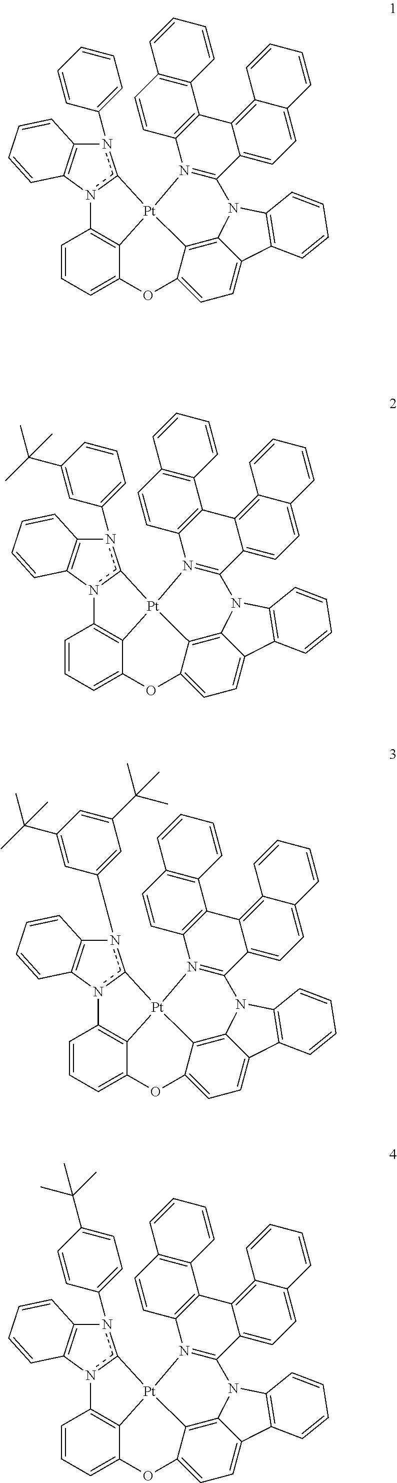

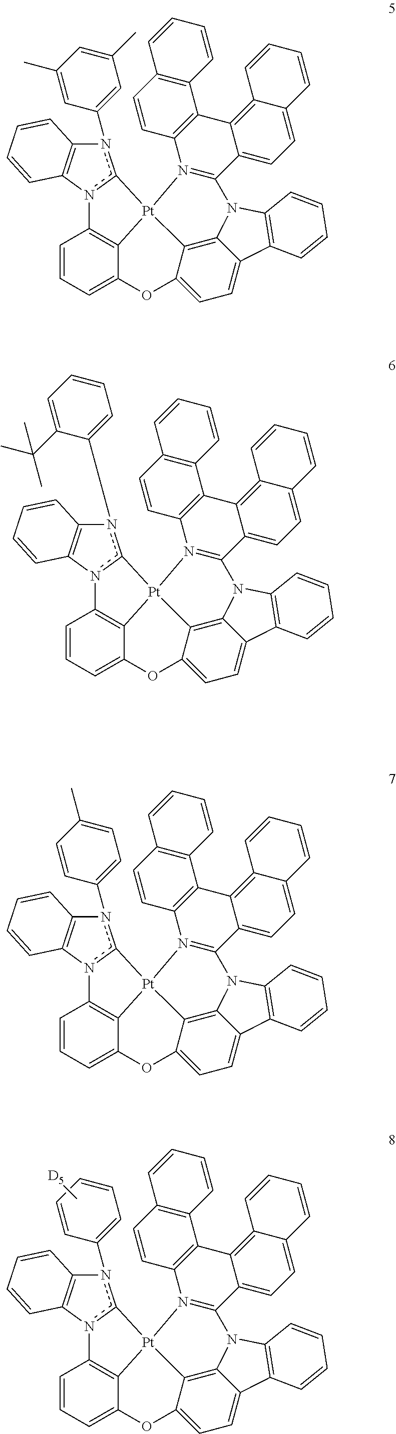

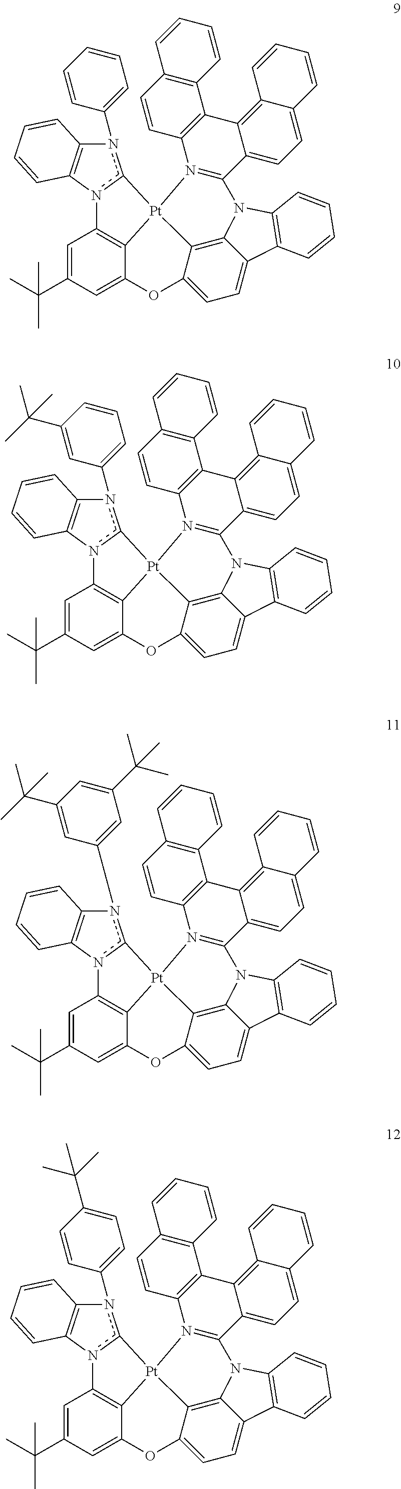

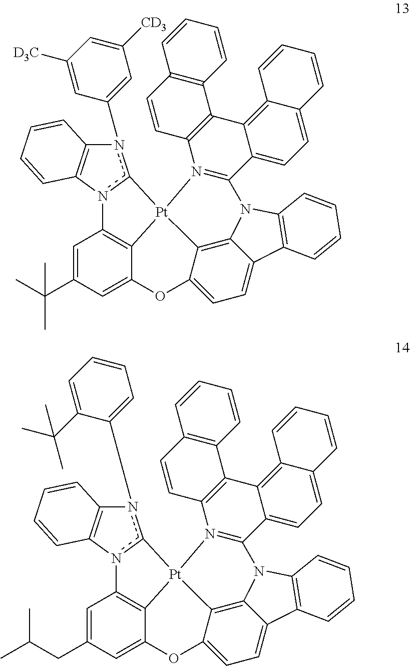

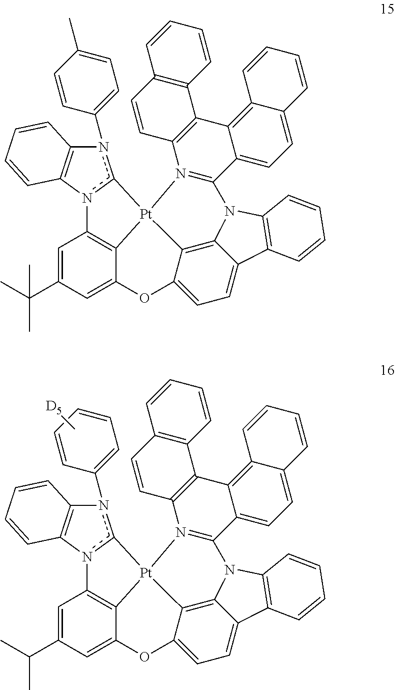

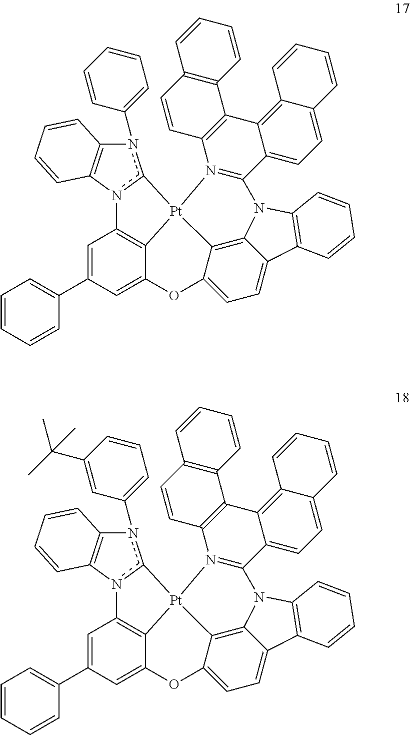

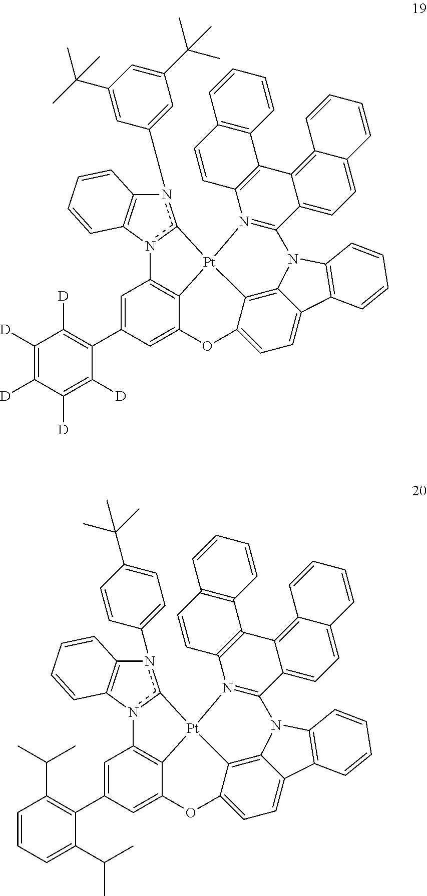

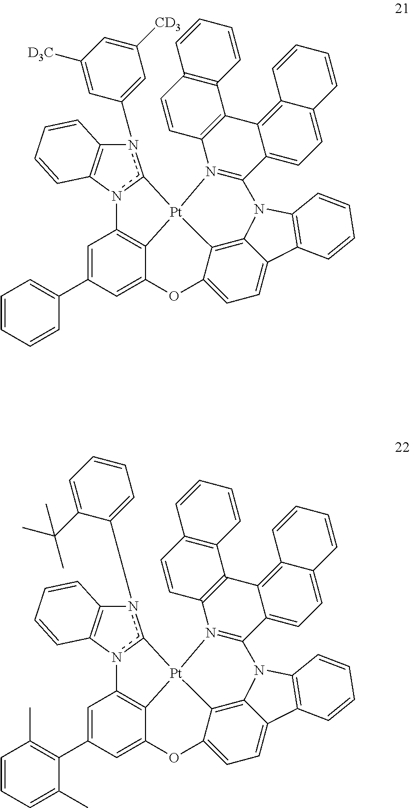

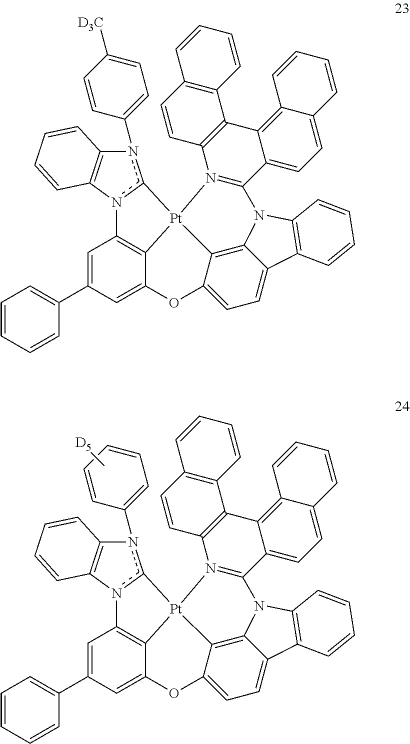

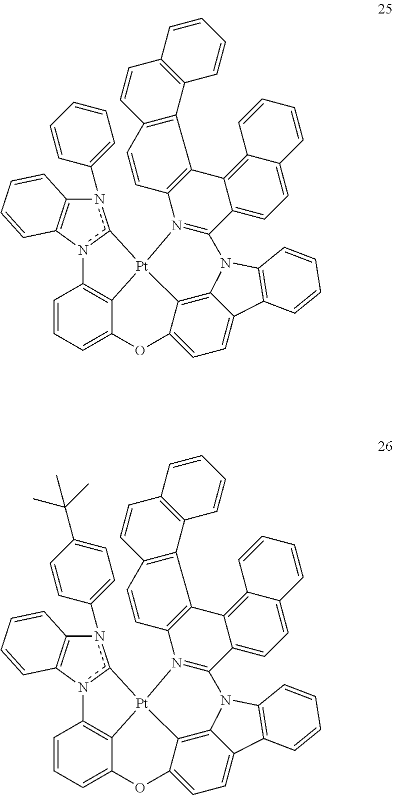

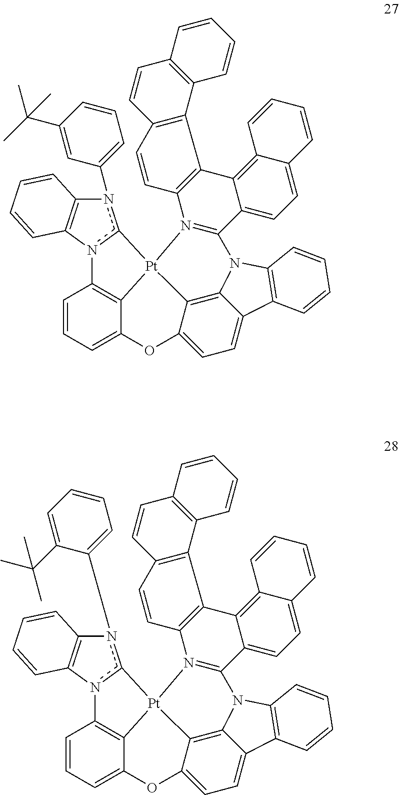

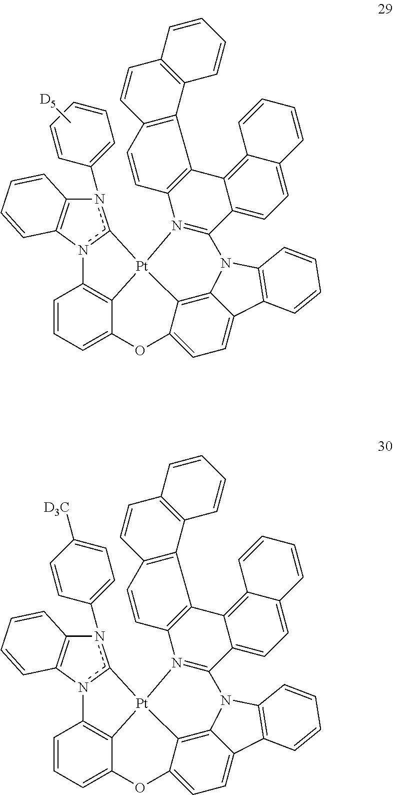

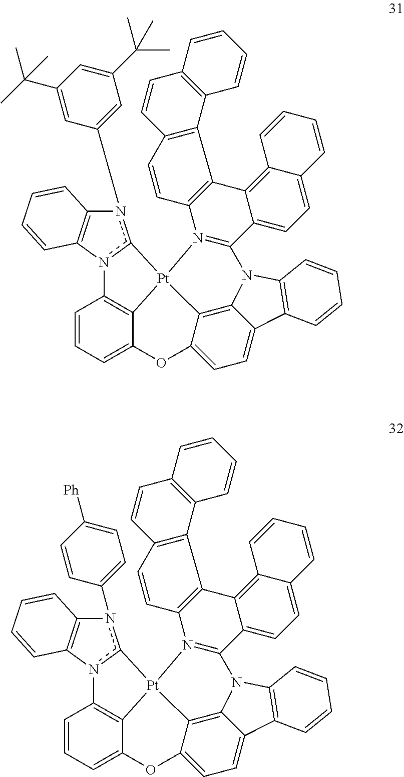

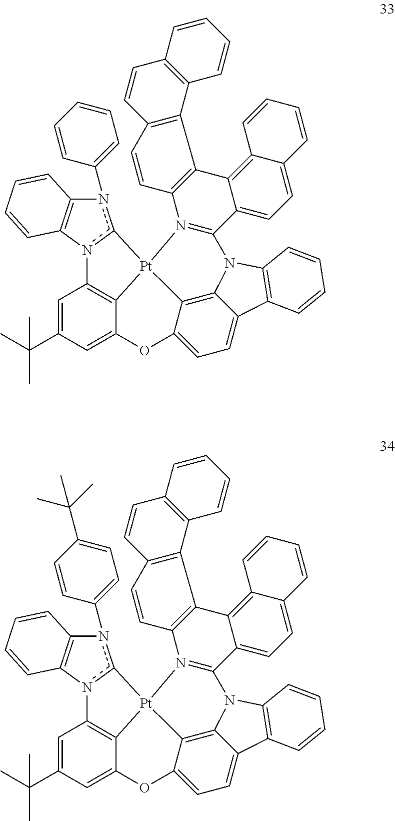

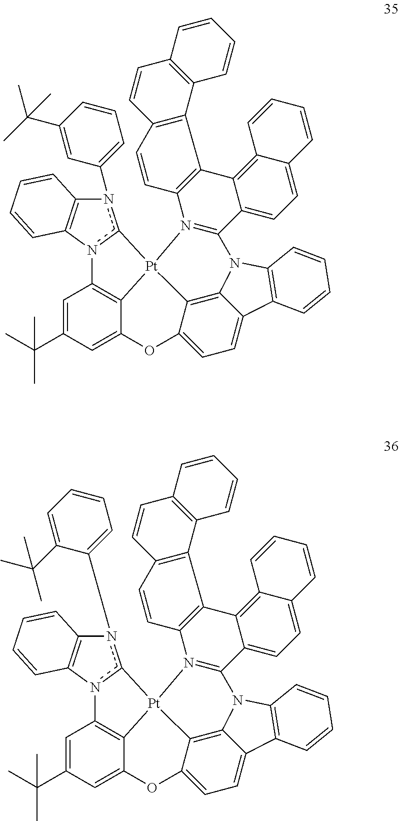

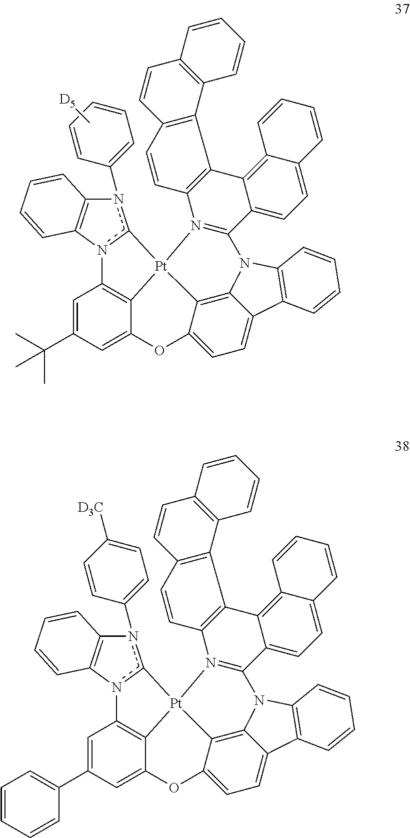

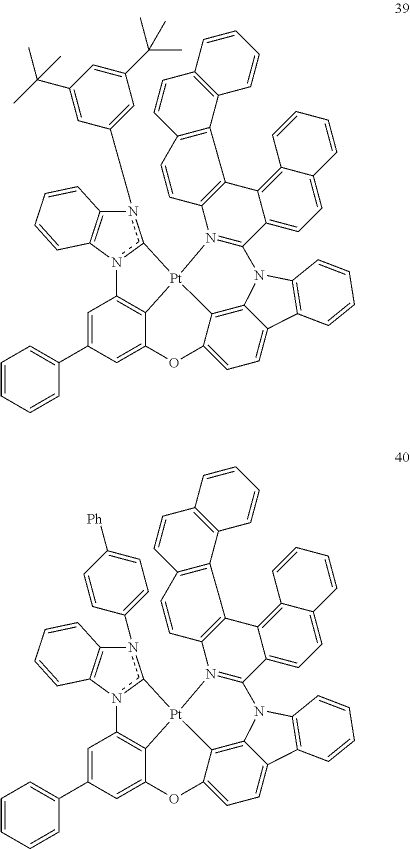

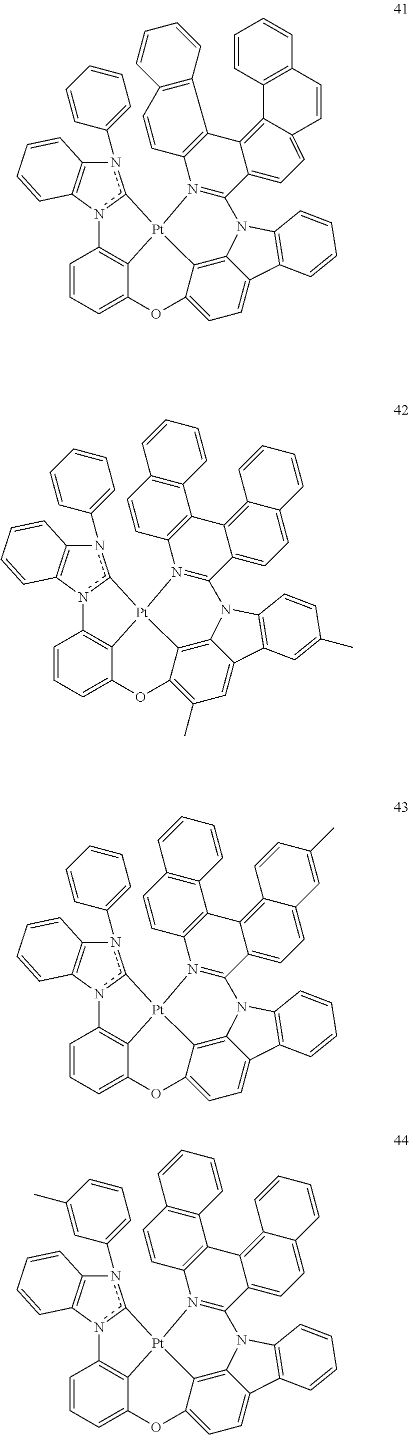

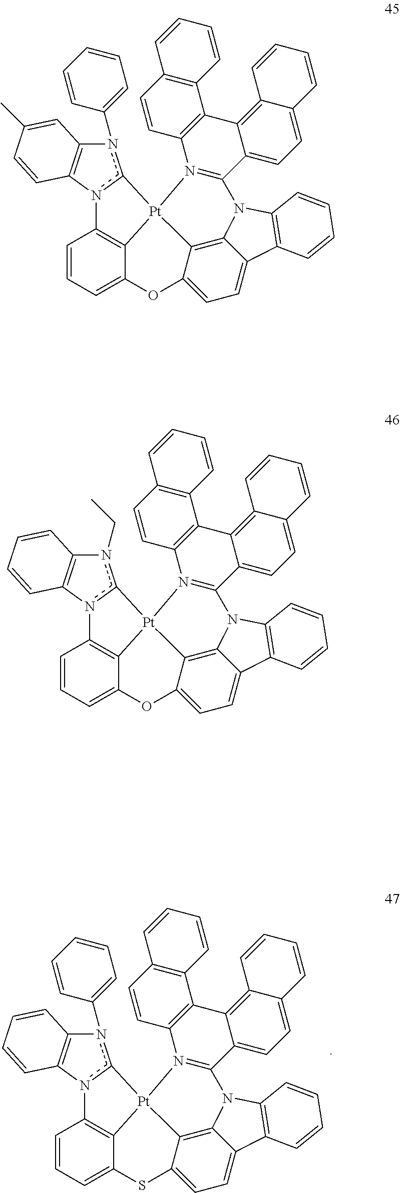

By introducing a bulky substituent to a lowest unoccupied molecular orbital (LUMO) of the organometallic compound represented by Formula 1, color-coordinate may be improved to emit green light having a relatively long wavelength, and structural stability of the compound may be secured.

Thus, a light-emitting device including the organometallic compound may have high luminance, excellent luminescence efficiency, and long lifespan characteristics.

Methods of synthesizing the organometallic compound represented by Formula 1 may be readily understood to those of ordinary skill in the art by referring to Synthesis Examples and Examples described herein.

The term “interlayer” as used herein refers to a single layer and/or all layers located between a first electrode and a second electrode in a light-emitting device.

According to an embodiment, an electronic apparatus may include the organic light-emitting device. The electronic apparatus may further include a thin-film transistor. In embodiments, the electronic apparatus may further include a thin-film transistor including a source electrode and drain electrode, and a first electrode of the light-emitting device may be electrically connected to the source electrode or the drain electrode. In an embodiment, the electronic apparatus may further include a color filter, a color-conversion layer, a touchscreen layer, a polarizing layer, or any combination thereof. The electronic apparatus may be understood by referring to the description of the electronic apparatus provided herein.

According to an embodiment, the electronic equipment may be a flat panel display, a curved display, a computer monitor, a medical monitor, a television, an advertisement board, an indoor light, an outdoor light, a signaling light, a head-up display, a fully transparent display, a partially transparent display, a flexible display, a rollable display, a foldable display, a stretchable display, a laser printer, a telephone, a cell phone, a tablet, a phablet, a personal digital assistant (PDAs), a wearable device, a laptop computer, a digital camera, a camcorder, a viewfinder, a microdisplay, a 3D display, a virtual reality display, an augmented reality displays, a vehicle, a video wall including multiple displays tiled together, a theater screen, a stadium screen, a phototherapy device, or a sign.

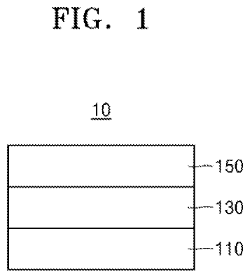

### [Description of FIG. 1]

FIG. 1 is a schematic cross-sectional view of a light-emitting device 10 according to an embodiment. The light-emitting device 10 may include a first electrode 110, an interlayer 130, and a second electrode 150.

Hereinafter, the structure of the light-emitting device 10 according to an embodiment and a method of manufacturing the light-emitting device 10 according to an embodiment will be described in connection with FIG. 1.

### [First Electrode 110]

In FIG. 1, a substrate may be further included under the first electrode 110 or above the second electrode 150. The substrate may be a glass substrate or a plastic substrate. The substrate may be a flexible substrate including plastic having excellent heat resistance and durability, for example, polyimide, polyethylene terephthalate (PET), polycarbonate, polyethylene naphthalate, polyarylate (PAR), polyetherimide, or any combination thereof.

The first electrode 110 may be formed by depositing or sputtering, on the substrate, a material for forming the first electrode 110. In case that the first electrode 110 is an anode, a high work function material that may readily inject holes may be used as a material for a first electrode.

The first electrode 110 may be a reflective electrode, a semi-transmissive electrode, or a transmissive electrode. In case that the first electrode 110 is a transmissive electrode, a material for forming the first electrode 110 may be indium tin oxide (ITO), indium zinc oxide (IZO), tin oxide (SnO₂), zinc oxide (ZnO), or any combination thereof. In embodiments, in case that the first electrode 110 is a semi-transmissive electrode or a reflective electrode, magnesium (Mg), silver (Ag), aluminum (Al), aluminum-lithium (Al—Li), calcium (Ca), magnesium-indium (Mg—In), magnesium-silver (Mg—Ag), or any combination thereof may be used as a material for forming the first electrode 110.

The first electrode 110 may have a structure consisting of a single layer or a structure including two or more layers. In embodiments, the first electrode 110 may have a triple-layered structure of ITO/Ag/ITO.

### [Interlayer 130]

The interlayer 130 may be on the first electrode 110. The interlayer 130 may include an emission layer.

The interlayer 130 may further include a hole transport region between the first electrode 110 and the emission layer, and an electron transport region between the emission layer and the second electrode 150.

The interlayer 130 may further include metal-containing compounds such as organometallic compounds, inorganic materials such as quantum dots, and the like, in addition to various organic materials.

In an embodiment, the interlayer 130 may include at least two emitting units stacked between the first electrode 110 and the second electrode 150; and at least one charge generation layer located between the at least two emitting units. In case that the interlayer 130 includes the at least two emitting units and the at least one charge generation layer, the light-emitting device 10 may be a tandem light-emitting device.

### [Hole Transport Region in Interlayer 130]

The hole transport region may have a structure consisting of a layer consisting of a single material, a structure consisting of a layer including different materials, or a structure having multiple layers including different materials.

The hole transport region may include a hole injection layer, a hole transport layer, an emission auxiliary layer, an electron blocking layer, or a combination thereof.

For example, the hole transport region may have a multi-layered structure, e.g., a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein the layers of each structure may be stacked on the first electrode 110 in its respective stated order, but the structure of the hole transport region is not limited thereto.

The hole transport region may include the compound represented by Formula 201, the compound represented by Formula 202, or any combination thereof:

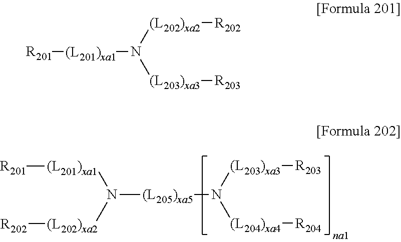

In Formulae 201 and 202,

L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,

xa1 to xa4 may each independently be an integer from 0 to 5,

xa5 may be an integer from 1 to 10,

R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

R₂₀₁ and R₂₀₂ may optionally be bound to each other via a single bond, a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group (e.g., a carbazole group or the like) unsubstituted or substituted with at least one R₁₀ₐ (e.g., Compound HT16 described herein),

R₂₀₃ and R₂₀₄ may optionally be bound to each other via a single bond, a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group unsubstituted or substituted with at least one R₁₀ₐ, and

na1 may be an integer from 1 to 4.

In embodiments, the compound represented Formula 201 and the compound represented Formula 202 may each independently include at least one of groups represented by Formulae CY201 to CY217:

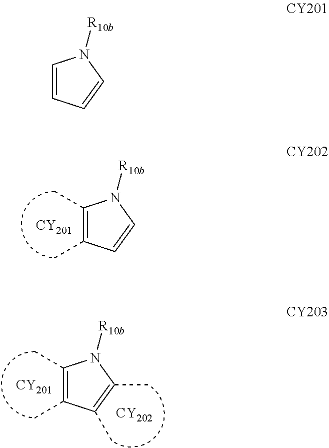

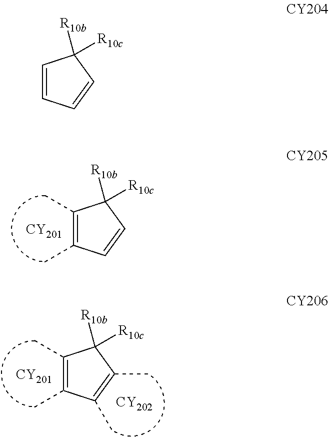

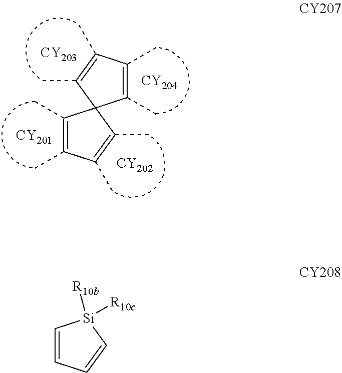

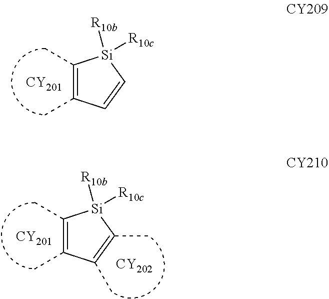

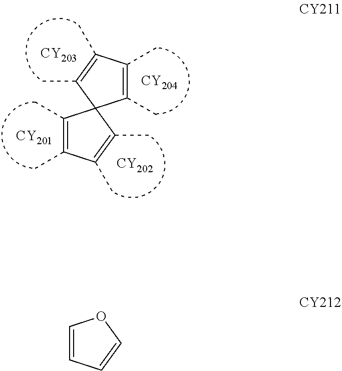

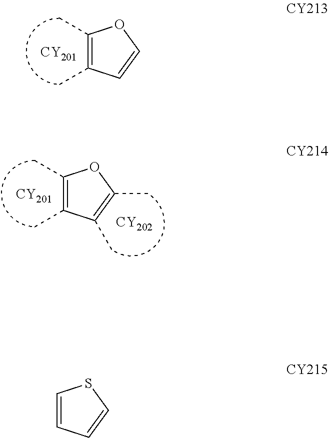

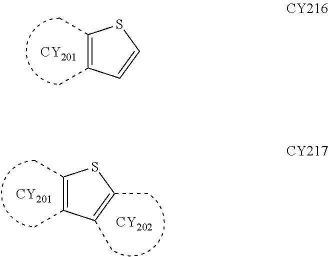

In Formulae CY201 to CY217, R_{10b} and R_{10c} may each independently be as defined in connection with R₁₀ₐ in the specification, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In an embodiment, in Formulae CY201 to CY217, ring CY₂₀₁ to ring CY₂₀₄ may each independently be a benzene group, a naphthalene group, a phenanthrene group, or an anthracene group.

In embodiments, the compound represented by Formula 201 and the compound represented by Formula 202 may each include at least one of groups represented by Formulae CY201 to CY203.

In embodiments, the compound represented by Formula 201 may include at least one of groups represented by Formulae CY201 to CY203 and at least one of groups represented by Formulae CY204 to CY217.

In embodiments, in Formula 201, xa1 may be 1, R₂₀₁ may be represented by one of Formulae CY201 to CY203, xa2 may be 0, and R₂₀₂ may be represented by one of Formulae CY204 to CY207.

In embodiments, the compound represented by Formula 201 and the compound represented by Formula 202 may each not include groups represented by Formulae CY201 to CY203.

In embodiments, the compound represented by Formula 201 and the compound represented by Formula 202 may each not include groups represented by Formulae CY201 to CY203, and include at least one of groups represented by Formulae CY204 to CY217.

In embodiments, the compound represented by Formula 201 and the compound represented by Formula 202 may each not include groups represented by Formulae CY201 to CY217.

In embodiments, the hole transport region may include one of Compounds HT1 to HT46 and m-MTDATA, TDATA, 2-TNATA, NPB (NPD), β-NPB, TPD, spiro-TPD, spiro-NPB, methylated-NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphorsulfonic acid (PANI/CSA), polyaniline/poly(4-styrenesulfonate (PANI/PSS), or any combination thereof:

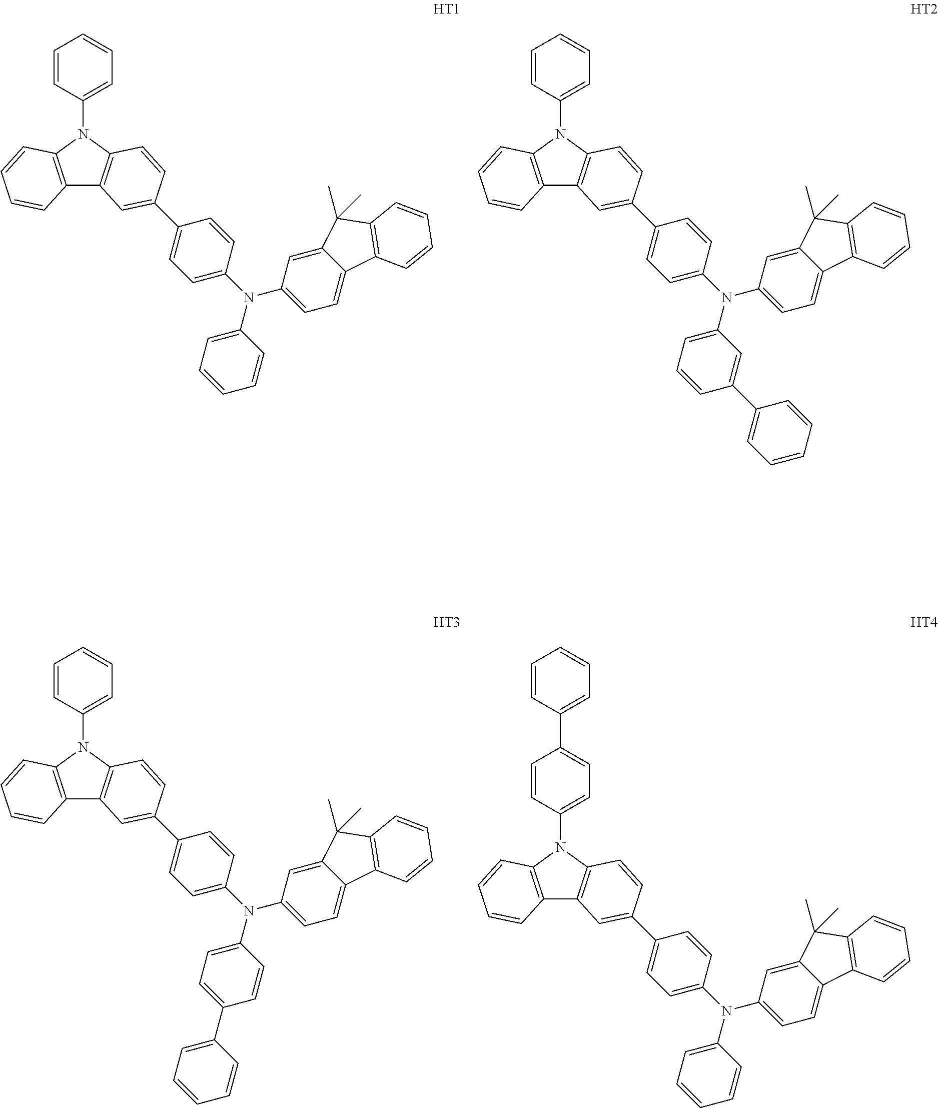 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

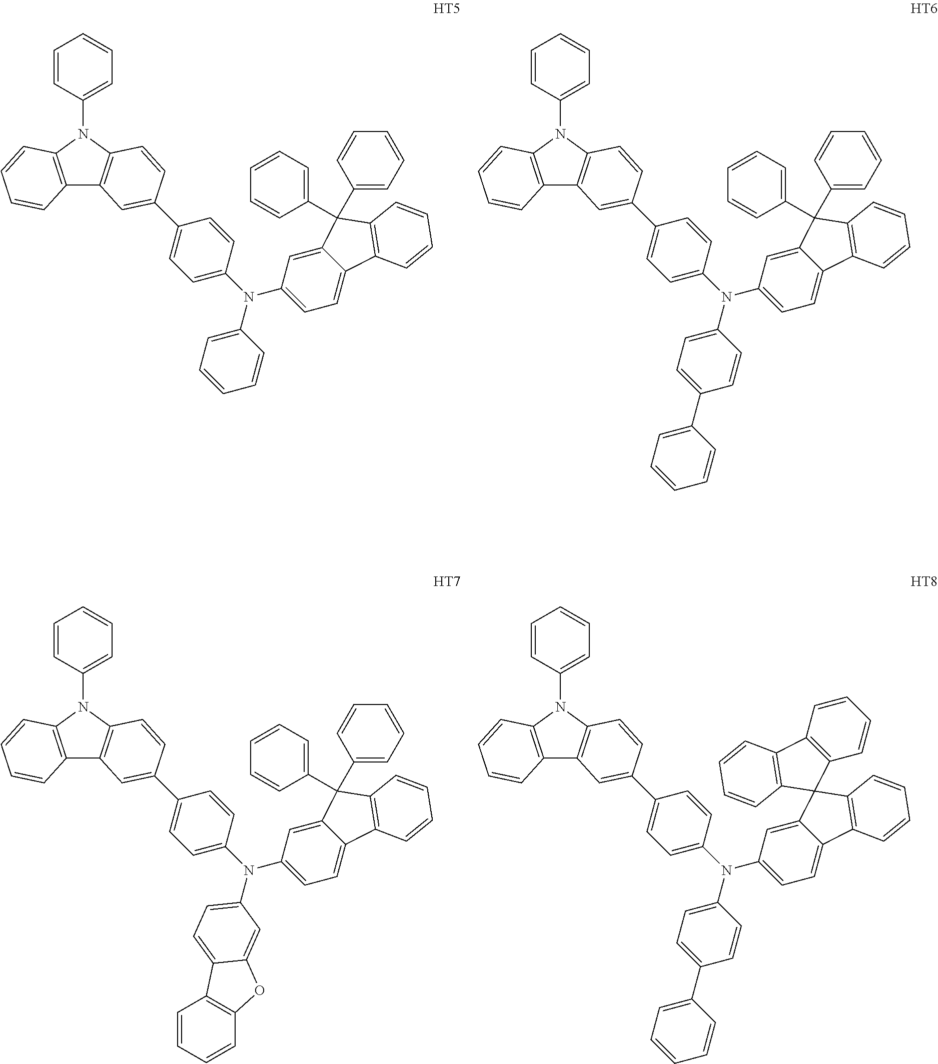 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

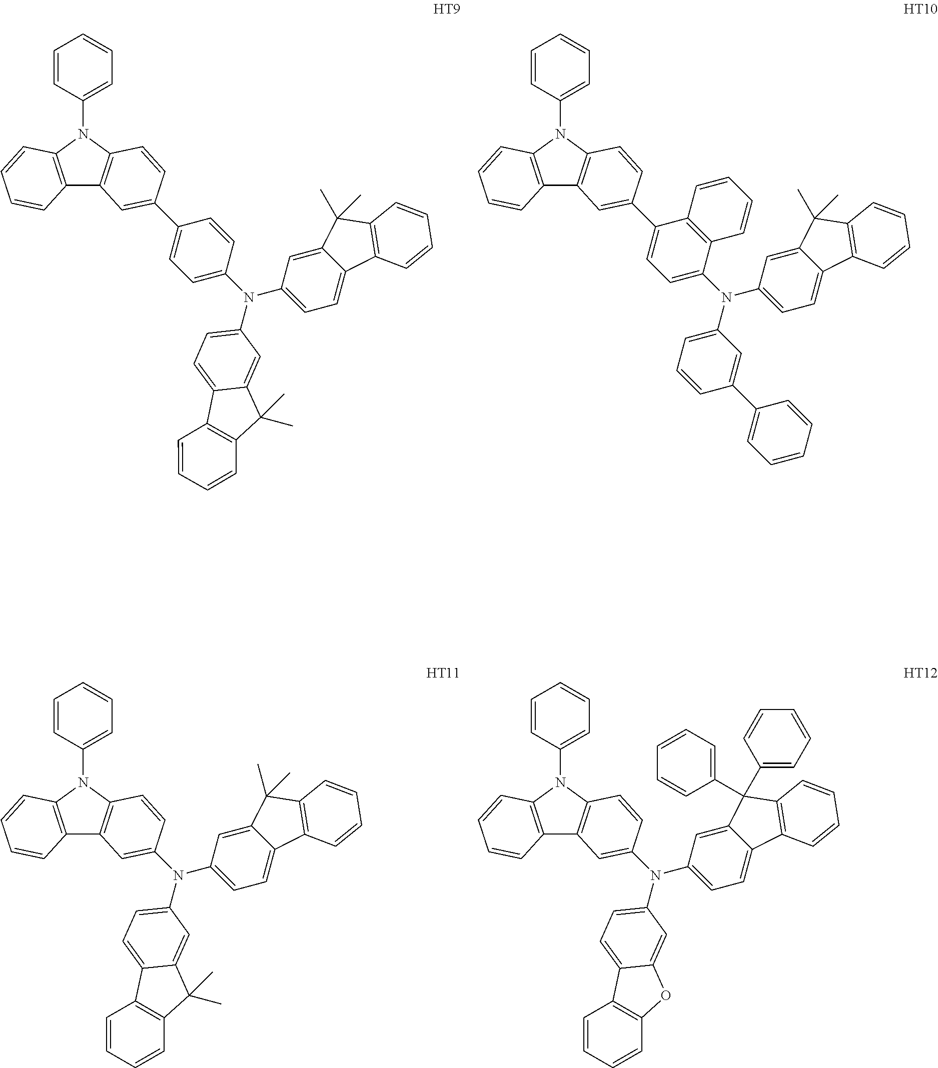 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

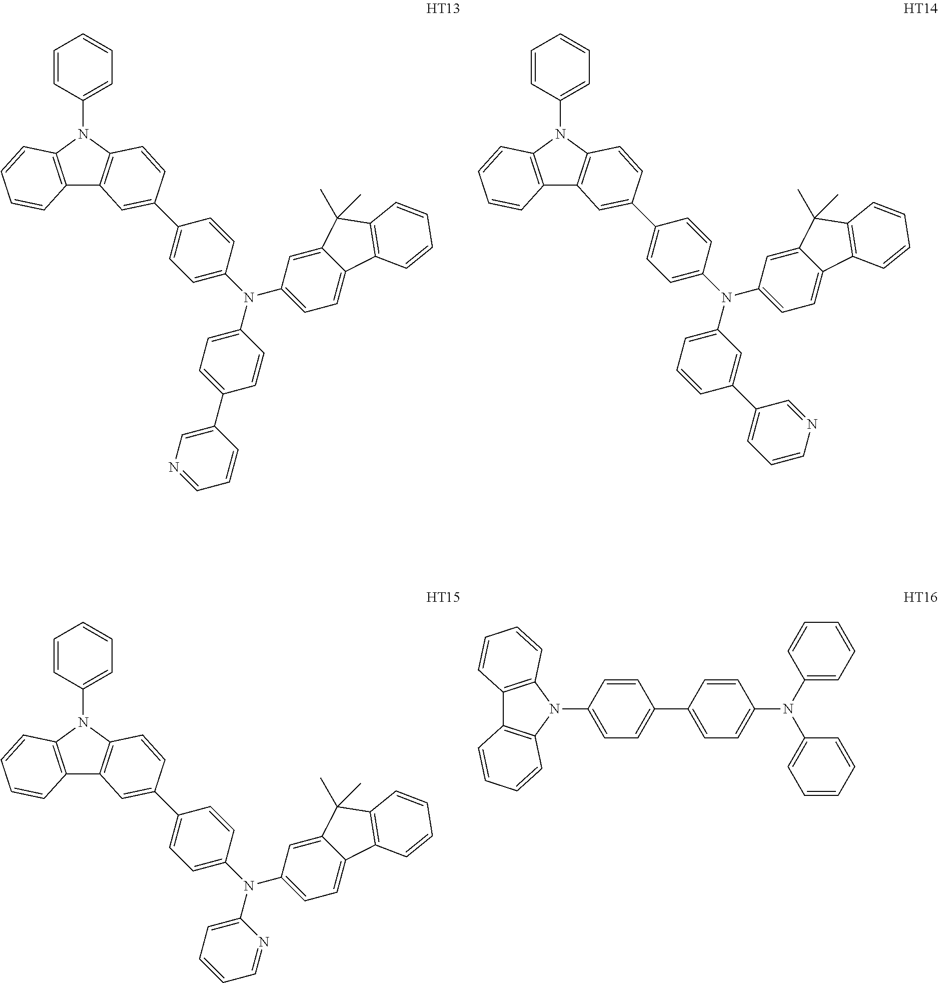 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1]

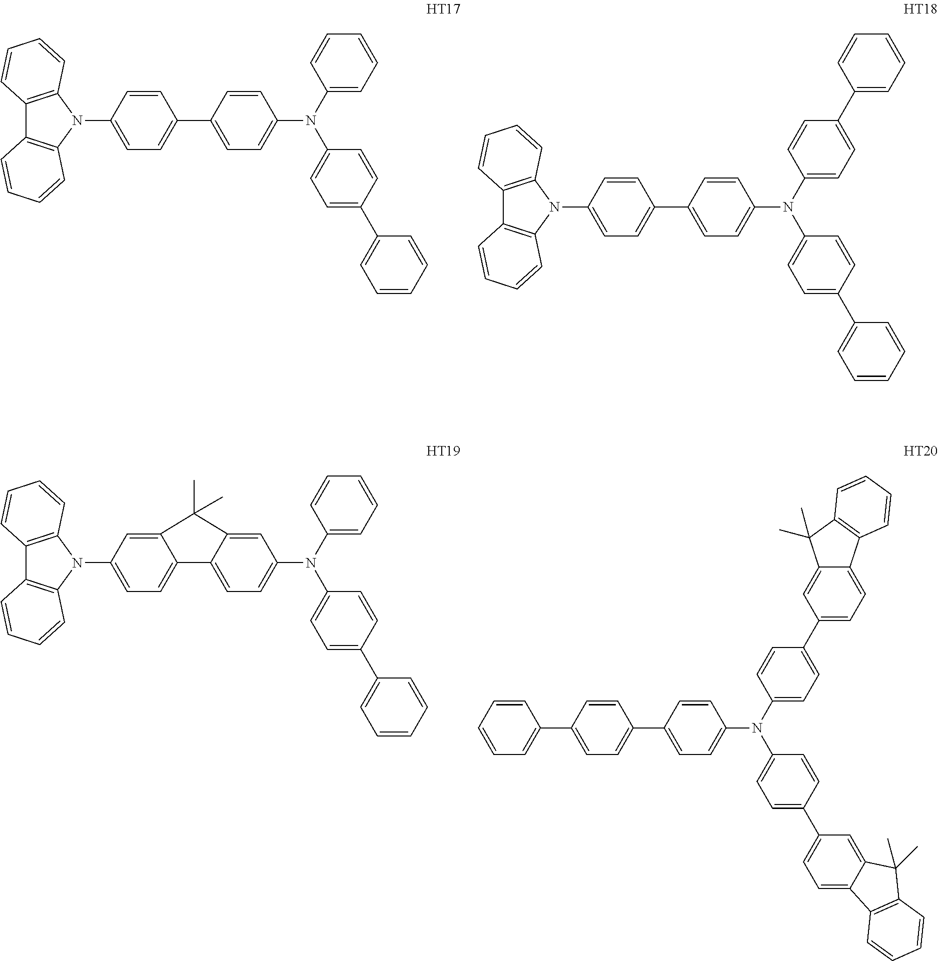 [SMILES: c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21]

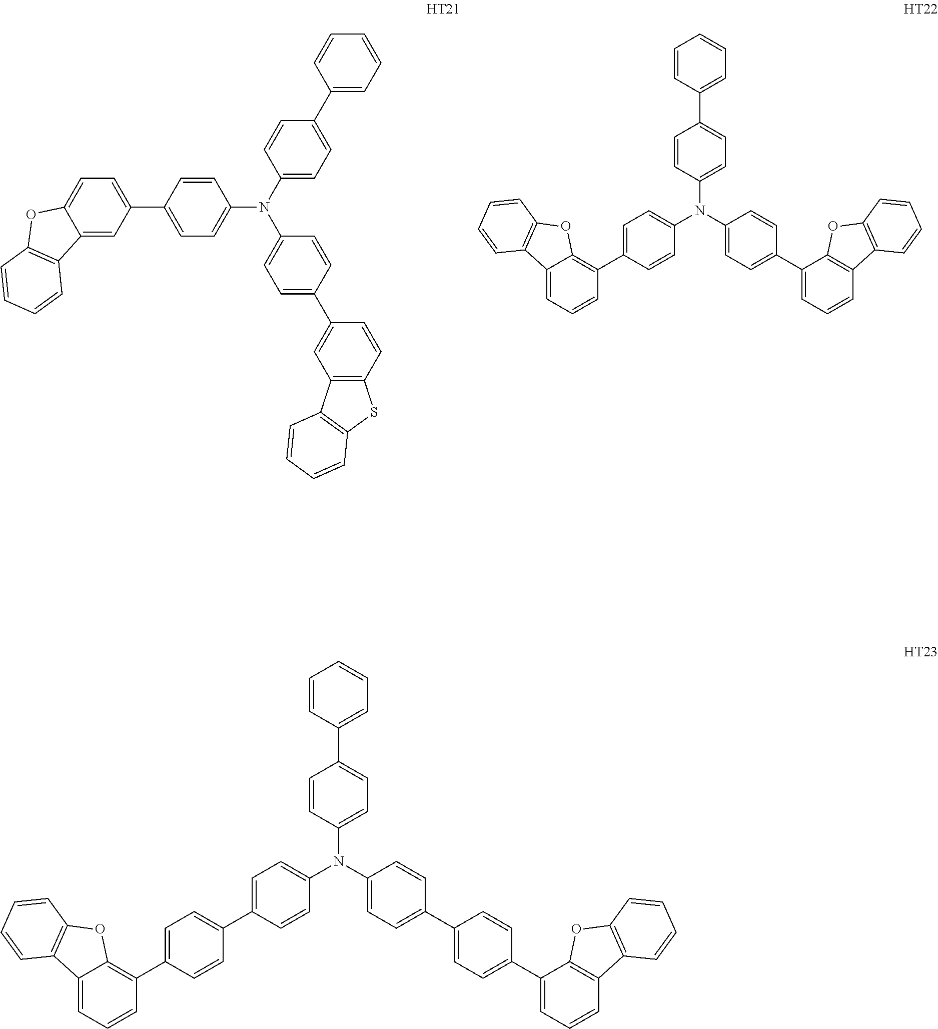 [SMILES: c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

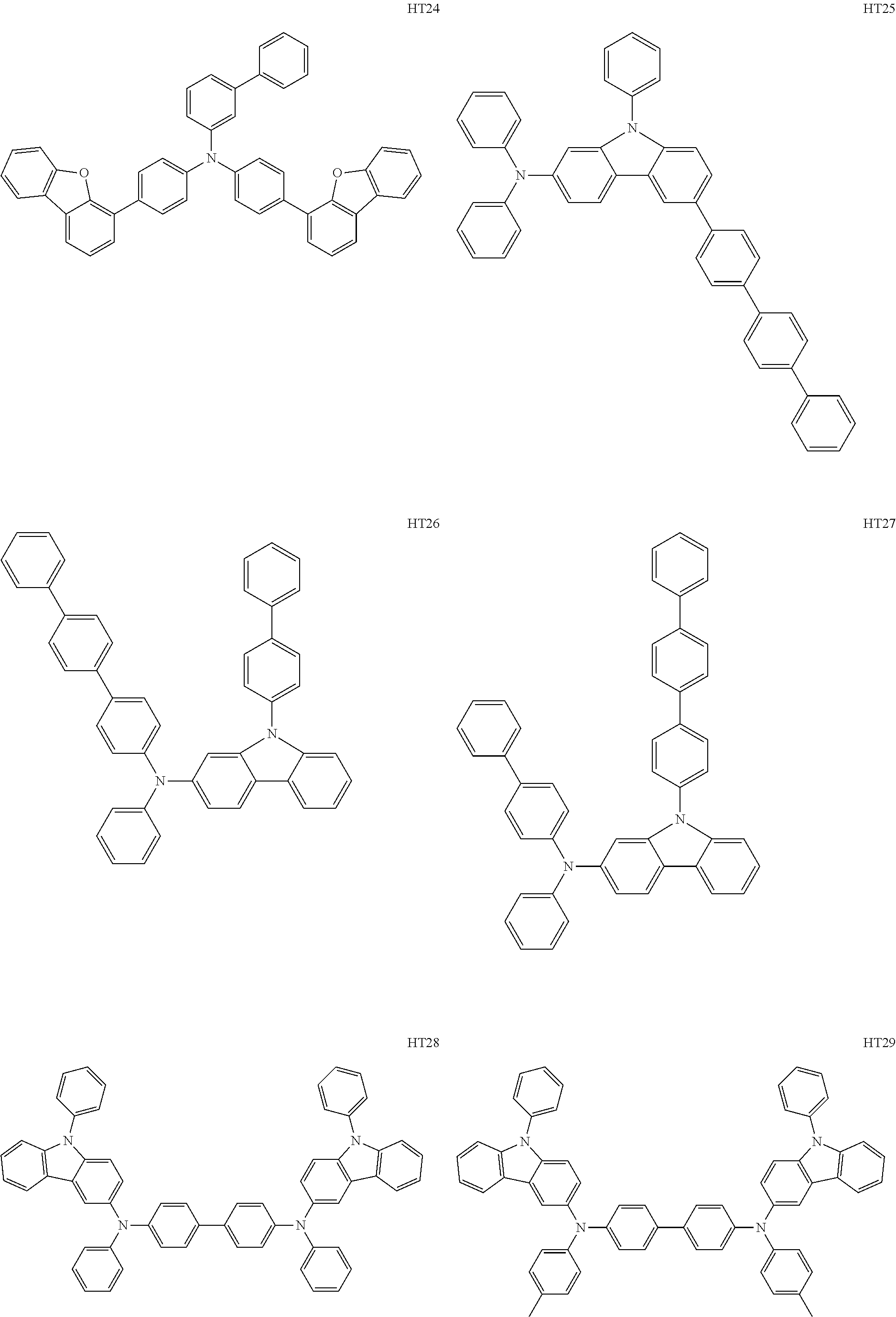

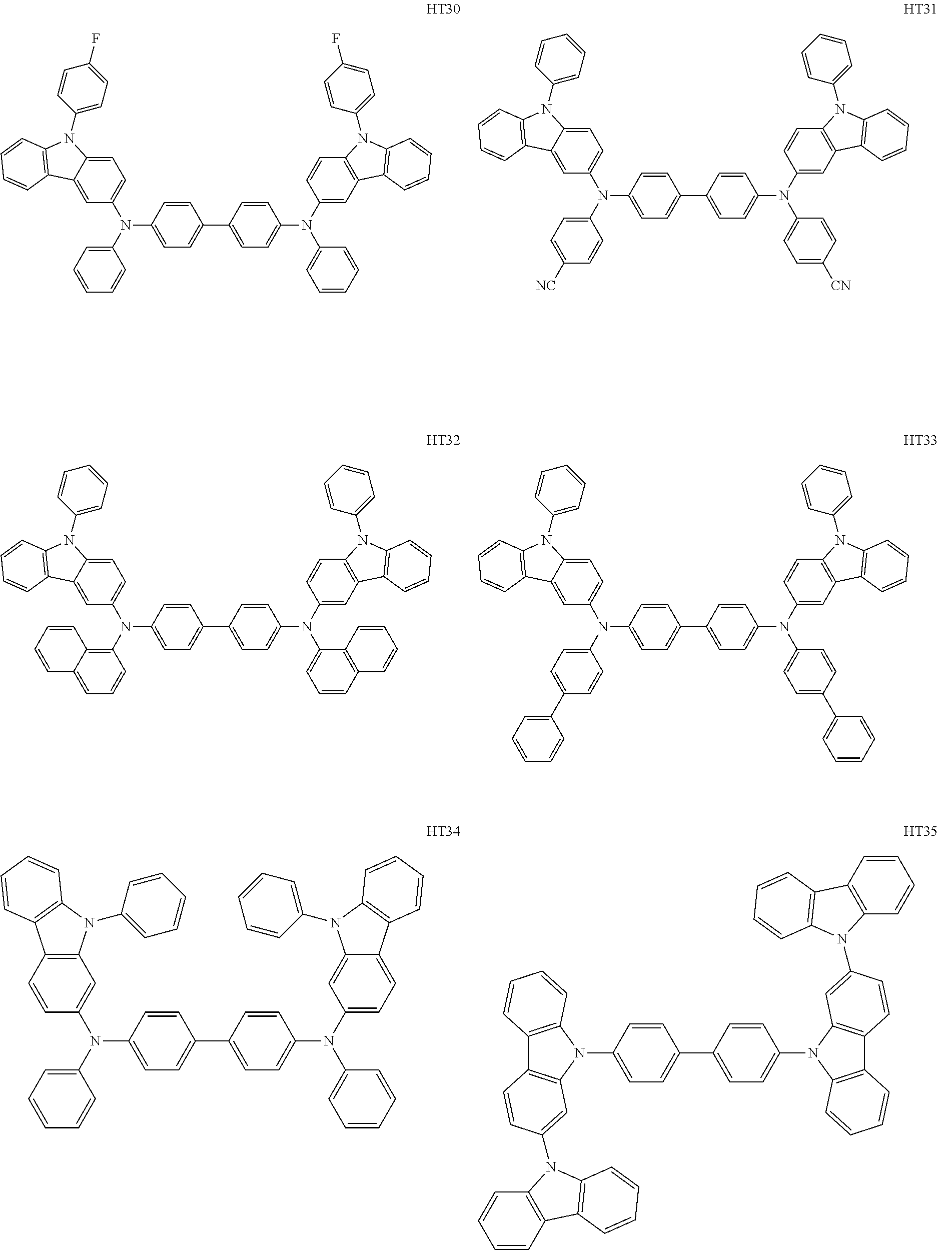

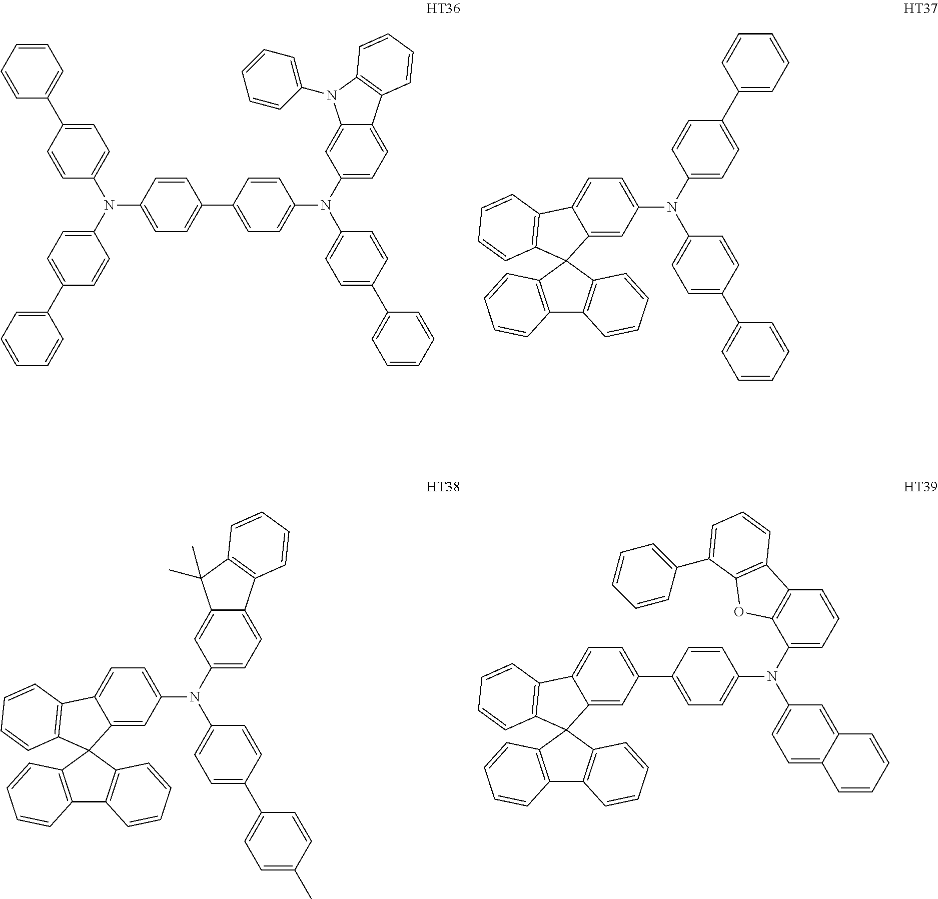 [SMILES: c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1 ; c1ccc(-c2ccc(N(c3ccc(-c4ccccc4)cc3)c3ccc4c(c3)C3(c5ccccc5-c5ccccc53)c3ccccc3-4)cc2)cc1 ; Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1]

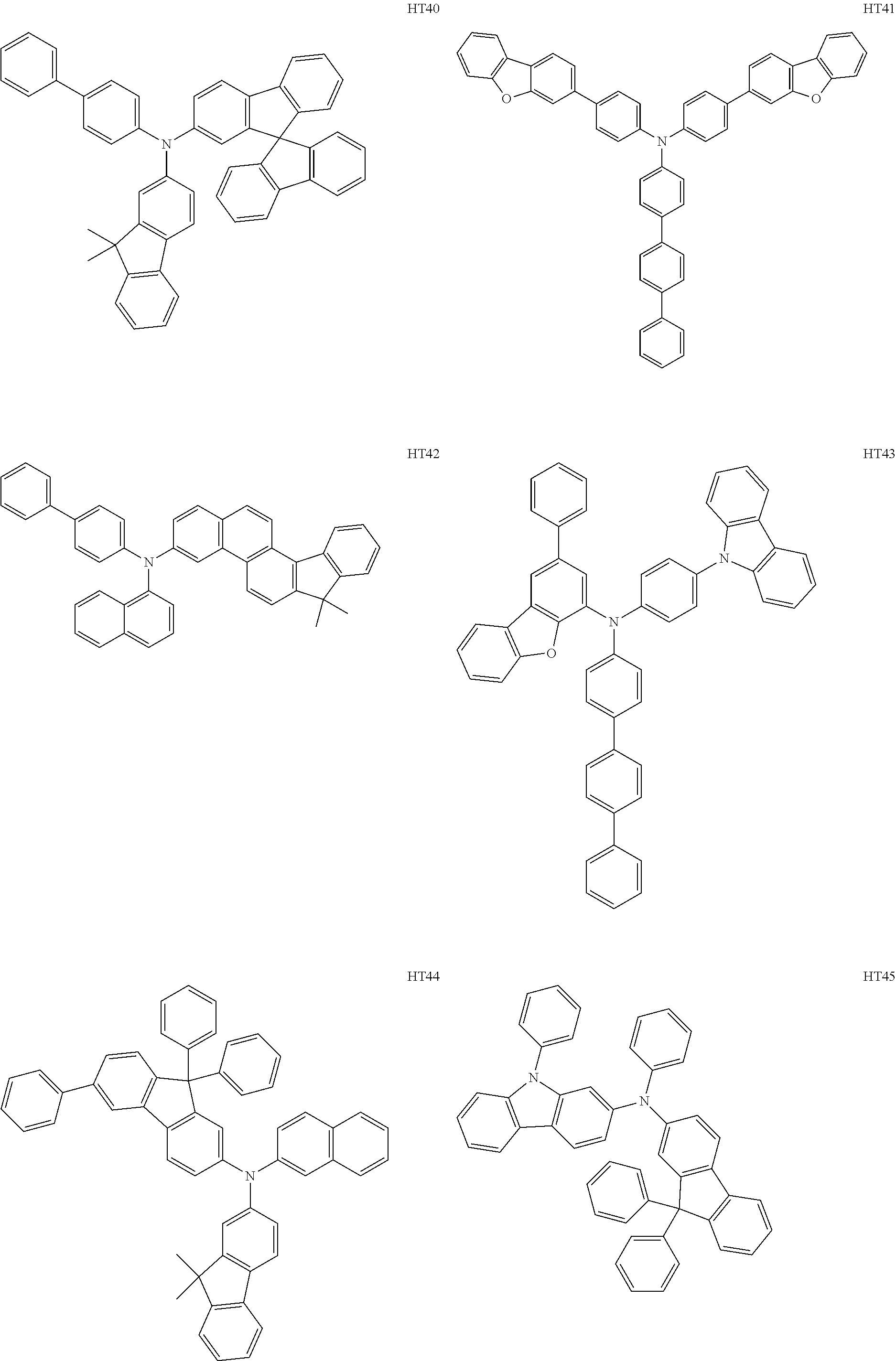

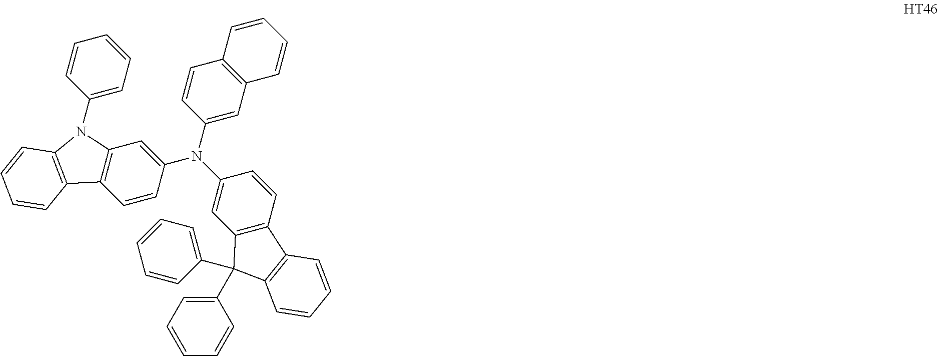 [SMILES: c1ccc(-n2c3ccccc3c3ccc(N(c4ccc5c(c4)C(c4ccccc4)(c4ccccc4)c4ccccc4-5)c4ccc5ccccc5c4)cc32)cc1]

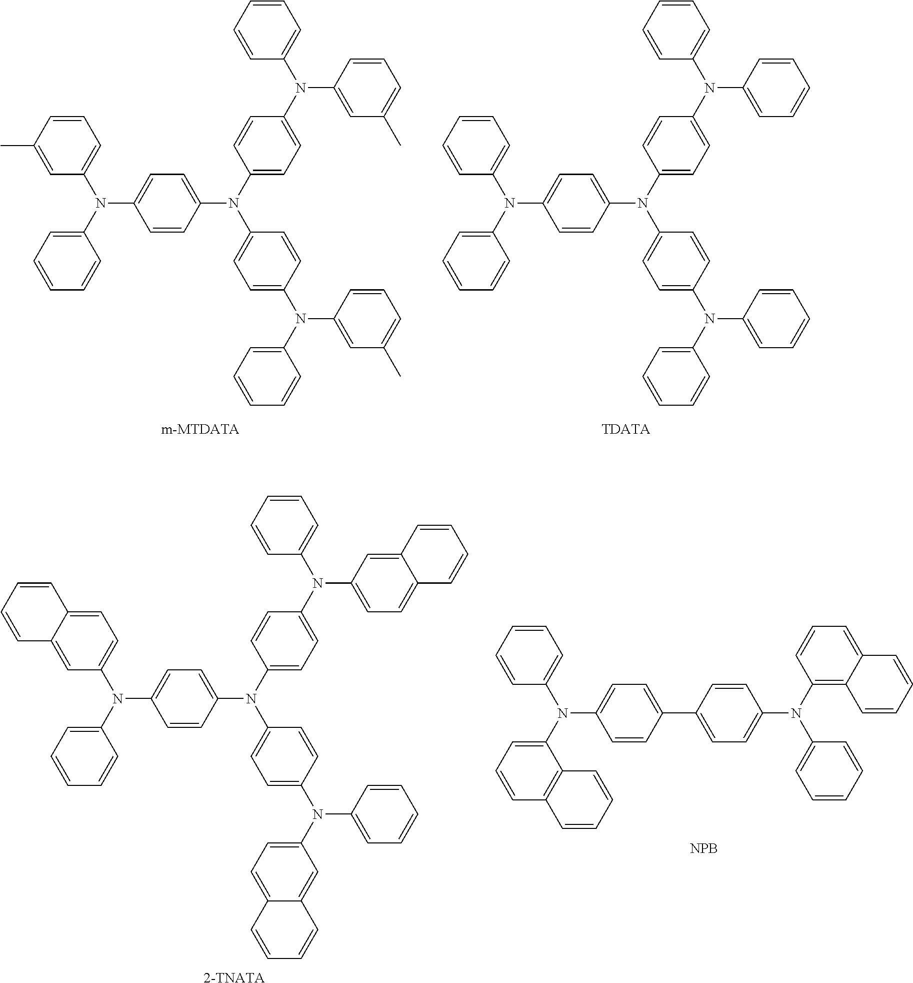

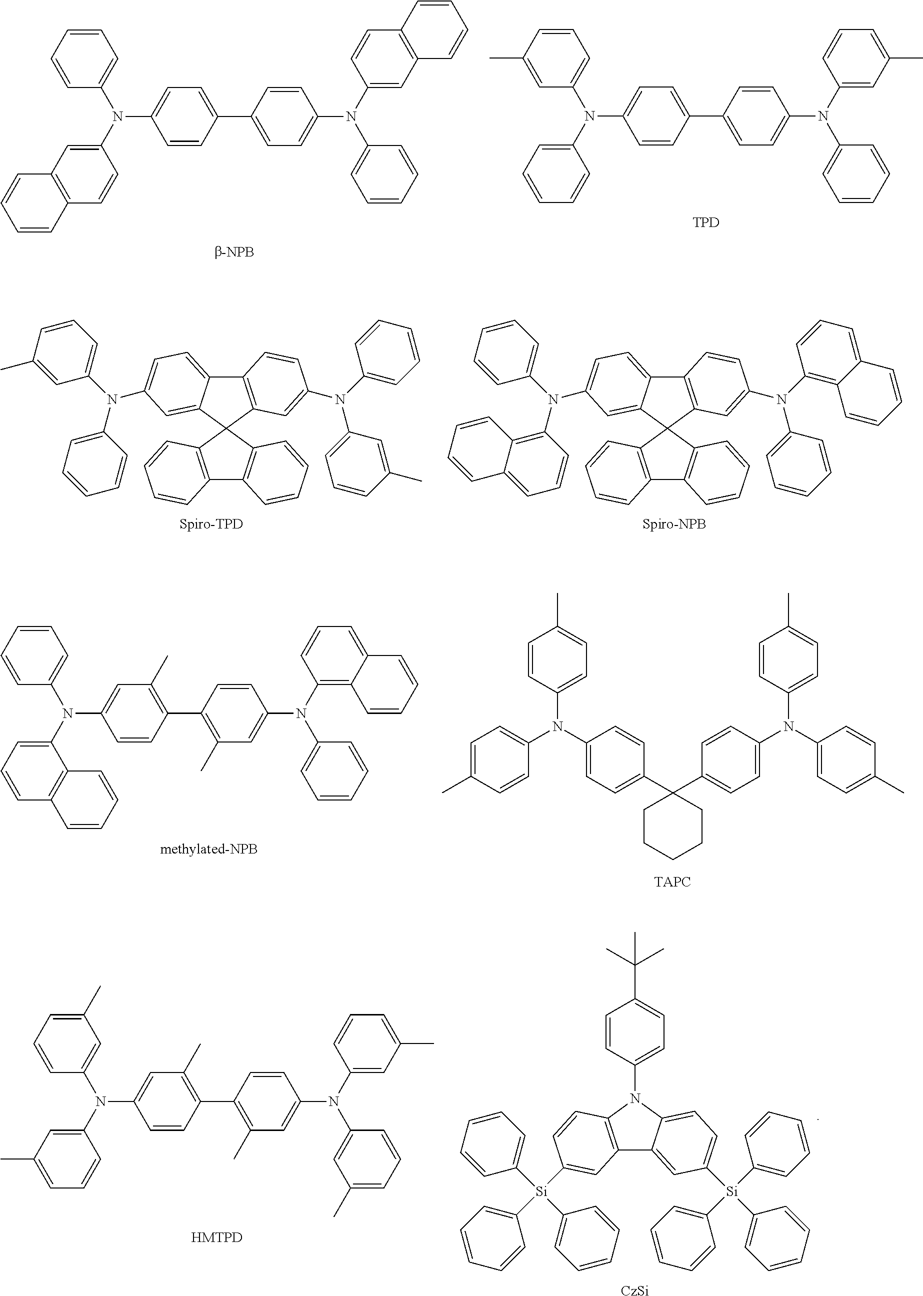

A thickness of the hole transport region may be in a range of about 50 Angstroms (Å) to about 10,000 Å. For example, a thickness of the hole transport region may be in a range of about 100 Å to about 4,000 Å. In case that the hole transport region includes a hole injection layer, a hole transport layer, or any combination thereof, a thickness of the hole injection layer may be in a range of about 100 Å to about 9,000 Å, and a thickness of the hole transport layer may be in a range of about 50 Å to about 2,000 Å. For example, the thickness of the hole injection layer may be in a range of about 100 Å to about 1,000 Å. For example, the thickness of the hole transport layer may be in a range of about 100 Å to about 1,500 Å. When the thicknesses of the hole transport region, the hole injection layer, and the hole transport layer are within any of these ranges, excellent hole transport characteristics may be obtained without a substantial increase in driving voltage.

The emission auxiliary layer may increase light luminescence efficiency by compensating for an optical resonance distance according to a wavelength of light emitted by an emission layer. The electron blocking layer may prevent leakage of electrons to a hole transport region from an emission layer. Materials that may be included in the hole transport region may also be included in an emission auxiliary layer and an electron blocking layer.

[p-Dopant]

The hole transport region may include a charge generating material as well as the aforementioned materials to improve conductive properties of the hole transport region. The charge generating material may be substantially homogeneously or non-homogeneously dispersed (for example, as a single layer consisting of charge generating material) in the hole transport region.

The charge generating material may include, for example, a p-dopant.

In embodiments, a lowest unoccupied molecular orbital (LUMO) energy level of the p-dopant may be −3.5 eV or less.

In embodiments, the p-dopant may include a quinone derivative, a compound containing a cyano group, a compound containing element EL1 and element EL2, or any combination thereof.

Examples of a quinone derivative may include TCNQ, F4-TCNQ, and the like.

Examples of a compound containing a cyano group may include HAT-CN, a compound represented by Formula 221, and the like:

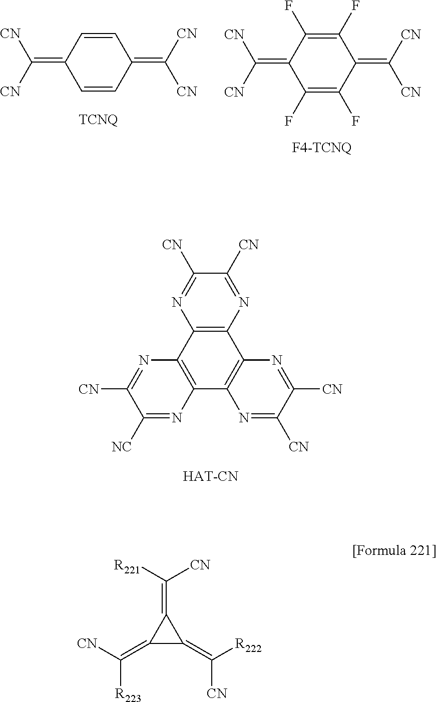

In Formula 221,

R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

at least one of R₂₂₁ to R₂₂₃ may each independently be: a C₃-C₆₀ carbocyclic group or a C₁-C₆₀ heterocyclic group, substituted with a cyano group; —F; —Cl; —Br; —I; a C₁-C₂₀ alkyl group substituted with a cyano group, —F, —Cl, —Br, —I, or any combination thereof; or any combination thereof.

In the compound containing element EL1 and element EL2, element EL1 may be a metal, a metalloid, or a combination thereof, and element EL2 may be a non-metal, a metalloid, or a combination thereof.

Examples of a metal may include: an alkali metal (e.g., lithium (Li), sodium (Na), potassium (K), rubidium (Rb), cesium (Cs), or the like); an alkaline earth metal (e.g., beryllium (Be), magnesium (Mg), calcium (Ca), strontium (Sr), barium (Ba), or the like); a transition metal (e.g., titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), or the like); a post-transition metal (e.g., zinc (Zn), indium (In), tin (Sn), or the like); a lanthanide metal (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), or the like); and the like.

Examples of a metalloid may include silicon (Si), antimony (Sb), tellurium (Te), and the like.

Examples of a non-metal may include oxygen (O), a halogen (e.g., F, Cl, Br, I, and the like), and the like.

Examples of a compound containing element EL1 and element EL2 may include a metal oxide, a metal halide (e.g., a metal fluoride, a metal chloride, a metal bromide, a metal iodide, and the like), a metalloid halide (e.g., a metalloid fluoride, a metalloid chloride, a metalloid bromide, a metalloid iodide, and the like), a metal telluride, or any combination thereof.

Examples of a metal oxide may include a tungsten oxide (e.g., WO, W₂O₃, WO₂, WO₃, or W₂O₅), a vanadium oxide (e.g., VO, V₂O₃, VO₂, or V₂O₅), a molybdenum oxide (MoO, Mo₂O₃, MoO₂, MoO₃, or Mo₂O₅), and a rhenium oxide (e.g., ReO₃).

Examples of a metal halide may include an alkali metal halide, an alkaline earth metal halide, a transition metal halide, a post-transition metal halide, a lanthanide metal halide, and the like.

Examples of an alkali metal halide may include LiF, NaF, KF, RbF, CsF, LiCl, NaCl, KCl, RbCl, CsCl, LiBr, NaBr, KBr, RbBr, CsBr, Lil, NaI, KI, RbI, CsI, and the like.

Examples of an alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, and BaI₂.

Examples of a transition metal halide may include a titanium halide (e.g., TiF₄, TiCl₄, TiBr₄, or TiI₄), a zirconium halide (e.g., ZrF₄, ZrCl₄, ZrBr₄, or ZrI₄), a hafnium halide (e.g., HfF₄, HfC₁₄, HfBr₄, or Hf₁₄), a vanadium halide (e.g., VF₃, VCl₃, VBr₃, or VI₃), a niobium halide (e.g., NbF₃, NbCl₃, NbBr₃, or NbI₃), a tantalum halide (e.g., TaF₃, TaCl₃, TaBr₃, or TaI₃), a chromium halide (e.g., CrF₃, CrCl₃, CrBr₃, or CrI₃), a molybdenum halide (e.g., MoF₃, MoCl₃, MoBr₃, or MoI₃), a tungsten halide (e.g., WF₃, WCl₃, WBr₃, or WI₃), a manganese halide (e.g., MnF₂, MnCl₂, MnBr₂, or MnI₂), a technetium halide (e.g., TcF₂, TcCl₂, TcBr₂, or TcI₂), a rhenium halide (e.g., ReF₂, ReCl₂, ReBr₂, or ReI₂), an iron halide (e.g., FeF₂, FeCl₂, FeBr₂, or FeI₂), a ruthenium halide (e.g., RuF₂, RuCl₂, RuBr₂, or RuI₂), an osmium halide (e.g., OsF₂, OsCl₂, OsBr₂, or OsI₂), a cobalt halide (e.g., CoF₂, COCl₂, CoBr₂, or CoI₂), a rhodium halide (e.g., RhF₂, RhCl₂, RhBr₂, or RhI₂), an iridium halide (e.g., IrF₂, IrCl₂, IrBr₂, or IrI₂), a nickel halide (e.g., NiF₂, NiCl₂, NiBr₂, or NiI₂), a palladium halide (e.g., PdF₂, PdCl₂, PdBr₂, or PdI₂), a platinum halide (e.g., PtF₂, PtCl₂, PtBr₂, or PtI₂), a copper halide (e.g., CuF, CuCl, CuBr, or CuI), a silver halide (e.g., AgF, AgCl, AgBr, or AgI), and a gold halide (e.g., AuF, AuCl, AuBr, or AuI).

Examples of a post-transition metal halide may include a zinc halide (e.g., ZnF₂, ZnCl₂, ZnBr₂, or ZnI₂), an indium halide (e.g., InI₃), and a tin halide (e.g., SnI₂).

Examples of a lanthanide metal halide may include YbF, YbF₂, YbF₃, SmF₃, YbCl, YbCl₂, YbCl₃ SmCl₃, YbBr, YbBr₂, YbBr₃ SmBr₃, YbI, YbI₂, YbI₃, and SmI₃.

Examples of a metalloid halide may include an antimony halide (e.g., SbCl₅).

Examples of a metal telluride may include an alkali metal telluride (e.g., Li₂Te, Na₂Te, K₂Te, Rb₂Te, or Cs₂Te), an alkaline earth metal telluride (e.g., BeTe, MgTe, CaTe, SrTe, or BaTe), a transition metal telluride (e.g., TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, or Au₂Te), a post-transition metal telluride (e.g., ZnTe), and a lanthanide metal telluride (e.g., LaTe, CeTe, PrTe, NdTe, PmTe, EuTe, GdTe, TbTe, DyTe, HoTe, ErTe, TmTe, YbTe, or LuTe).

### [Emission Layer in Interlayer 130]

When the light-emitting device 10 is a full color light-emitting device, the emission layer may be patterned into a red emission layer, a green emission layer, and/or a blue emission layer, according to a subpixel. In embodiments, the emission layer may have a stacked structure. The stacked structure may include two or more layers selected from a red emission layer, a green emission layer, and a blue emission layer. The two or more layers may be in direct contact with each other or may be separated from each other to emit white light. In embodiments, the emission layer may include two or more materials. The two or more materials may include a red light-emitting material, a green light-emitting material, or a blue light-emitting material. The two or more materials may be mixed with each other in a single layer to emit white light. In embodiments, the emission layer may emit blue light.

In embodiments, the emission layer may include the heterocyclic compound represented by Formula 1 described herein.

The emission layer may include a host and a dopant.

In embodiments, the dopant may include the heterocyclic compound represented by Formula 1 described herein. The dopant may include, in addition to the heterocyclic compound represented by Formula 1, a phosphorescent dopant, a fluorescent dopant, or any combination thereof. In addition to the heterocyclic compound represented by Formula 1, the phosphorescent dopant or the fluorescent dopant that may be included in the emission layer may each be understood by referring to the descriptions of the phosphorescent dopant or the fluorescent dopant.

The amount of the dopant in the emission layer may be in a range of about 0.01 parts to about 15 parts by weight based on 100 parts by weight of the host.

In embodiments, the emission layer may include quantum dots.

The emission layer may include a delayed fluorescence material. The delayed fluorescence material may serve as a host or a dopant in the emission layer.

A thickness of the emission layer may be in a range of about 100 Å to about 1,000 Å. For example, the thickness of the emission layer may be in a range of about 200 Å to about 600 Å. When the thickness of the emission layer is within any of these ranges, improved luminescence characteristics may be obtained without a substantial increase in driving voltage.

### [Host]

The host may include, for example, a carbazole-containing compound, an anthracene-containing compound, or any combination thereof.

In embodiments, the host may further include a compound represented by Formula 301:

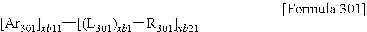

In Formula 301,

Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xb11 may be 1, 2, or 3,

xb1 may be an integer from 0 to 5,

R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),

xb21 may be an integer from 1 to 5, and

Q₃₀₁ to Q₃₀₃ may each independently be the same as described in connection with Q₁ as described herein.

In embodiments, in Formula 301, in case that xb11 in Formula 301 is 2 or greater, at least two Ar₃₀₁ (s) may be bound via a single bond.

In embodiments, the host may include a compound represented by Formula 301-1, a compound represented by Formula 301-2, or any combination thereof:

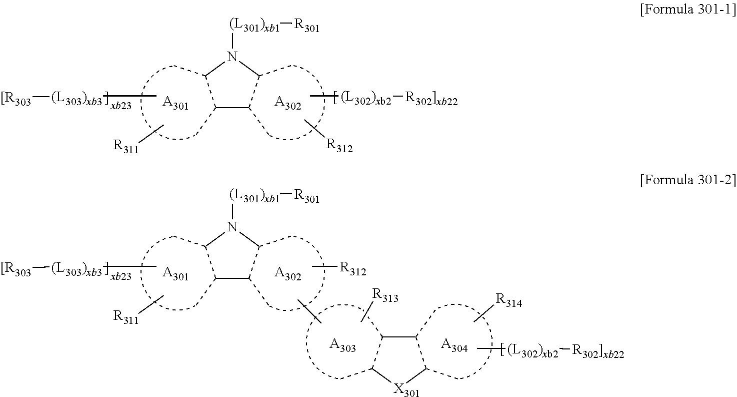

In Formulae 301-1 to 301-2,

ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

X₃₀₁ may be O, S, N-[(L₃₀₄)_{xb4}-R₃₀₄], C(R₃₀₄)(R₃₀₅), or Si(R₃₀₄)(R₃₀₅),

xb22 and xb23 may each independently be 0, 1, or 2,

L₃₀₁, xb1, and R₃₀₁ may respectively be understood by referring to the descriptions of L₃₀₁, xb1, and R₃₀₁ provided herein,

L₃₀₂ to L₃₀₄ may each independently be the same as L₃₀₁ described herein,

xb2 to xb4 may each independently be the same as xb1 described herein, and

R₃₀₂ to R₃₀₅ and R₃₁₁ to R₃₁₄ may each independently be the same as described in connection with R₃₀₁ described herein.

In embodiments, the host may include an alkaline earth-metal complex, a post-transition metal complex, or any combination thereof. For example, the host may include a Be complex (e.g., Compound H55), a Mg complex, a Zn complex, or any combination thereof.

In embodiments, the host may include one of Compounds H1 to H124, 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1′-biphenyl (CBP), 1,3-di-9-carbazolylbenzene (mCP), 1,3,5-tri(carbazol-9-yl)benzene (TCP), or any combination thereof:

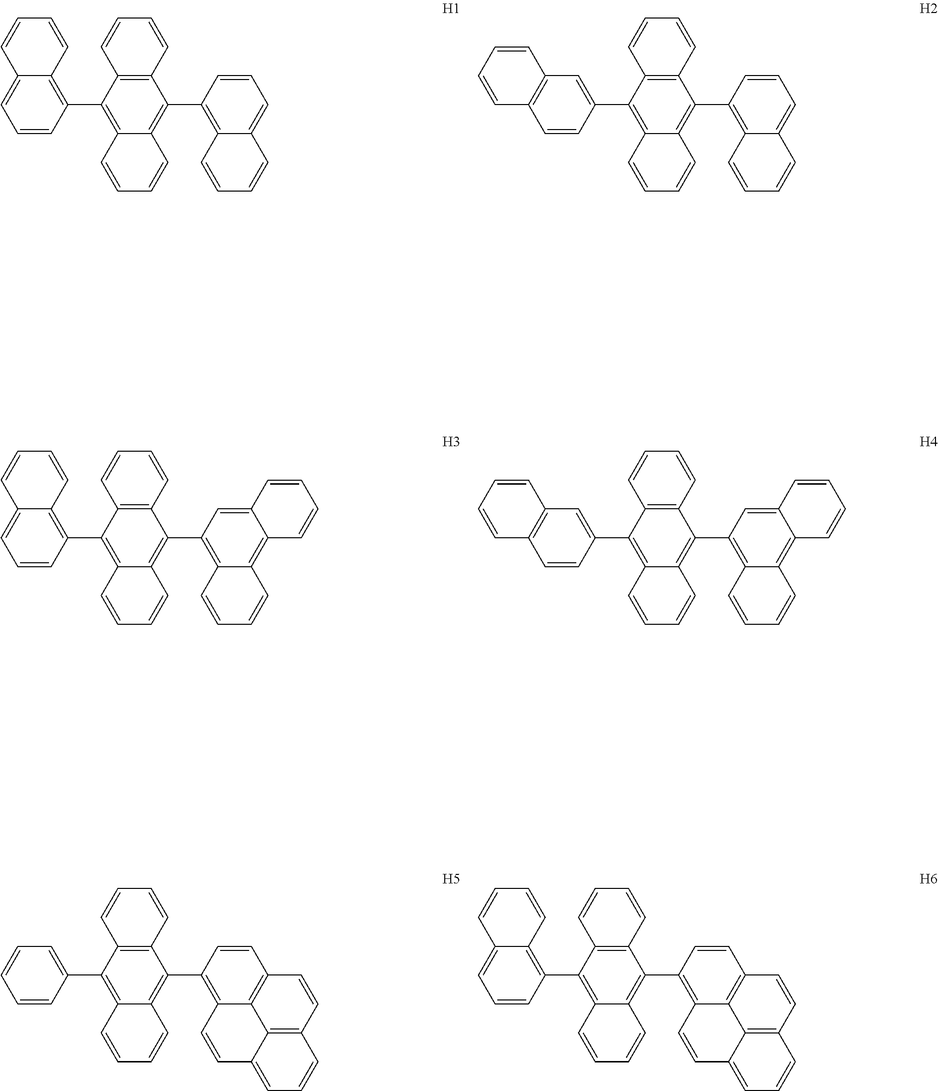

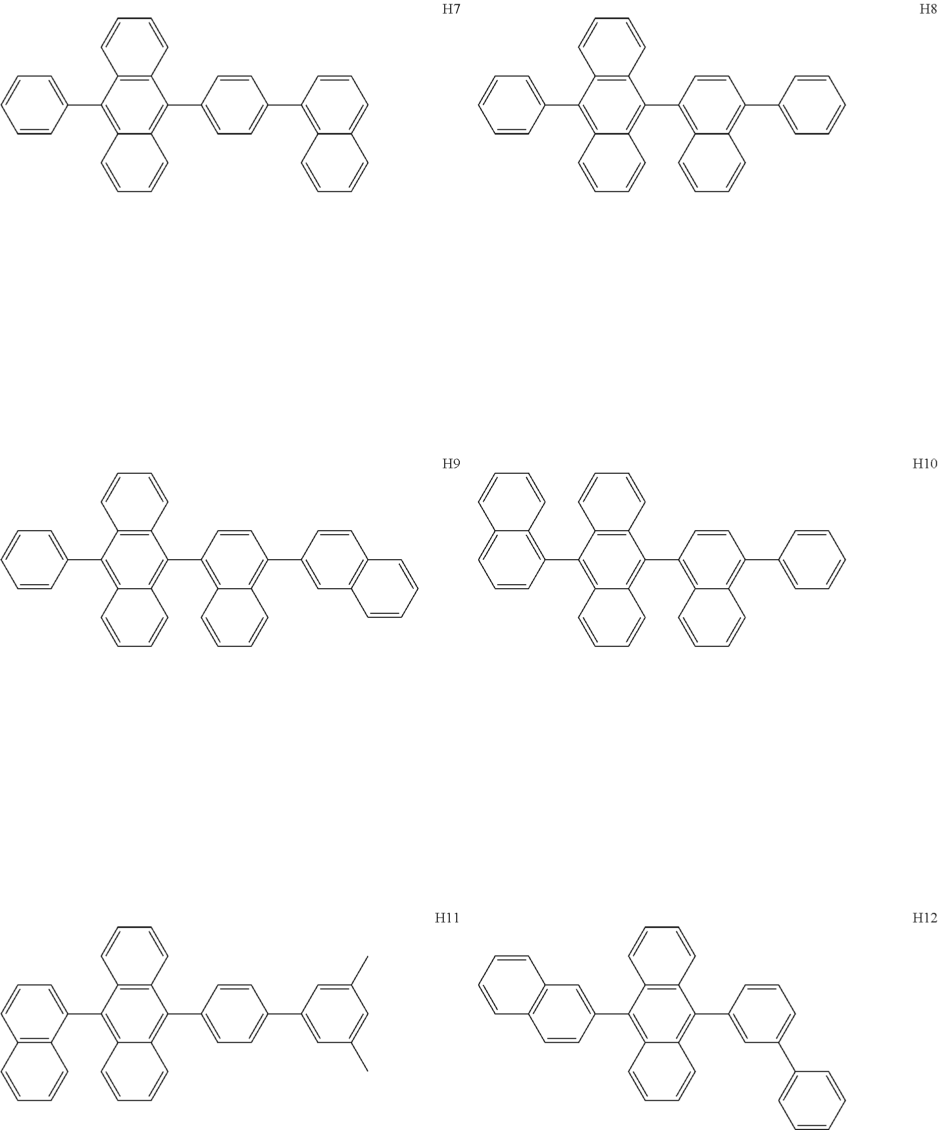

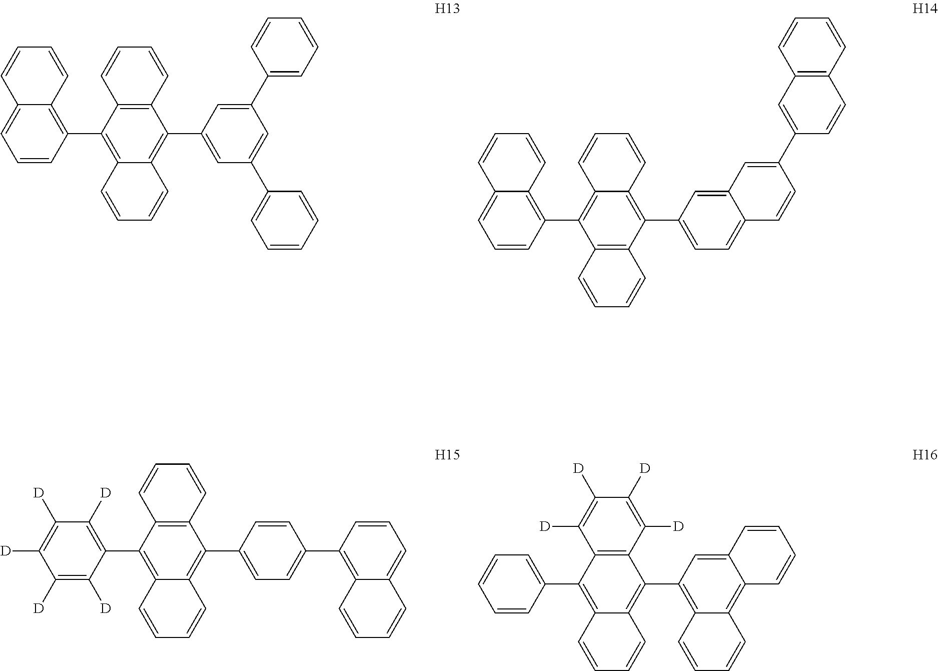

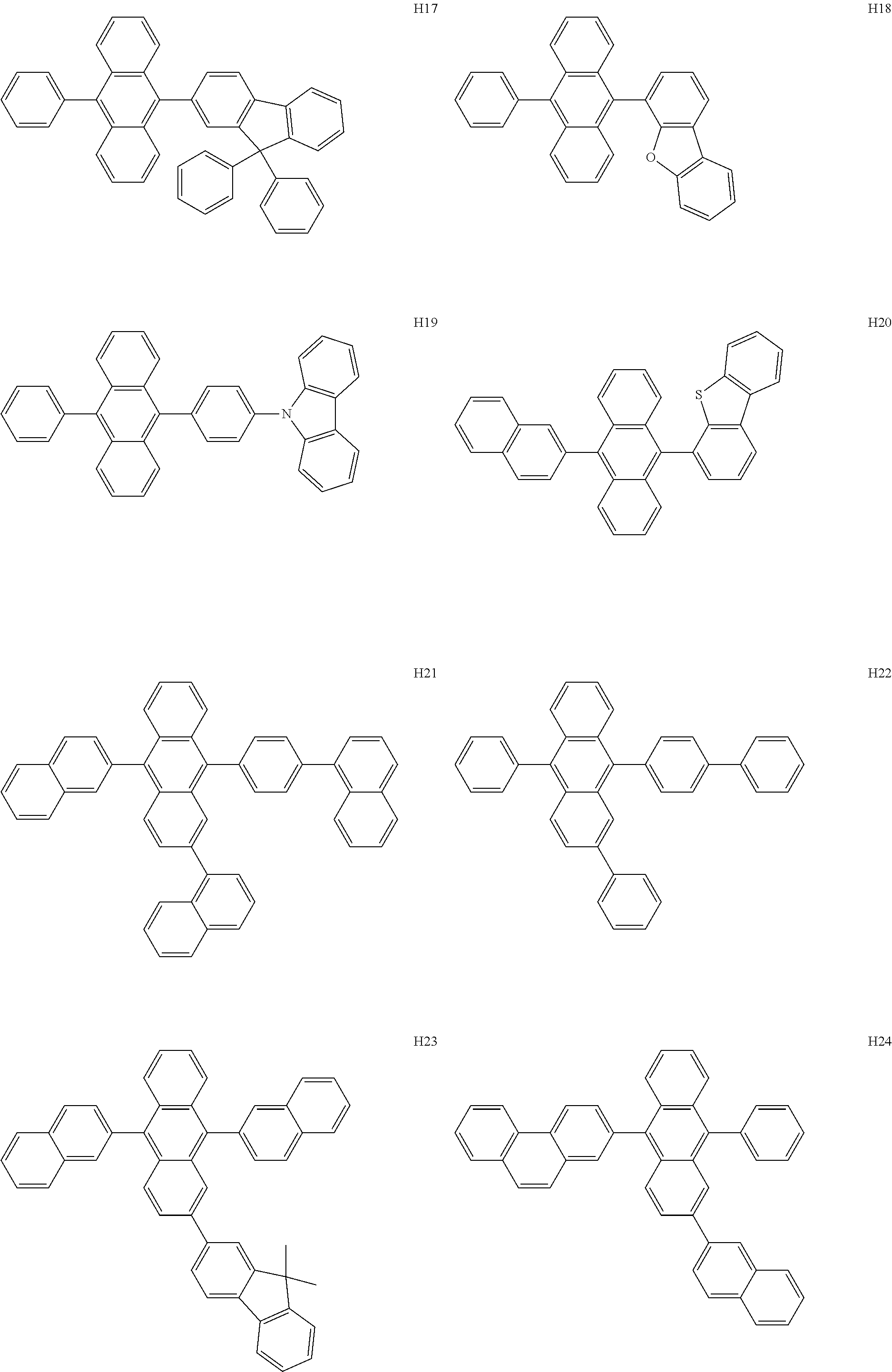

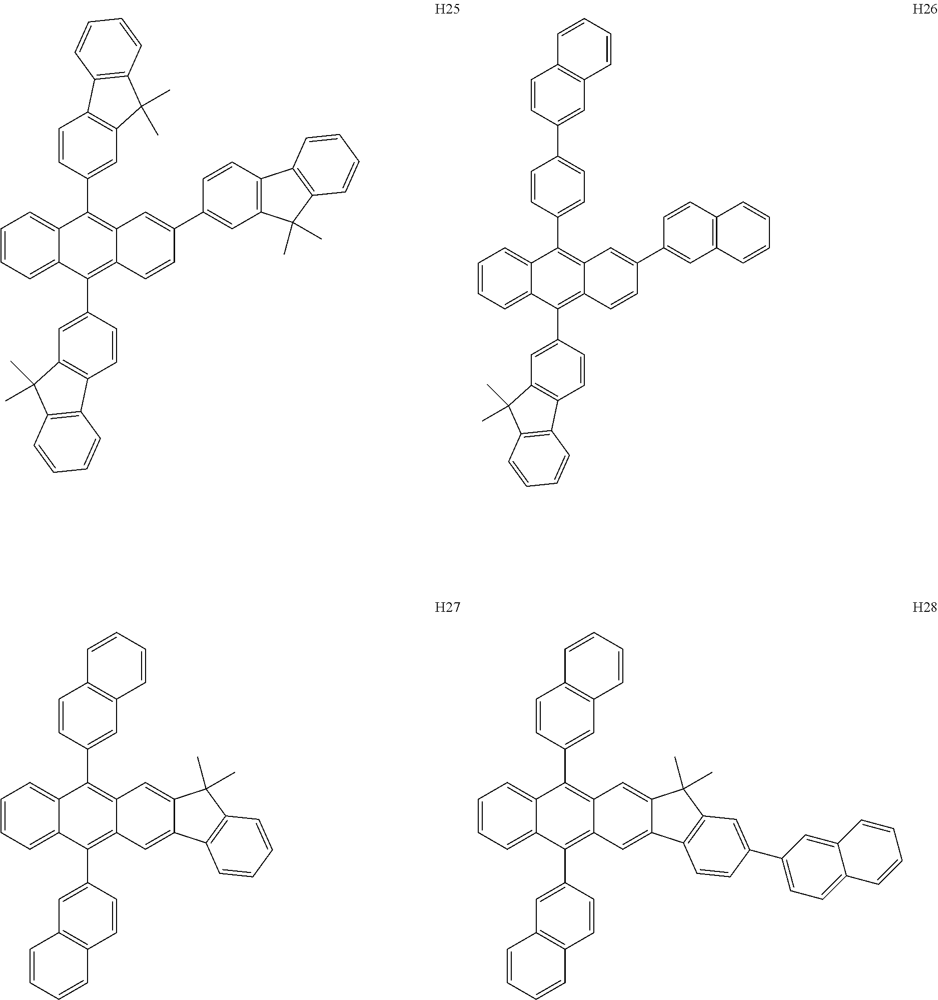

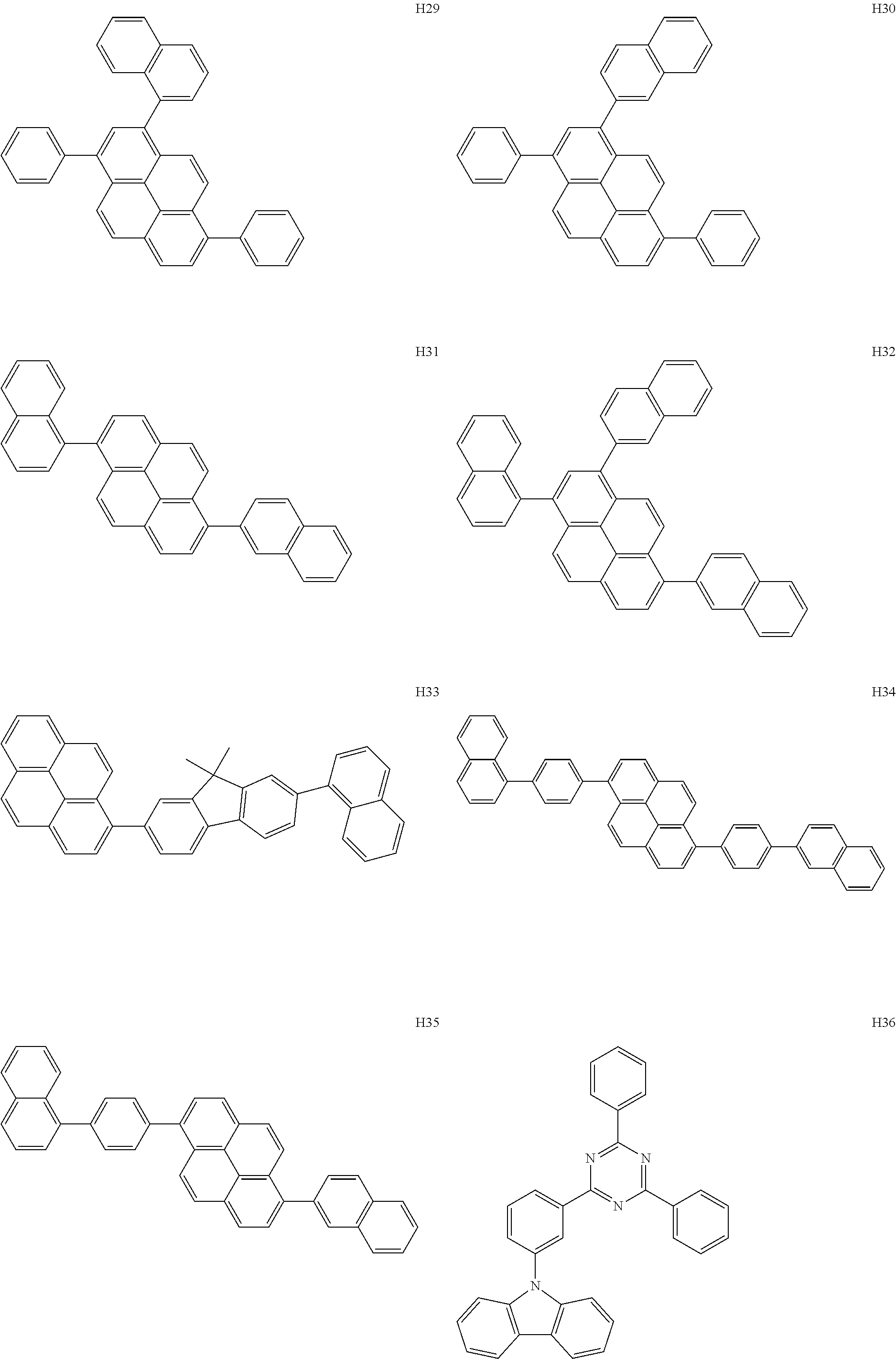

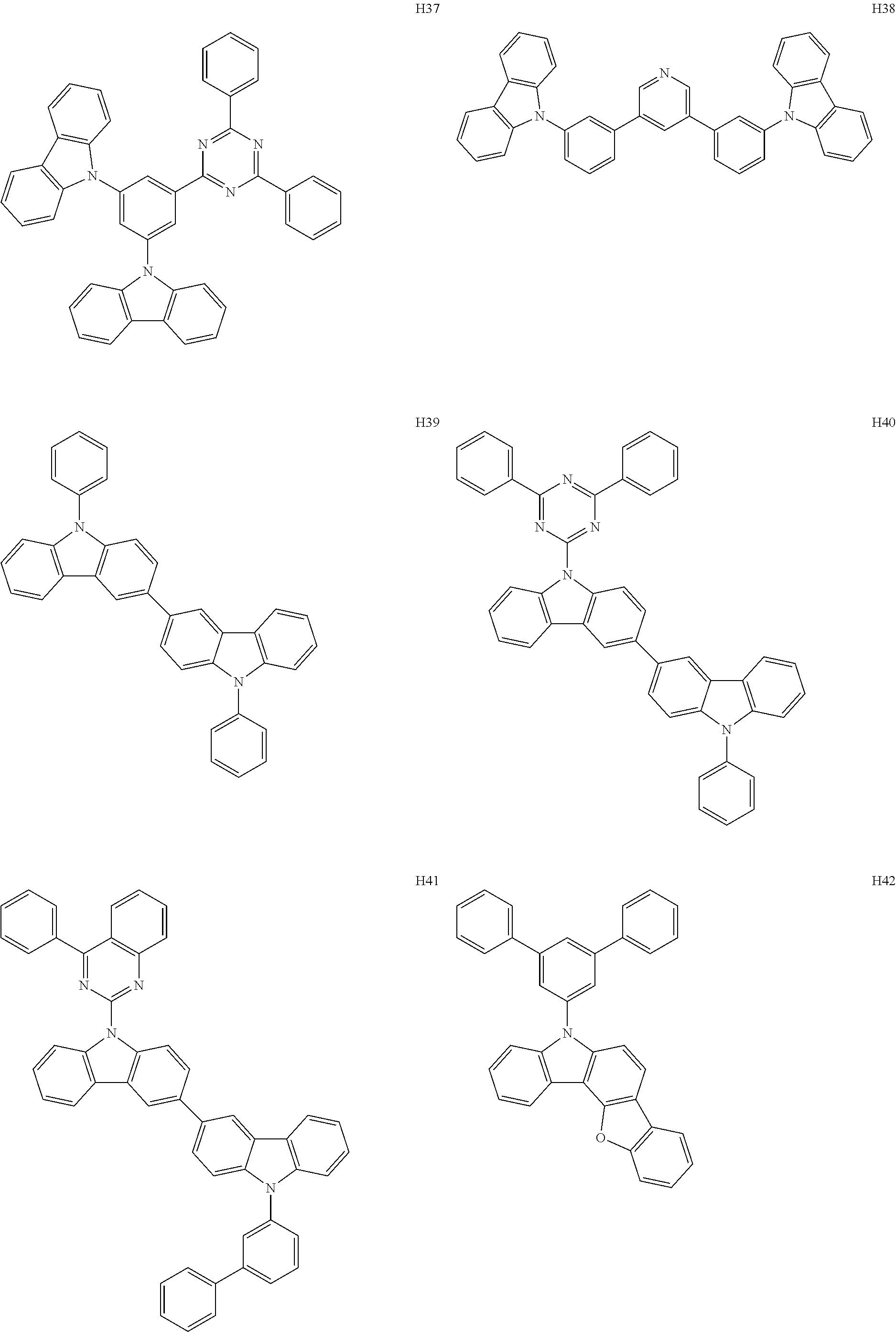 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1]

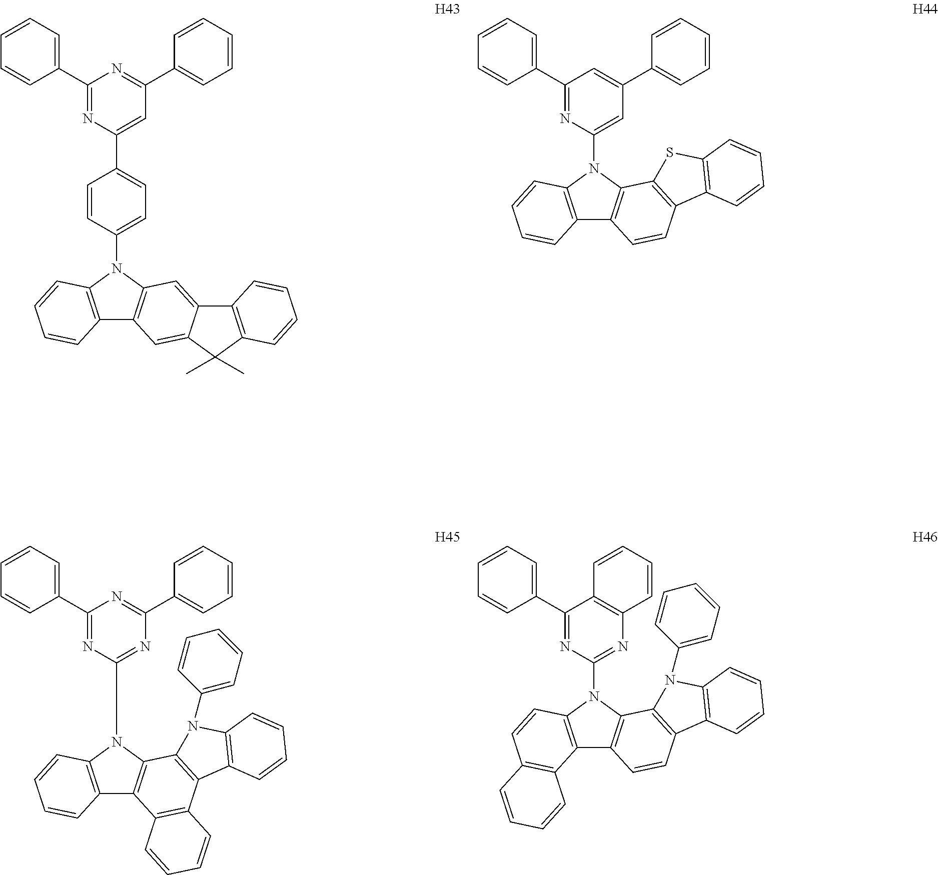 [SMILES: CC1(C)c2ccccc2-c2cc3c(cc21)c1ccccc1n3-c1ccc(-c2cc(-c3ccccc3)nc(-c3ccccc3)n2)cc1 ; c1ccc(-c2cc(-c3ccccc3)nc(-n3c4ccccc4c4ccc5c6ccccc6sc5c43)c2)cc1 ; c1ccc(-c2nc(-c3ccccc3)nc(-n3c4ccccc4c4c5ccccc5c5c6ccccc6n(-c6ccccc6)c5c43)n2)cc1 ; c1ccc(-c2nc(-n3c4ccc5ccccc5c4c4ccc5c6ccccc6n(-c6ccccc6)c5c43)nc3ccccc23)cc1]

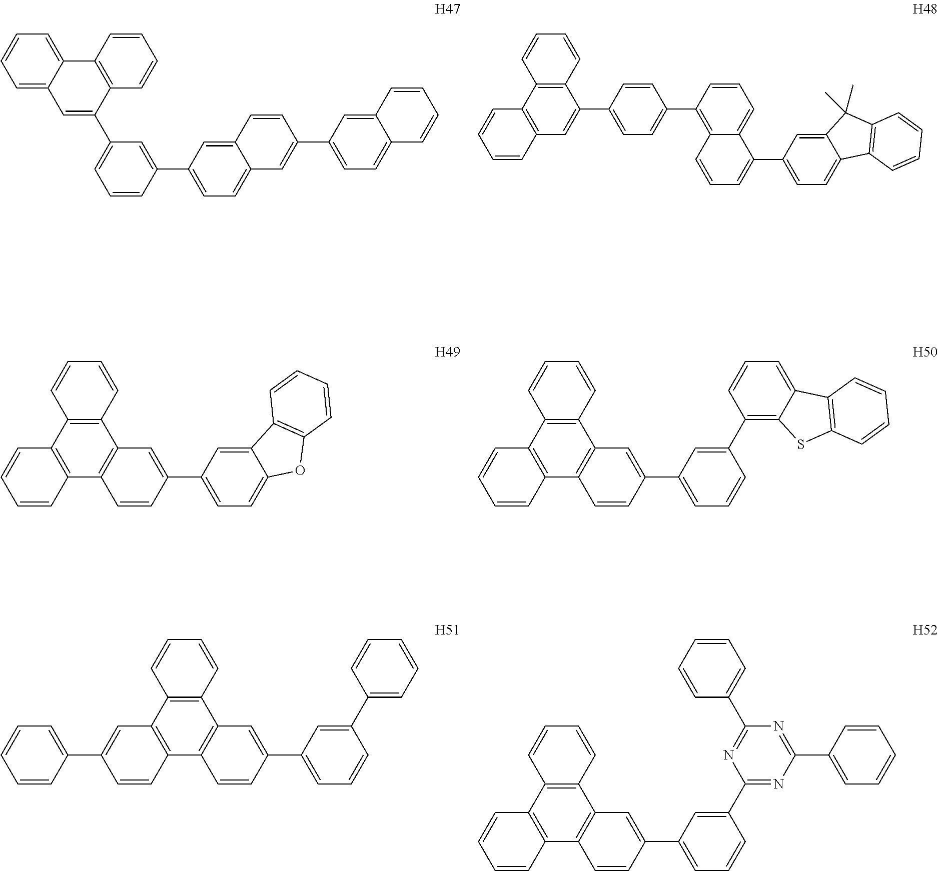

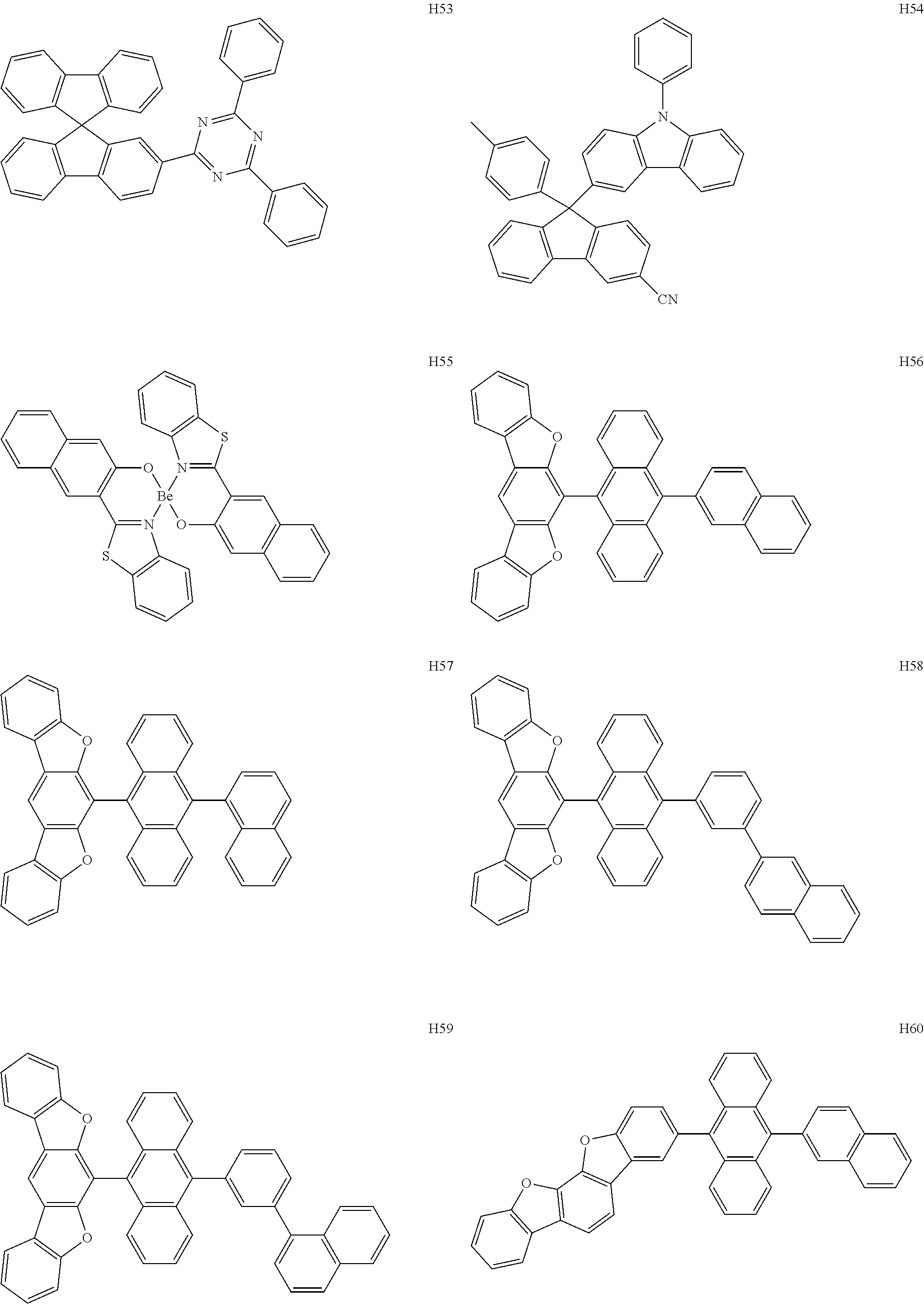

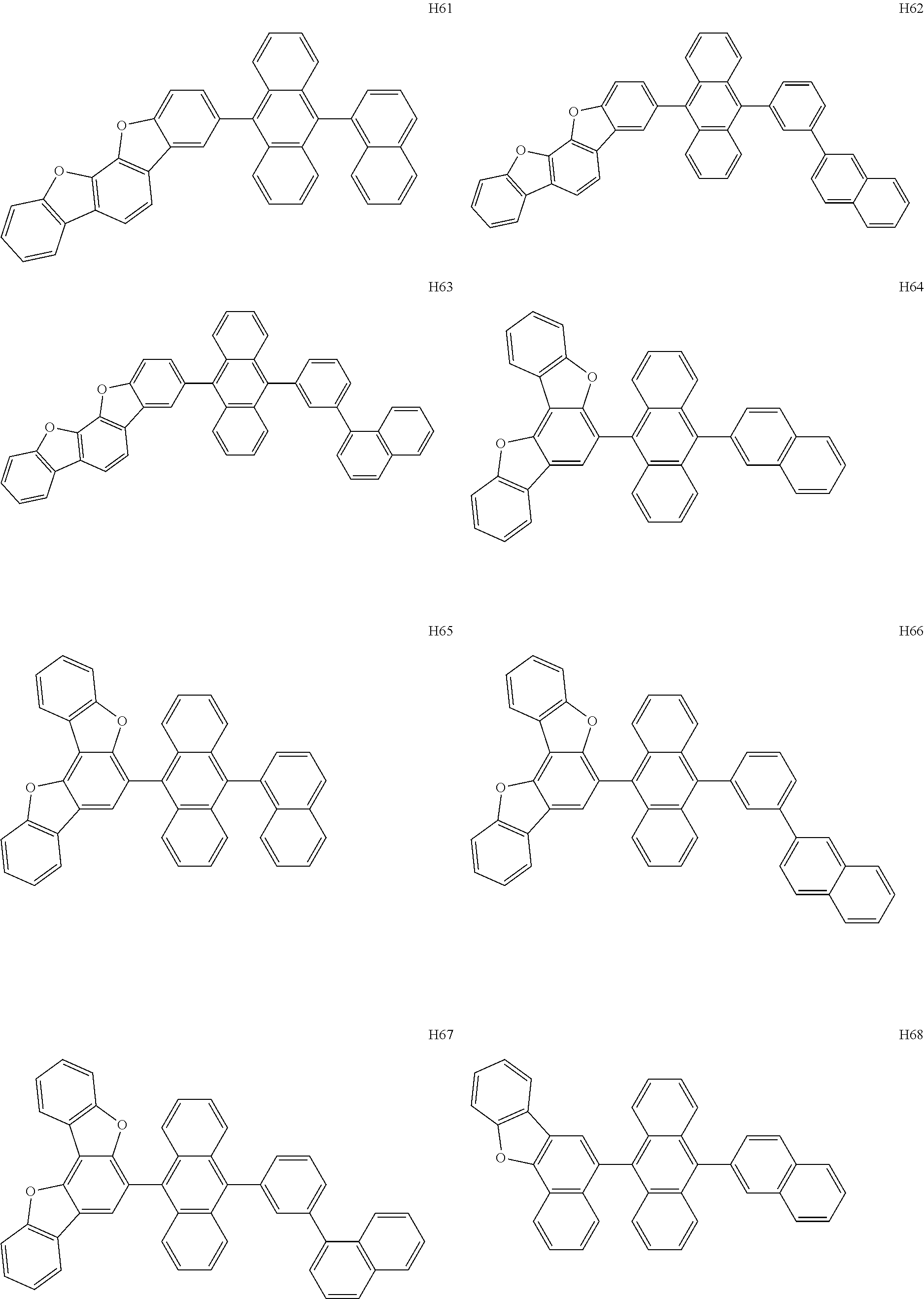

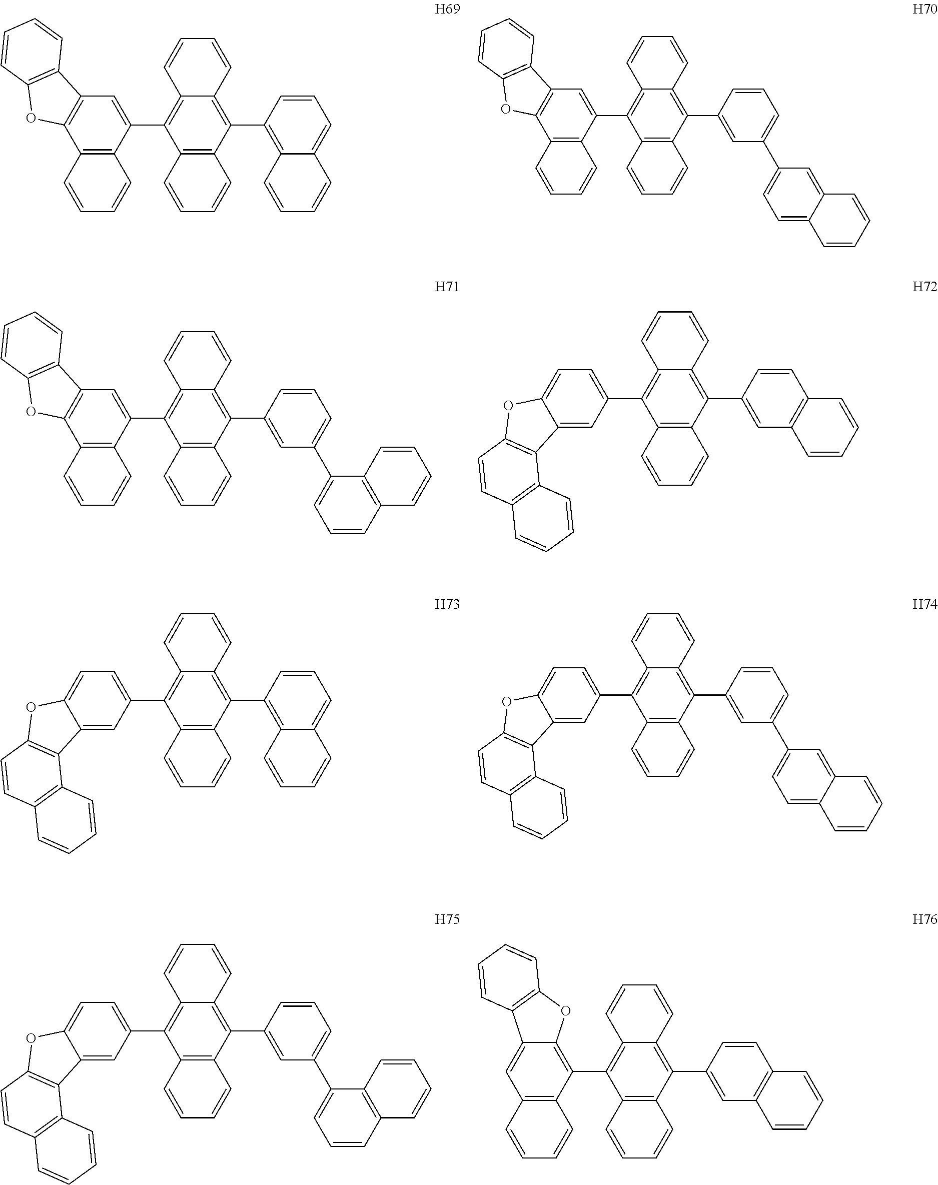

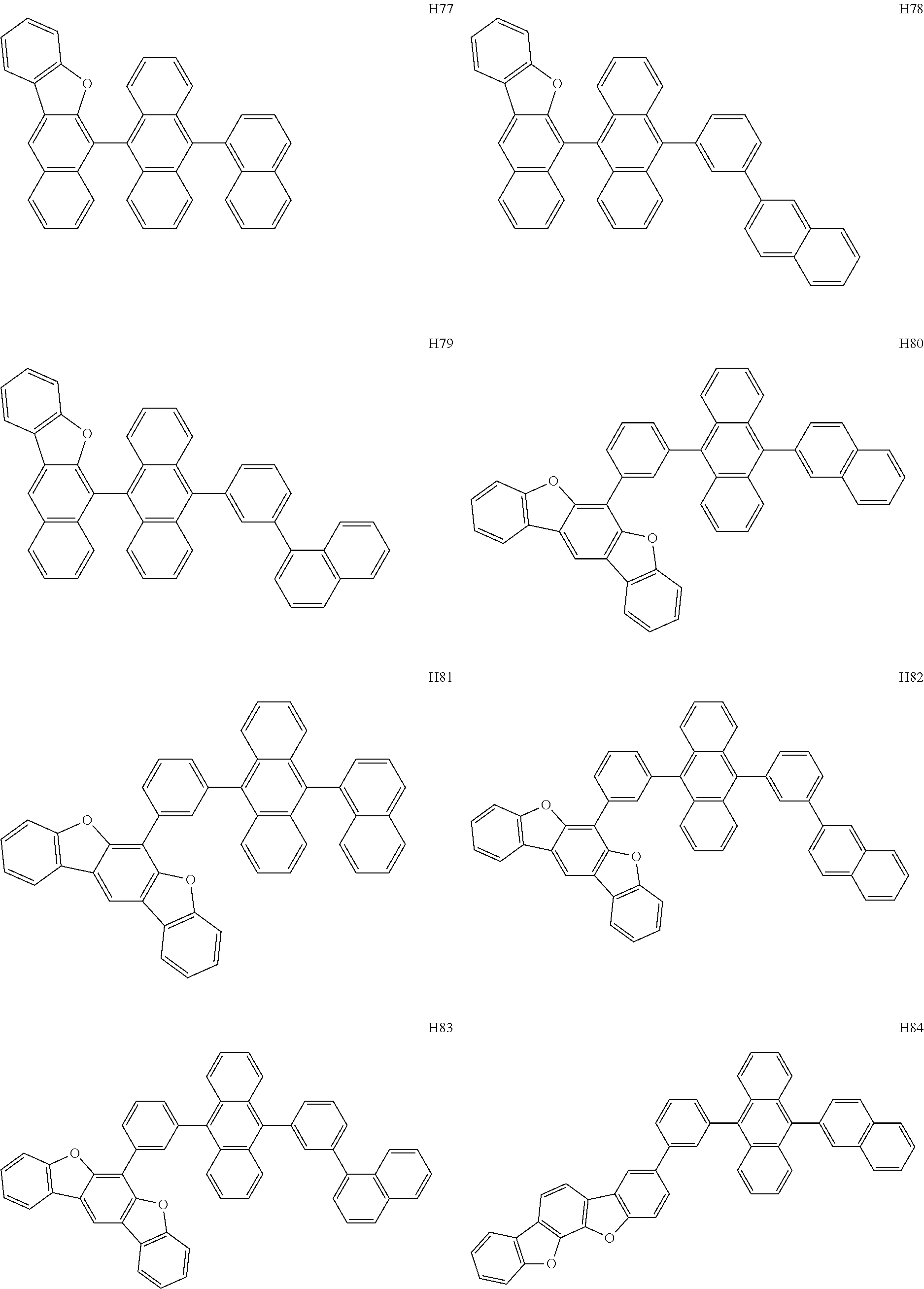

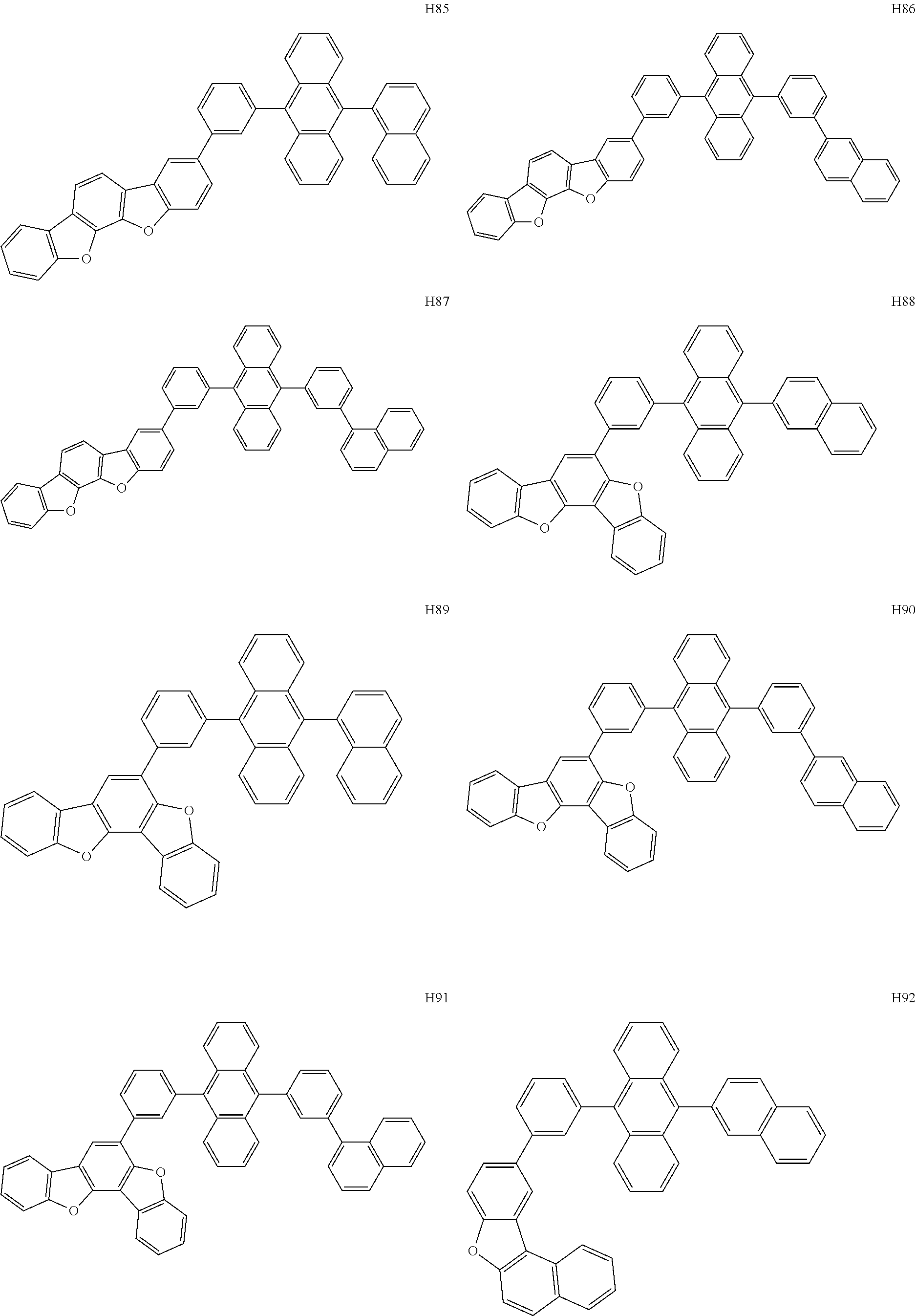

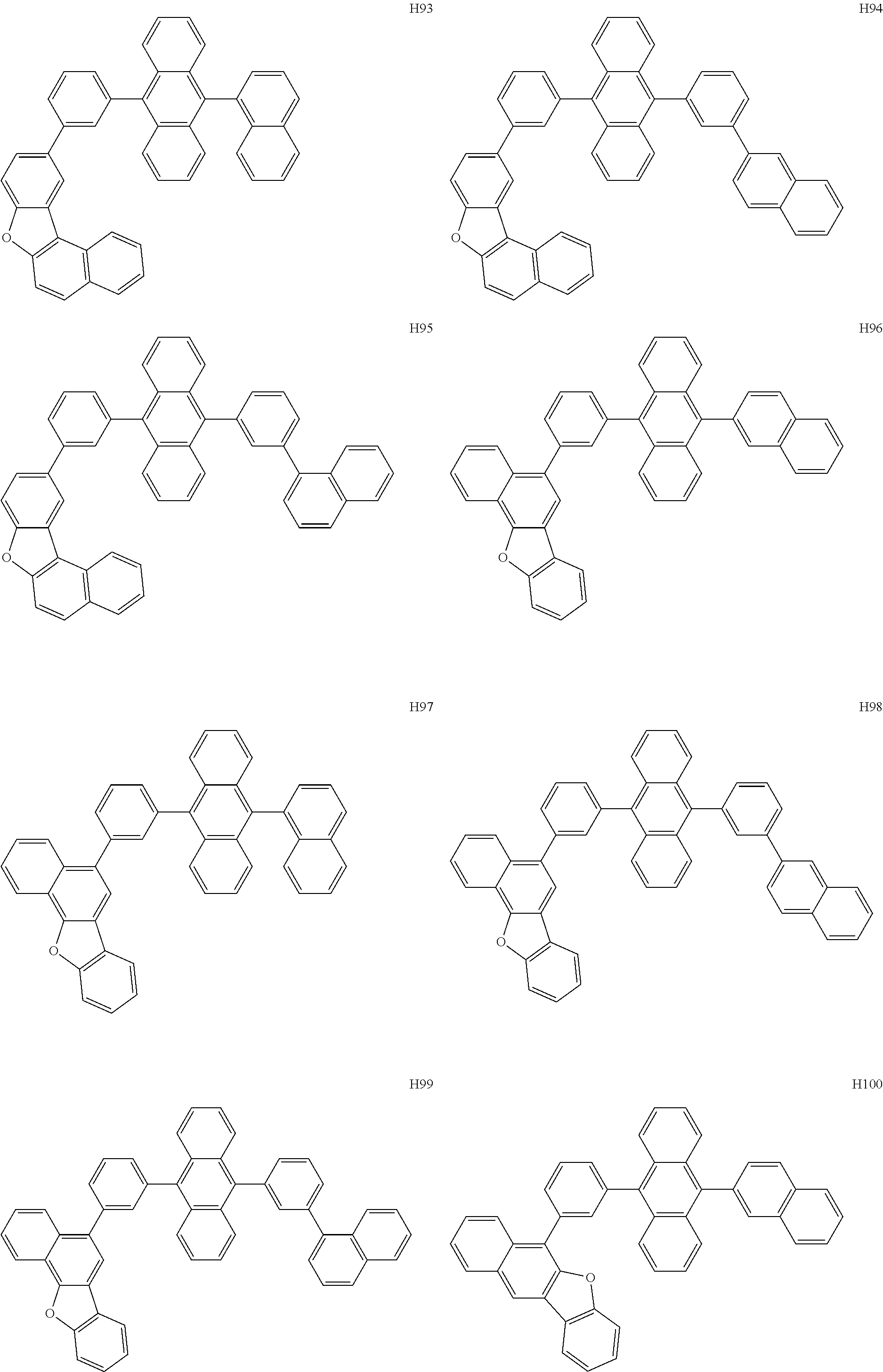

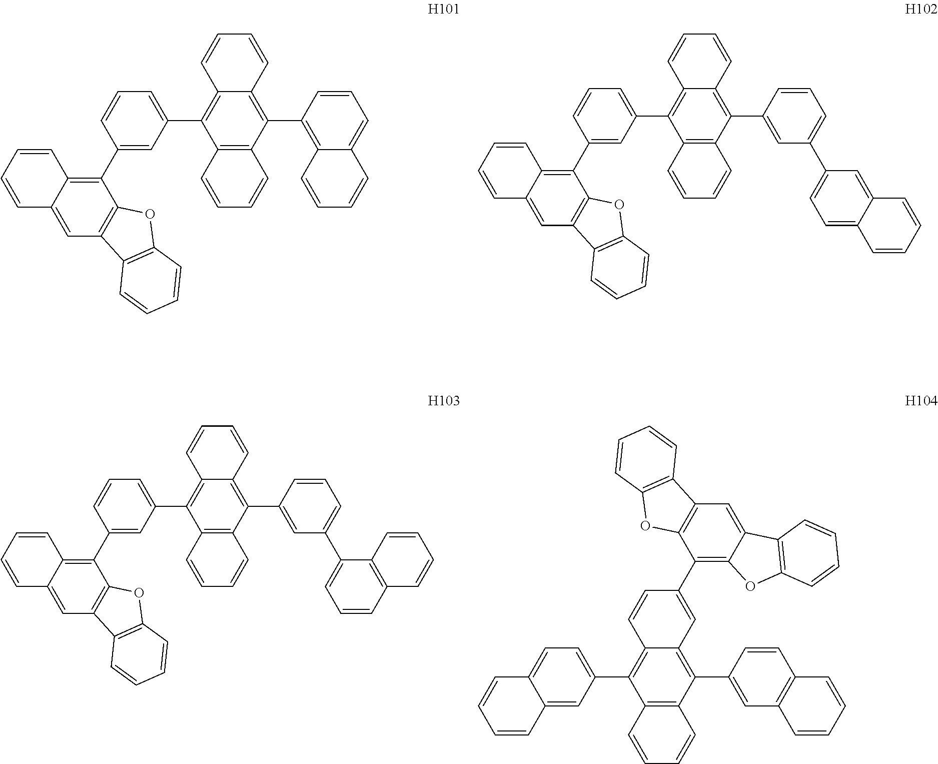 [SMILES: c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1 ; c1ccc2cc(-c3c4ccccc4c(-c4ccc5ccccc5c4)c4cc(-c5c6oc7ccccc7c6cc6c5oc5ccccc56)ccc34)ccc2c1]

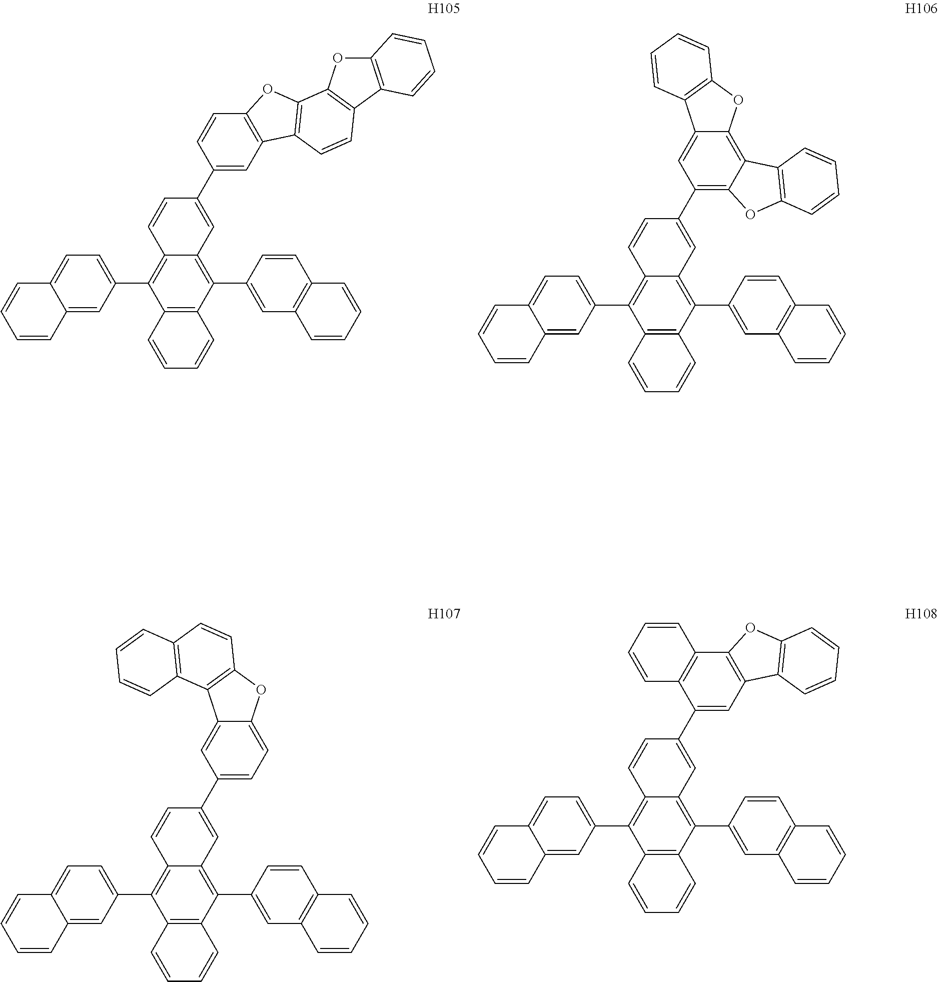 [SMILES: c1ccc2cc(-c3c4ccccc4c(-c4ccc5ccccc5c4)c4cc(-c5ccc6oc7c(ccc8c9ccccc9oc87)c6c5)ccc34)ccc2c1 ; c1ccc2cc(-c3c4ccccc4c(-c4ccc5ccccc5c4)c4cc(-c5cc6c7ccccc7oc6c6c5oc5ccccc56)ccc34)ccc2c1 ; c1ccc2cc(-c3c4ccccc4c(-c4ccc5ccccc5c4)c4cc(-c5ccc6oc7ccc8ccccc8c7c6c5)ccc34)ccc2c1 ; c1ccc2cc(-c3c4ccccc4c(-c4ccc5ccccc5c4)c4cc(-c5cc6c7ccccc7oc6c6ccccc56)ccc34)ccc2c1]

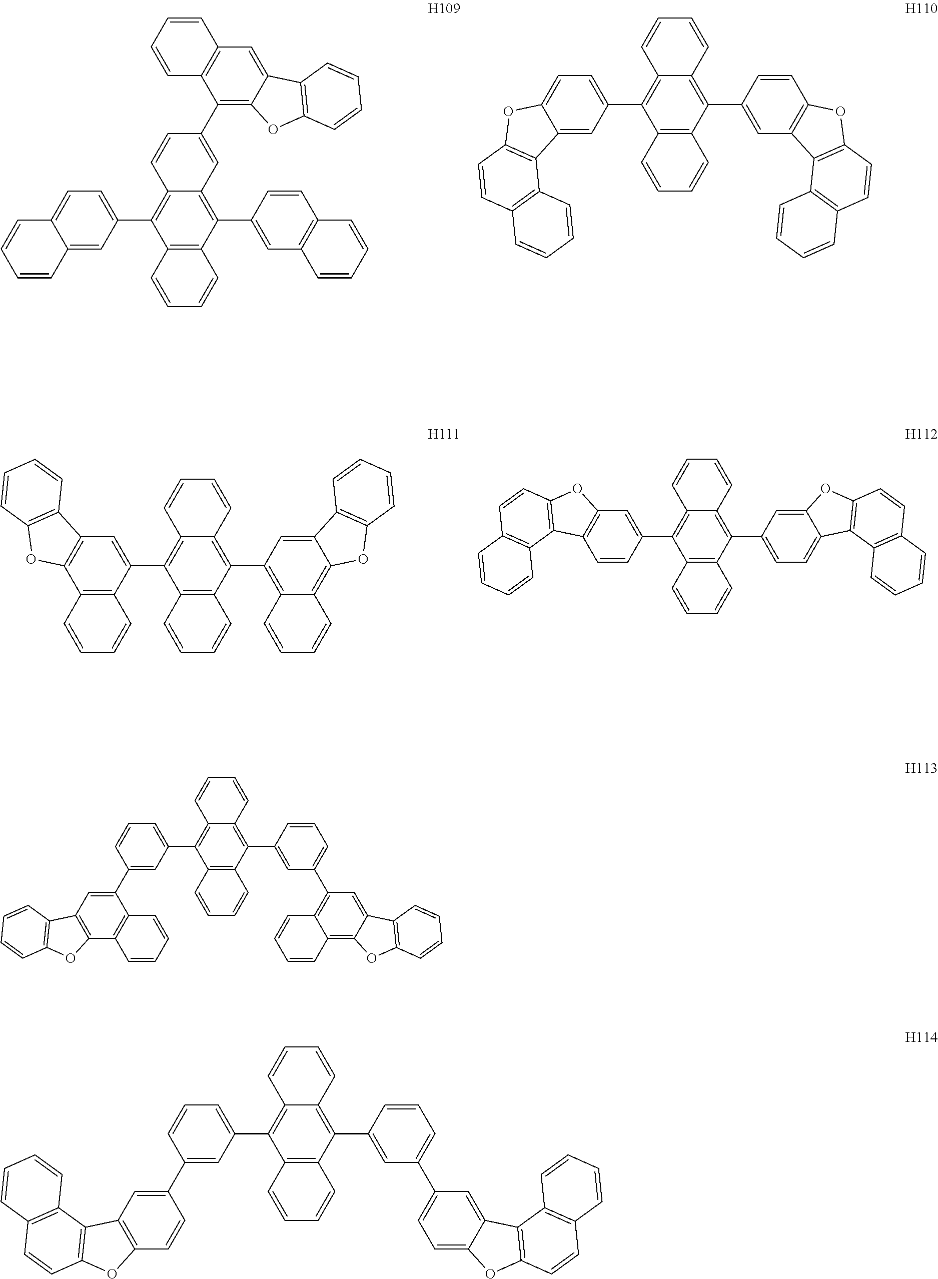

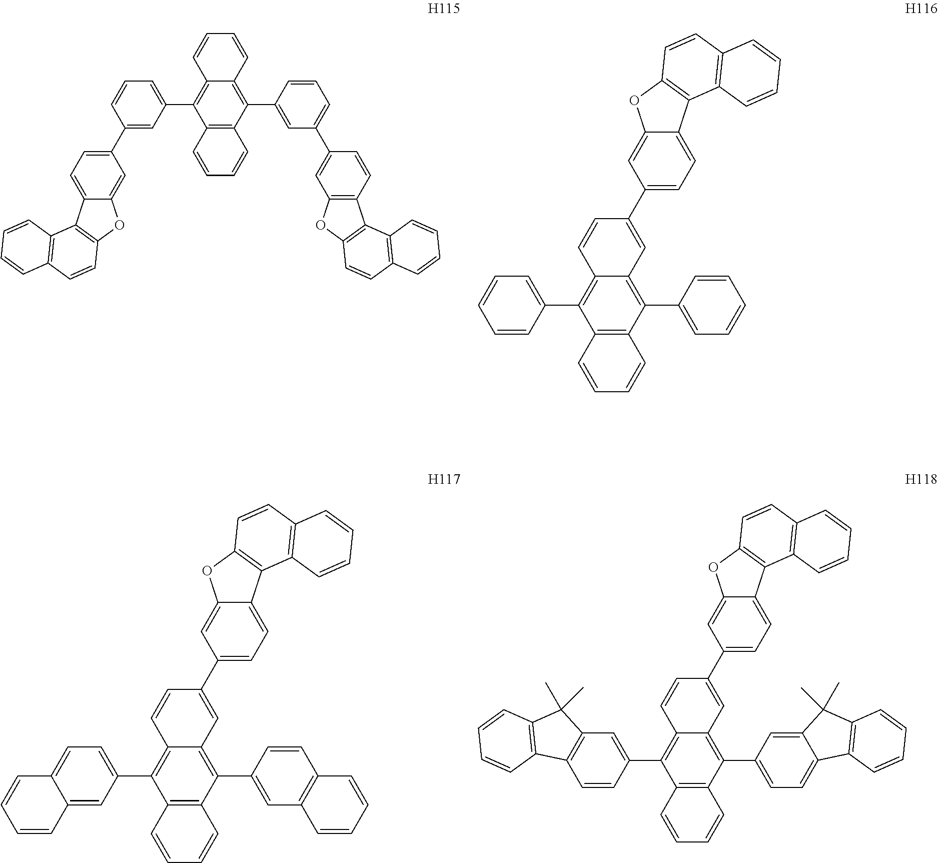 [SMILES: c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21]

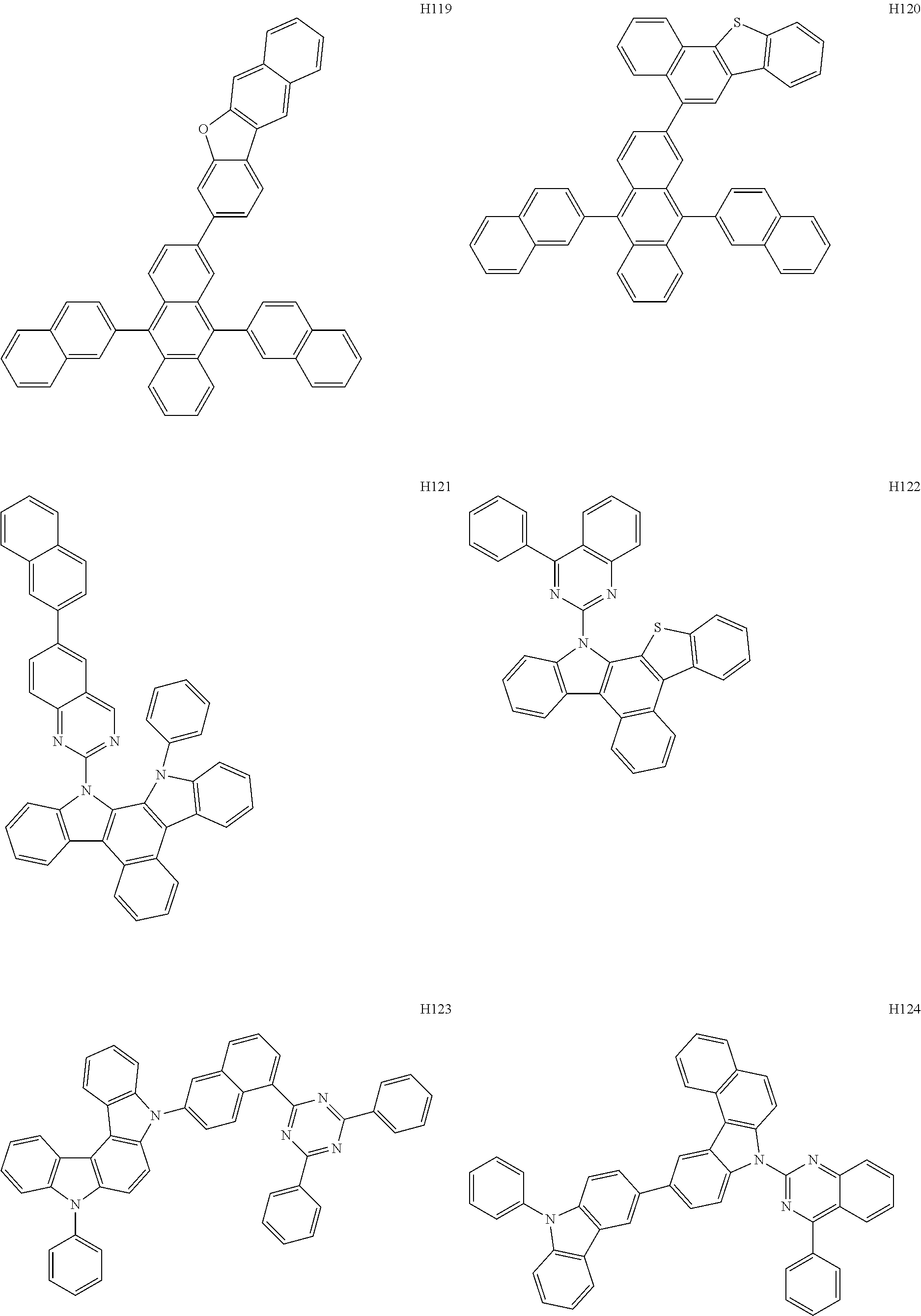

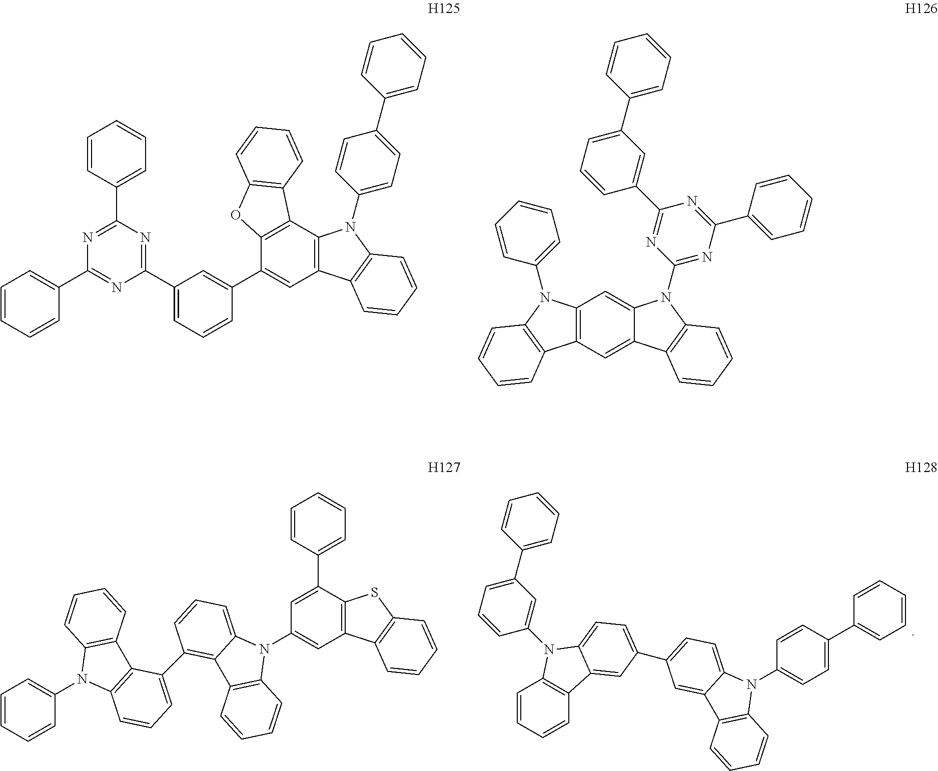 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2ccc(-n3c4ccccc4c4cc(-c5ccc6c(c5)c5ccccc5n6-c5cccc(-c6ccccc6)c5)ccc43)cc2)cc1]

### [Phosphorescent Dopant]

The phosphorescent dopant may include at least one transition metal as a center metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In embodiments, the phosphorescent dopant may include an organometallic complex represented by Formula 401:

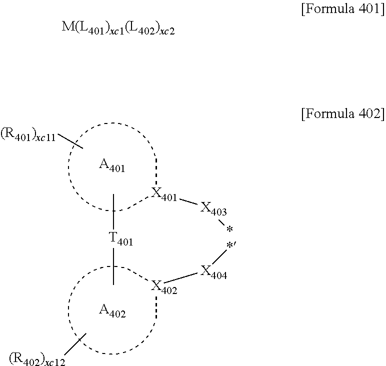

In Formulae 401 and 402,

M may be a transition metal (e.g., iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),

L₄₀₁ may be a ligand represented by Formula 402, and xc1 may be 1, 2, or 3, and in case that xc1 is 2 or greater, at least two L₄₀₁ (s) may be identical to or different from each other,

L₄₀₂ may be an organic ligand, and xc2 may be an integer from 0 to 4, and in case that xc2 is 2 or greater, at least two L₄₀₂(s) may be identical to or different from each other,

X₄₀₁ and X₄₀₂ may each independently be nitrogen or carbon, ring A₄₀₁ and ring A₄₀₂ may each independently be a C₃-C₆₀ carbocyclic group or a C₁-C₆₀ heterocyclic group,

T₄₀₁ may be a single bond, *—O—*′, *—S—*′, *—C(═O)*′, *—N(Q₄₁₁)-*′, *—C(Q₄₁₁)(Q₄₁₂)-*′, *—C(Q₄₁₁)═C(Q₄₁₂)-*′, *—C(Q₄₁₁)=*′, or *═C(Q₄₁₁)=*′,

X₄₀₃ and X₄₀₄ may each independently be a chemical bond (e.g., a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),

wherein Q₄₁₁ to Q₄₁₄ may each independently be the same as described in connection with Q₁ described herein,

R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),

wherein Q₄₀₁ to Q₄₀₃ may each independently be the same as described in connection with Q₁ described herein,

xc11 and xc12 may each independently be an integer from 0 to 10, and

* and *′ in Formula 402 each indicate a binding site to M in Formula 401.

For example, in Formula 402, X₄₀₁ may be nitrogen and X₄₀₂ may be carbon, or X₄₀₁ and X₄₀₂ may each be nitrogen.

In embodiments, in case that xc1 in Formula 402 is 2 or greater, two ring A₄₀₁ (s) of at least two L₄₀₁ (s) may optionally be bound via T₄₀₂ as a linking group, or two ring A₄₀₂(s) may optionally be bound via T₄₀₃ as a linking group (see Compounds PD1 to PD4 and PD7). T₄₀₂ and T₄₀₃ may each independently be the same as described herein in connection with T₄₀₁ described herein.

In Formula 401, L₄₀₂ may be any suitable organic ligand. For example, L₄₀₂ may be a halogen group, a diketone group (e.g., an acetylacetonate group), a carboxylic acid group (e.g., a picolinate group), —C(═O), an isonitrile group, —CN, a phosphorus group (e.g., a phosphine group or a phosphite group), or any combination thereof.

The phosphorescent dopant may be, for example, one of Compounds PD1 to PD39 or any combination thereof:

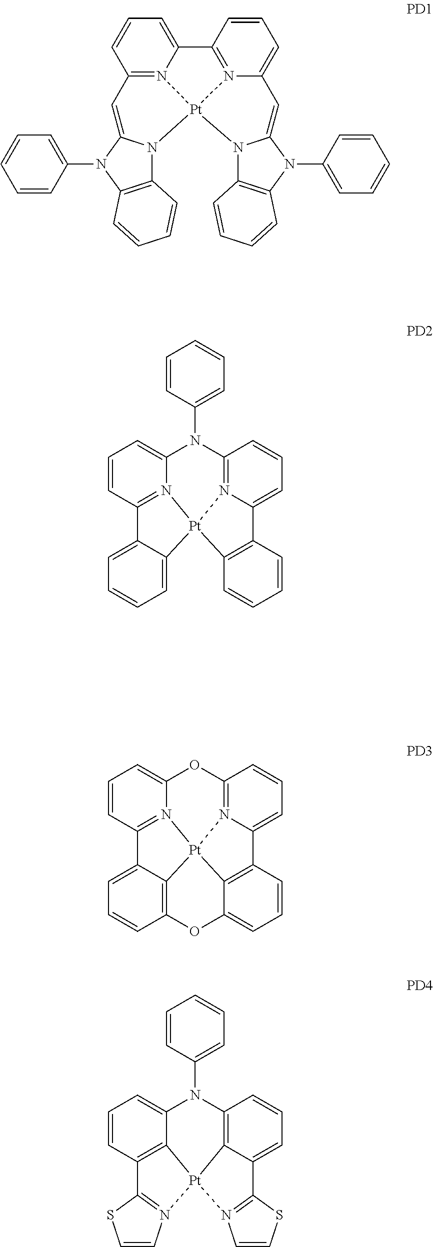

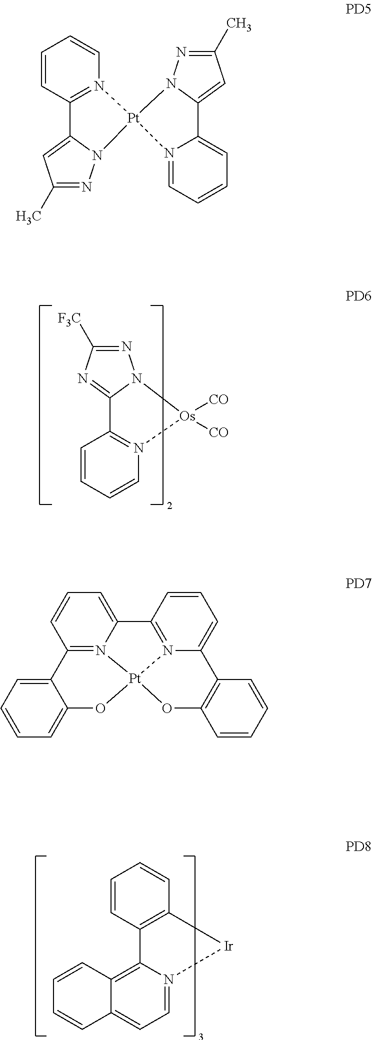

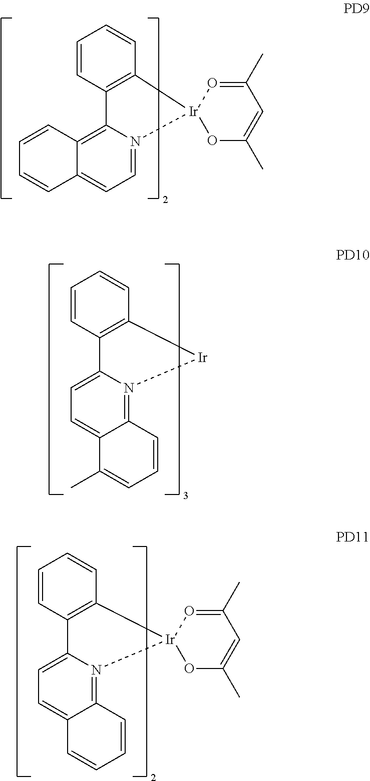

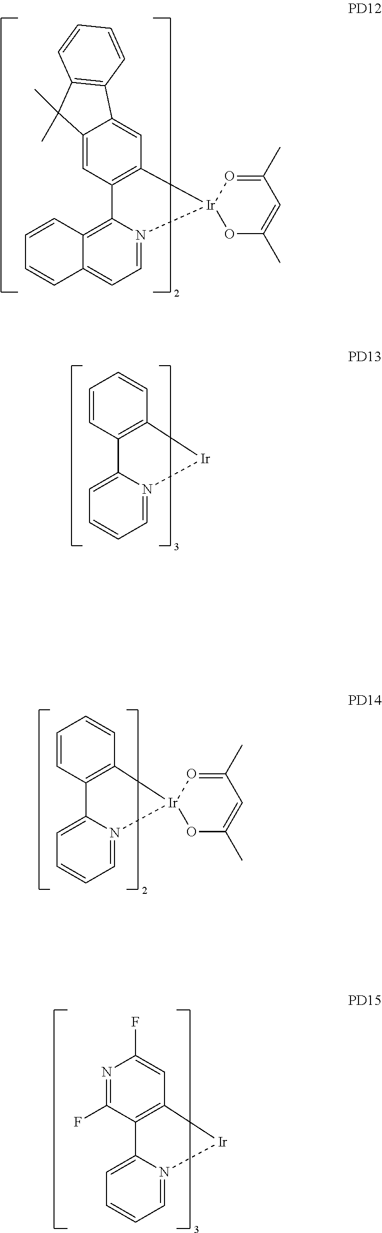

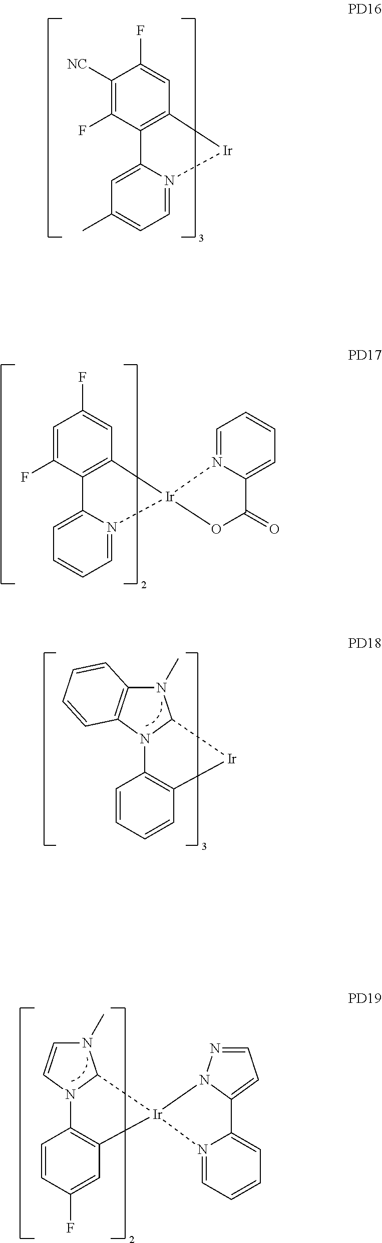

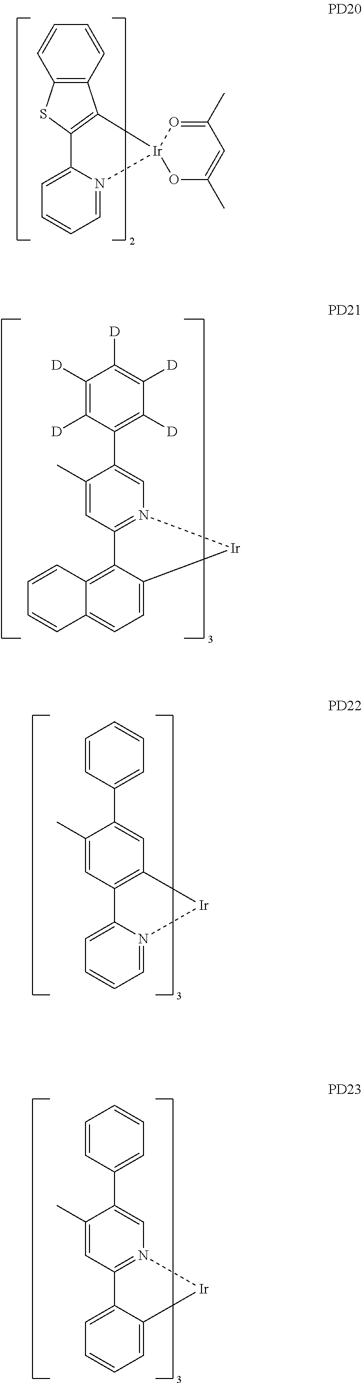

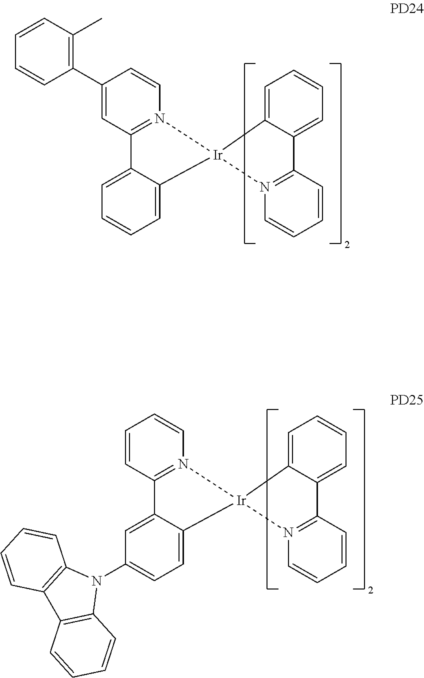

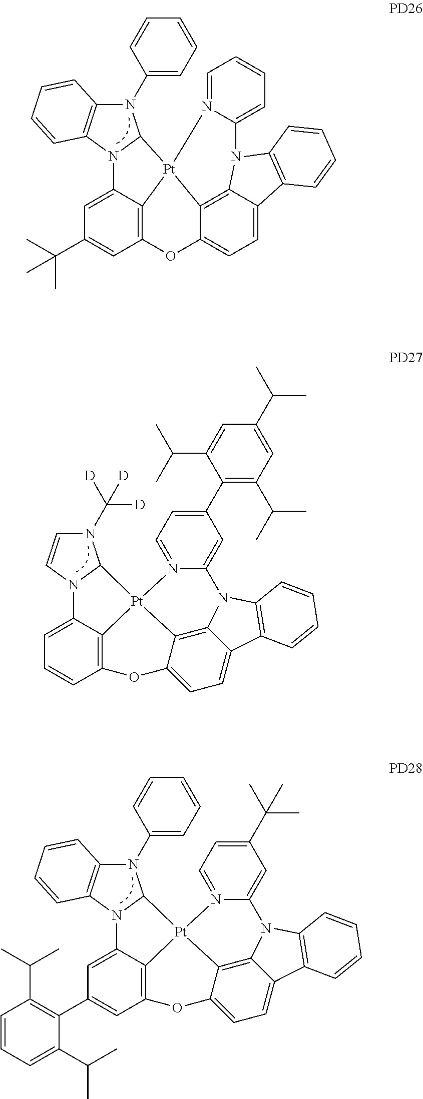

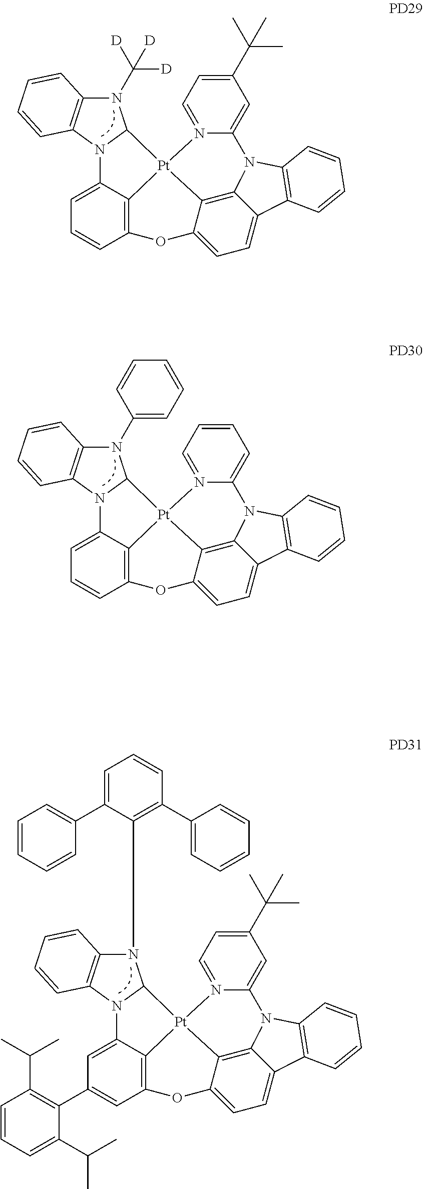

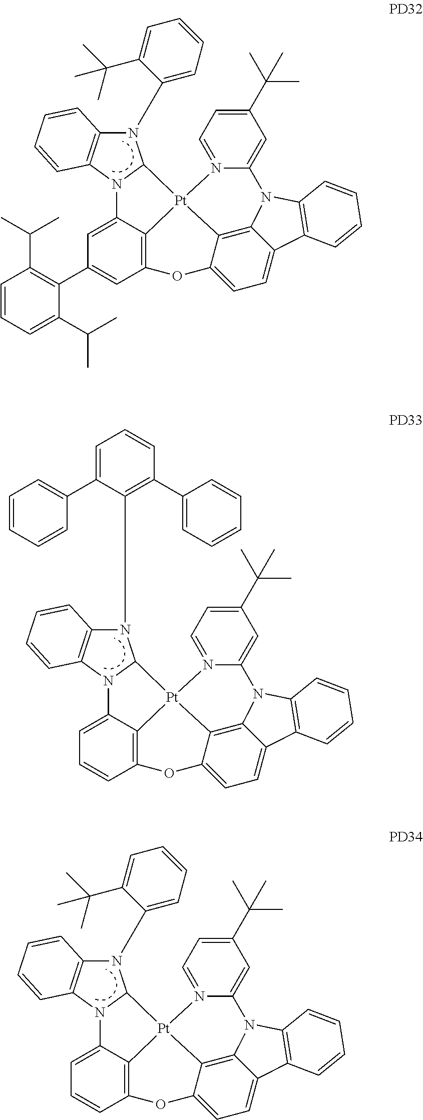

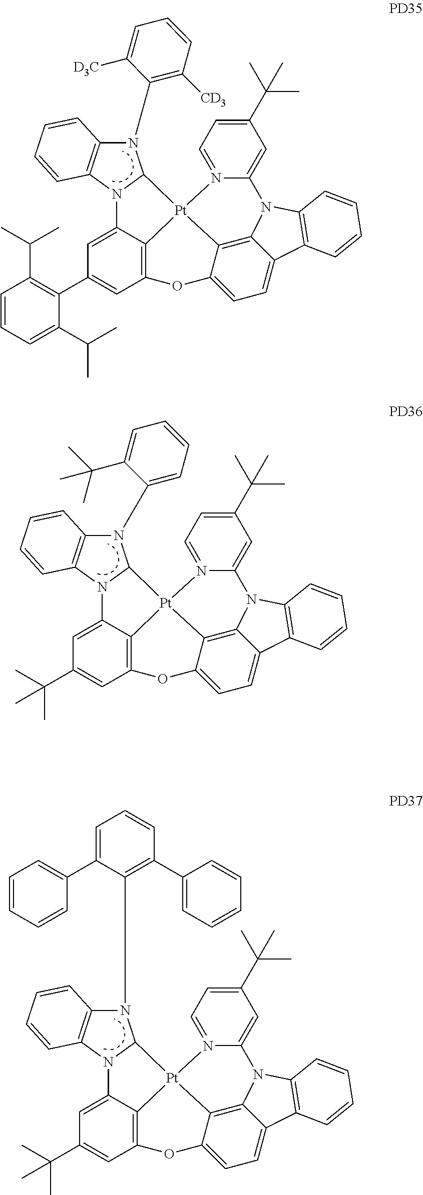

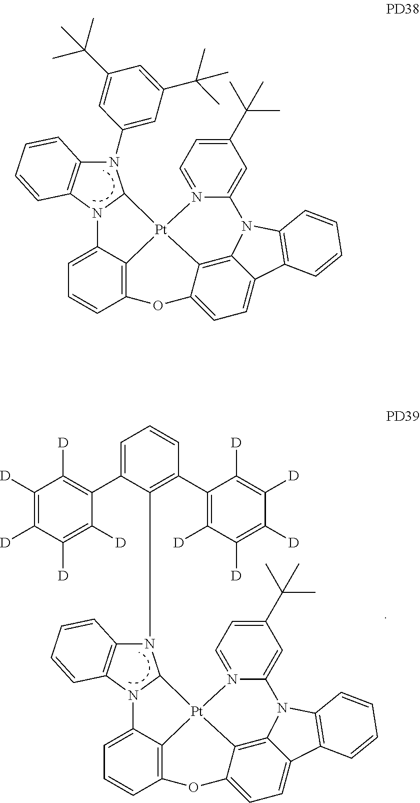

### [Fluorescent Dopant]

The fluorescent dopant may include an amine-containing compound, a styryl-containing compound, or any combination thereof:

In embodiments, the fluorescent dopant may include a compound represented by Formula 501:

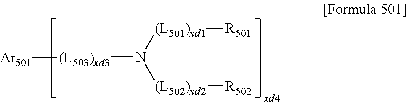

In Formula 501,

Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xd1 to xd3 may each independently be 0, 1, 2, or 3, and

xd4 may be 1, 2, 3, 4, 5, or 6.

In embodiments, in Formula 501, Ar₅₀₁ may include a condensed ring group (e.g., an anthracene group, a chrysene group, or a pyrene group) in which at least three monocyclic groups are condensed.

In embodiments, in Formula 501, xd4 may be 2.

In embodiments, the fluorescent dopant may include one of Compounds FD1 to FD36, DPVBi, DPAVBi, or any combination thereof:

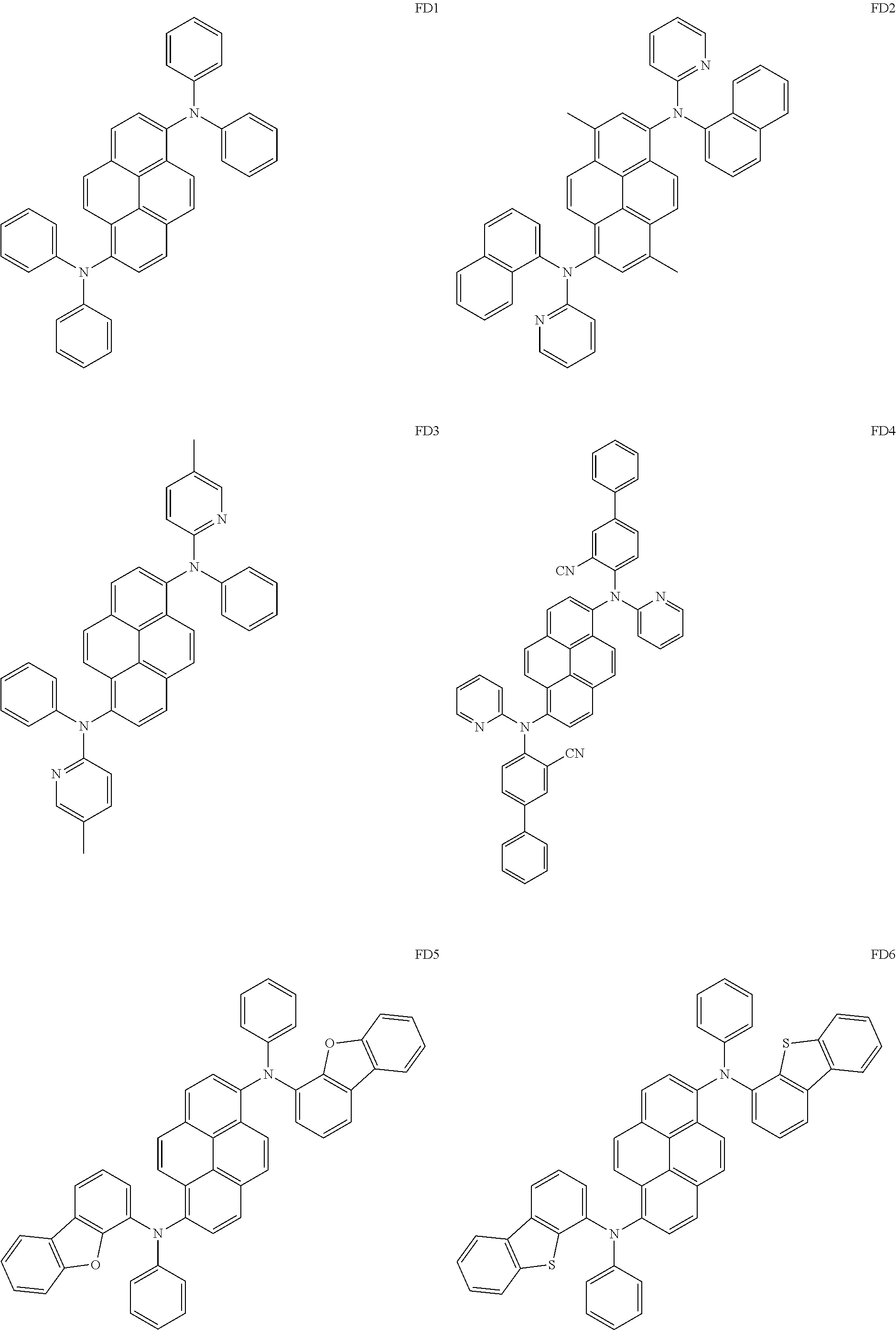

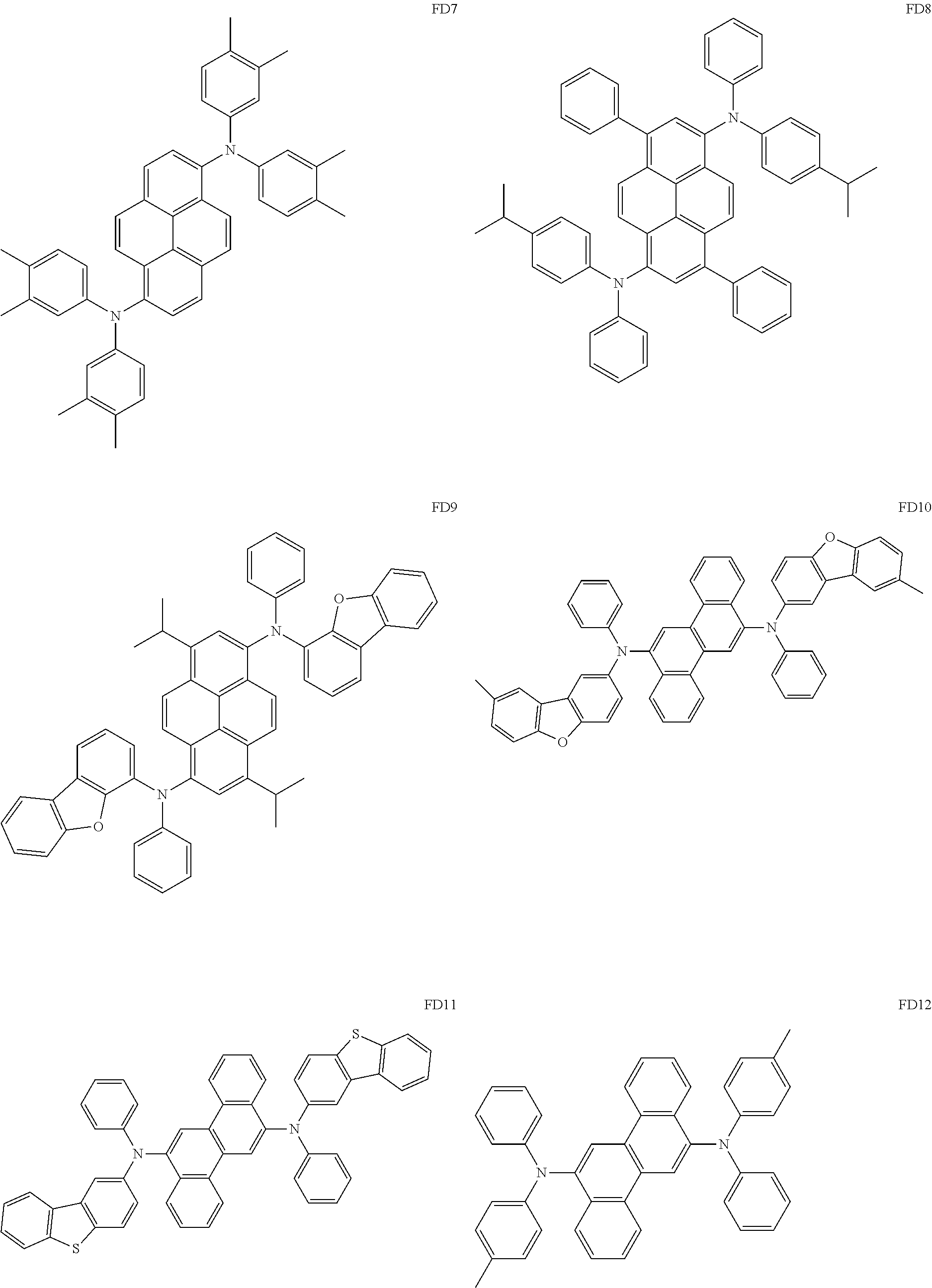

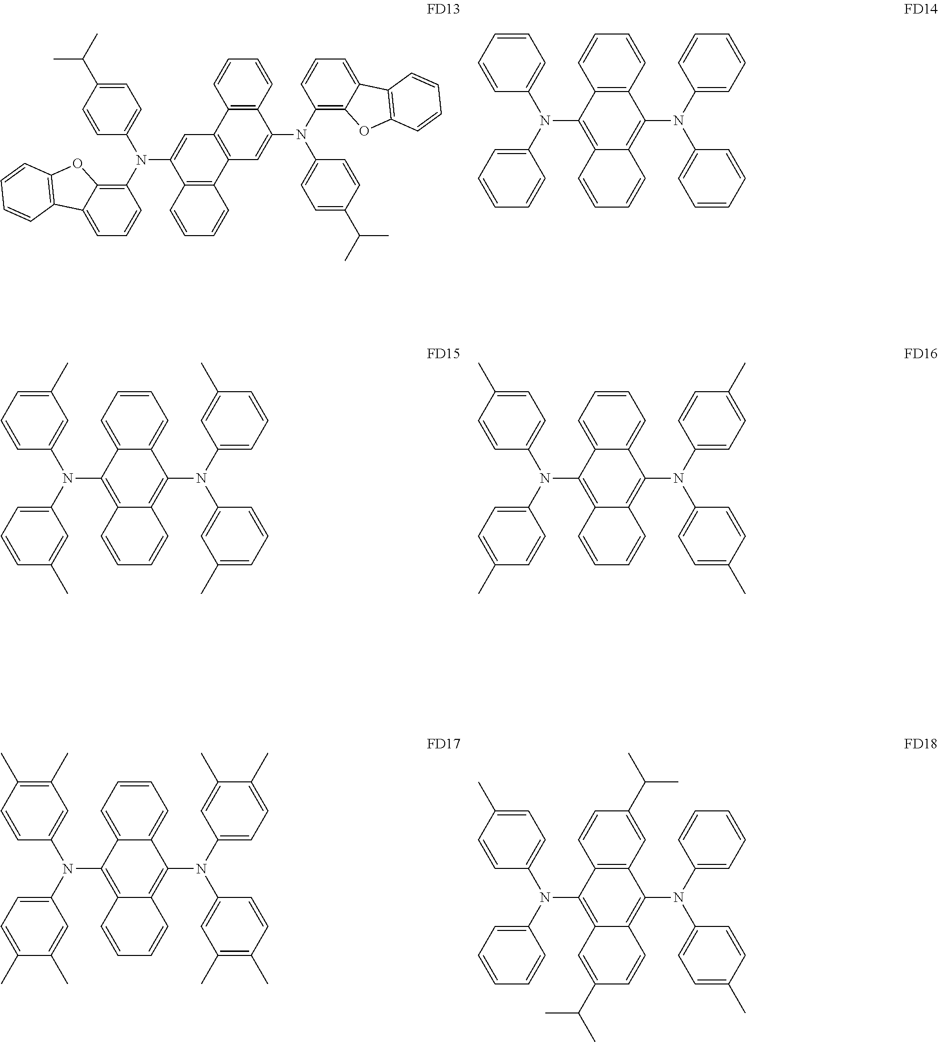

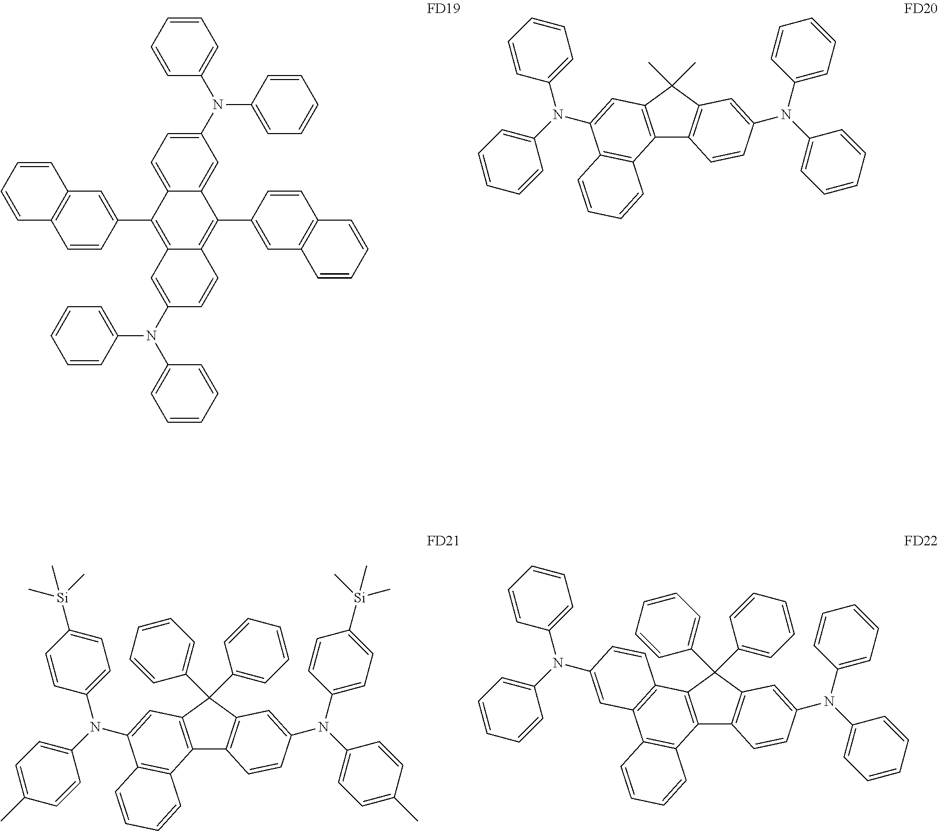

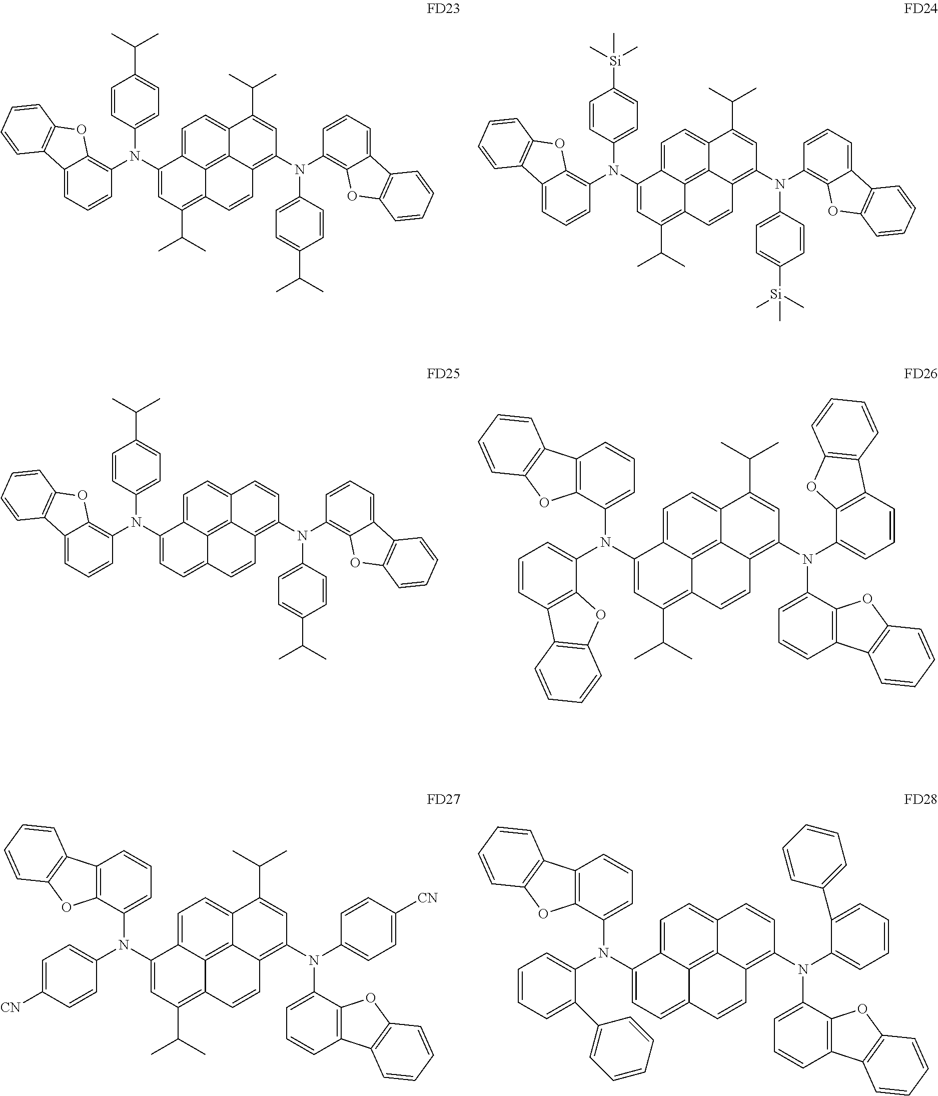

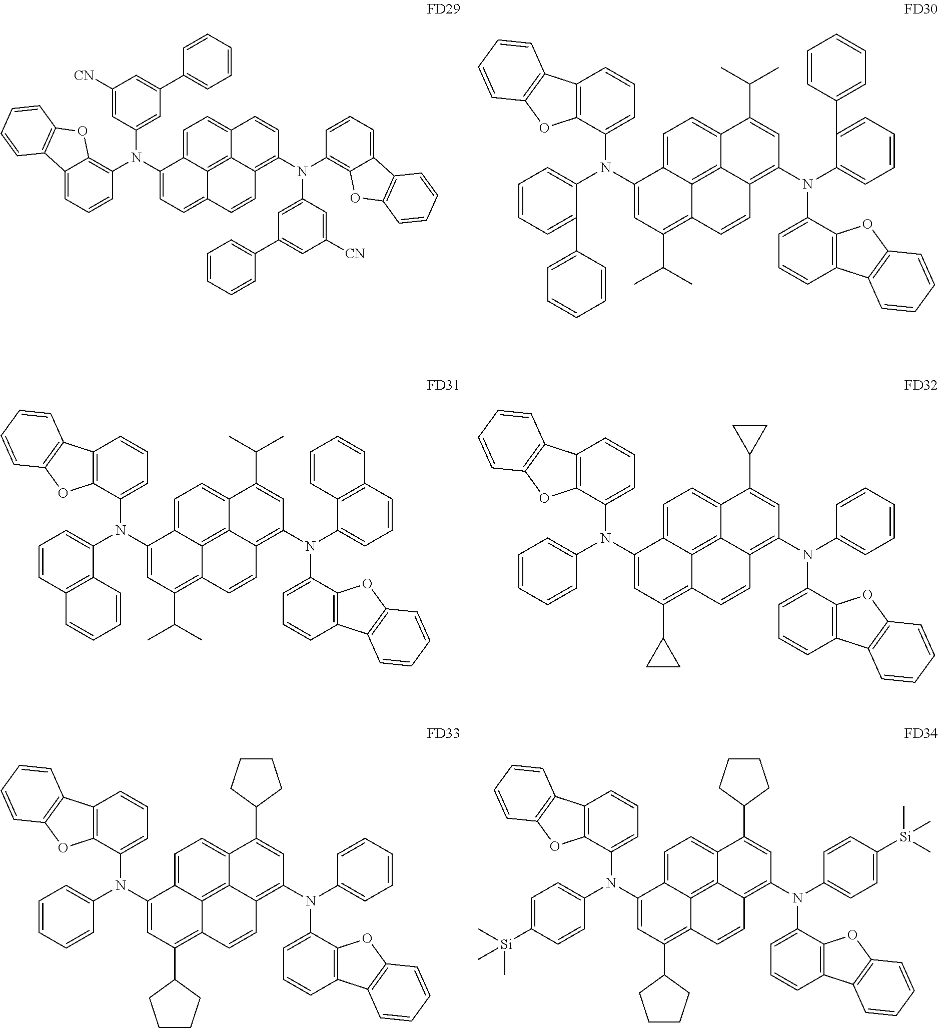

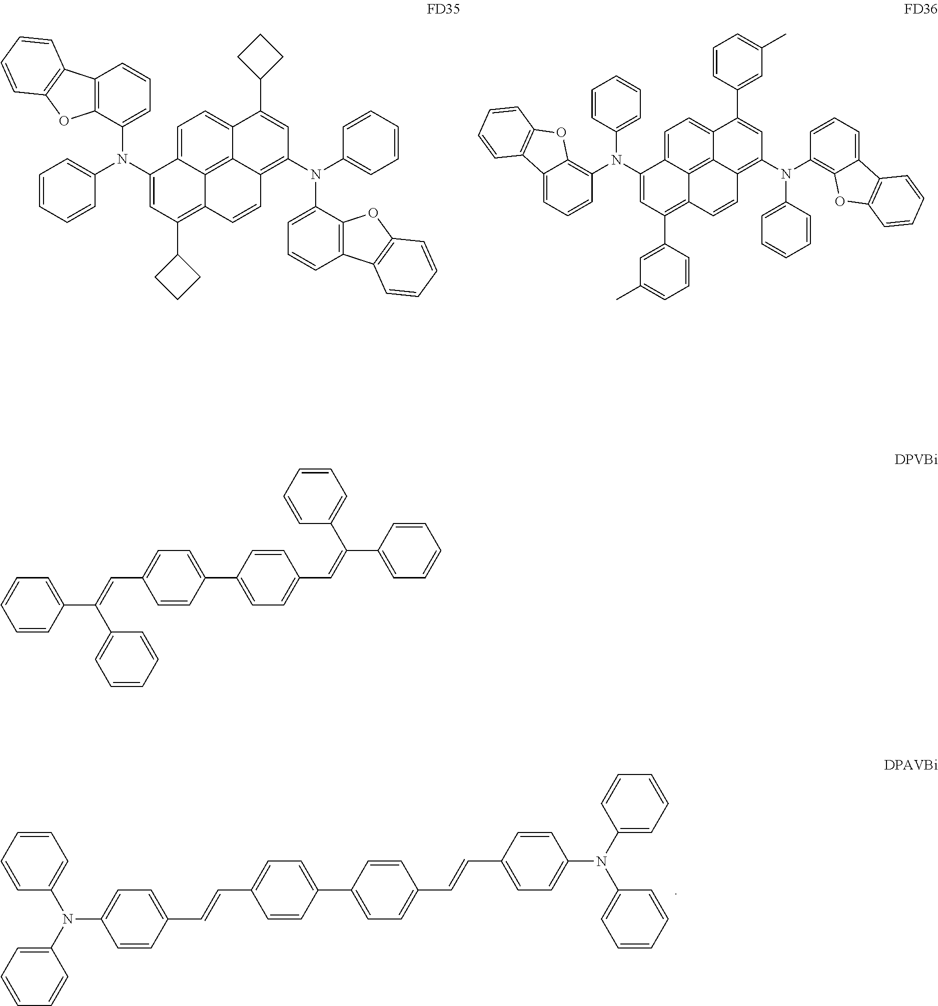

### Delayed Fluorescence Material

The emission layer may include a delayed fluorescence material.

The delayed fluorescence material may be any suitable compound that may emit delayed fluorescence according to a delayed fluorescence emission mechanism.

The delayed fluorescence material included in the emission layer may serve as a host or as a dopant, depending on the types of other materials included in the emission layer.

In embodiments, a difference between a triplet energy level (eV) of the delayed fluorescence material and a singlet energy level (eV) of the delayed fluorescence material may be in a range of about 0 eV to about 0.5 eV. In case that a difference between a triplet energy level (eV) of the delayed fluorescence material and a singlet energy level (eV) of the delayed fluorescence material is within this range, up-conversion from a triplet state to a singlet state in the delayed fluorescence material may be effectively occurred, thus improving luminescence efficiency and the like of the light-emitting device 10.

In embodiments, the delayed fluorescence material may include: a material including at least one electron donor (e.g., a π electron-rich C₃-C₆₀ cyclic group such as a carbazole group and the like) and at least one electron acceptor (e.g., a sulfoxide group, a cyano group, a π electron-deficient nitrogen-containing C₁-C₆₀ cyclic group, and the like); a material including a C₈-C₆₀ polycyclic group including at least two cyclic groups condensed to each other and sharing boron (B), or the like.

Examples of a delayed fluorescence material may include at least one of Compounds DF1 to DF14:

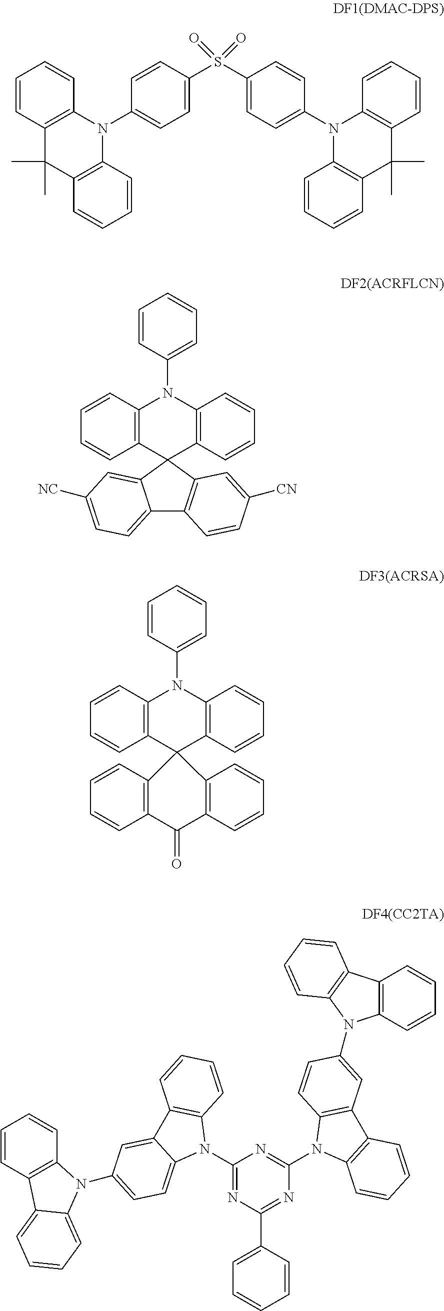

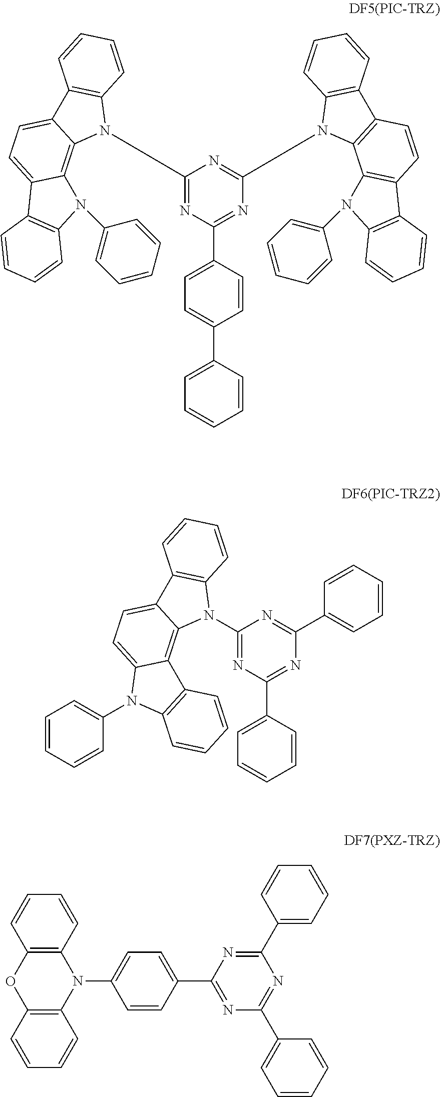 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-c3ccc(N4c5ccccc5Oc5ccccc54)cc3)n2)cc1]

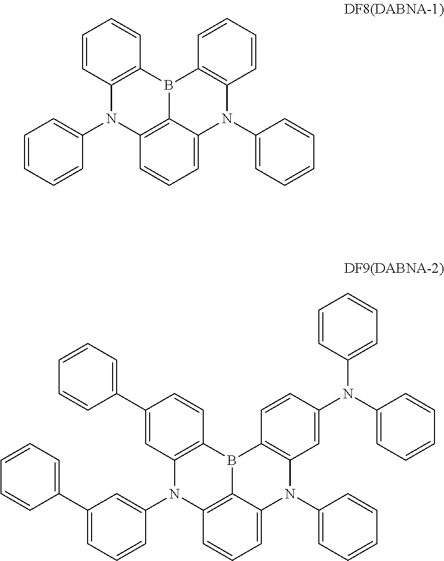 [SMILES: c1ccc(N2c3ccccc3B3c4ccccc4N(c4ccccc4)c4cccc2c43)cc1 ; c1ccc(-c2cccc(N3c4cc(-c5ccccc5)ccc4B4c5ccc(N(c6ccccc6)c6ccccc6)cc5N(c5ccccc5)c5cccc3c54)c2)cc1]

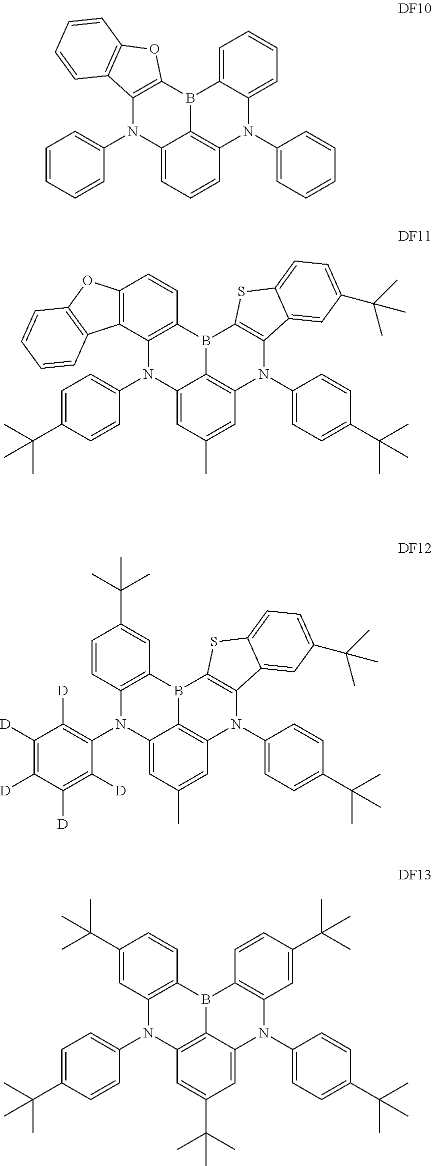

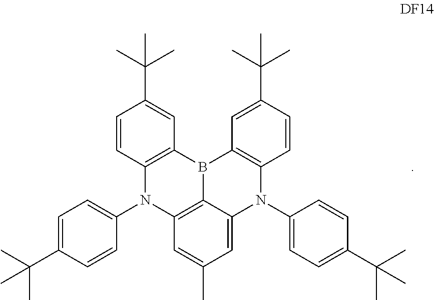 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1]

### [Quantum Dots]

The emission layer may include quantum dots.

In the specification, a quantum dot may be a crystal of a semiconductor compound. Quantum dots may emit light of various emission wavelengths depending on a size of the crystal. Quantum dots may emit light of various emission wavelengths by adjusting the element ratio in the quantum dot compound.

A diameter of the quantum dot may be, for example, in a range of about 1 nm to about 10 nm.

Quantum dots may be synthesized by a wet chemical process, an organic metal chemical vapor deposition process, a molecular beam epitaxy process, or any similar process.

The wet chemical process is a method of growing a quantum dot particle crystal by mixing a precursor material with an organic solvent. When the crystal grows, the organic solvent may naturally serve as a dispersant coordinated to a surface of the quantum dot crystal and may control the growth of the crystal. Thus, the wet chemical method may be more readily performed than a vapor deposition process such as a metal organic chemical vapor deposition (MOCVD) or a molecular beam epitaxy (MBE) process. Further, the growth of quantum dot particles may be controlled with a lower manufacturing cost.

The quantum dot may include a Group III-VI semiconductor compound; a Group II-VI semiconductor compound; a Group III-V semiconductor compound; a Group III-VI semiconductor compound; a Group I-III-VI semiconductor compound; a Group IV-VI semiconductor compound; a Group IV element or compound; or any combination thereof.

Examples of a Group II-VI semiconductor compound may include a binary compound such as CdS, CdSe, CdTe, ZnS, ZnSe, ZnTe, ZnO, HgS, HgSe, HgTe, MgSe, or MgS; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS; a quaternary compound such as CdZnSeS, CdZnSeTe, CdZnSTe, CdHgSeS, CdHgSeTe, CdHgSTe, HgZnSeS, HgZnSeTe, or HgZnSTe; or a combination thereof.

Examples of a Group III-V semiconductor compound may include a binary compound such as GaN, GaP, GaAs, GaSb, AlN, AlP, AlAs, AlSb, InN, InP, InAs, or InSb; a ternary compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, or InPSb; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb; or a combination thereof. In embodiments, the Group III-V semiconductor compound may further include a Group II element. Examples of a Group III-V semiconductor compound further including a Group II element may include InZnP, InGaZnP, InAlZnP, and the like.

Examples of a Group III-VI semiconductor compound may include a binary compound such as GaS, Ga₂S₃, GaSe, Ga₂Se₃, GaTe, InS, InSe, In₂Se₃, or InTe; or a ternary compound such as InGaS₃ or InGaSes; or any combination thereof.

Examples of a Group I-III-VI semiconductor compound may include a ternary compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, or AgAlO₂; a quaternary compound such as AgInGaS₂ or AgInGaSe₂; or any combination thereof.

Examples of a Group IV-VI semiconductor compound may include: a binary compound such as SnS, SnSe, SnTe, PbS, PbSe, or PbTe; a ternary compound such as SnSeS, SnSeTe, SnSTe, PbSeS, PbSeTe, PbSTe, SnPbS, SnPbSe, or SnPbTe; a quaternary compound such as SnPbSSe, SnPbSeTe, or SnPbSTe; or a combination thereof.

Examples of a Group IV element or compound may include: a single element material such as Si or Ge; a binary compound such as SiC or SiGe; or a combination thereof.

Individual elements included in the multi-element compound, such as a binary compound, a ternary compound, or a quaternary compound, may be present in a particle thereof at a uniform concentration or at a non-uniform concentration. The Formula refers to the types of elements included in a compound, and the element ratio in the compound may be different. For example, AgInGaS₂ may be AgInₓGa₁₋ₓS₂ (where x is a real number between 0 and 1).

The quantum dot may have a single structure in which the concentration of each element included in the quantum dot is uniform or a core-shell structure. In embodiments, in case that the quantum dot has a core-shell structure, materials included in the core may be different from materials included in the shell.

The shell of the quantum dot may serve as a protective layer for preventing chemical denaturation of the core to maintain semiconductor characteristics and/or may serve as a charging layer for imparting electrophoretic characteristics to the quantum dot. The shell may be a single-layer or a multi-layer. An interface between a core and a shell may have a concentration gradient where a concentration of elements present in the shell decreases toward the core.

Examples of a shell of the quantum dot may include a metal oxide, a non-metal oxide, a semiconductor compound, or a combination thereof. Examples of a metal oxide or a non-metal oxide may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound such as MgAl₂O₄, CoFe₂O₄, NiFe₂O₄, or CoMn₂O₄; or any combination thereof. Examples of a semiconductor compound may include a Group III-VI semiconductor compound; a Group II-VI semiconductor compound; a Group III-V semiconductor compound; a Group III-VI semiconductor compound; a Group I-III-VI semiconductor compound, a Group IV-VI semiconductor compound; or any combination thereof. In embodiments, examples of a semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or any combination thereof.

Individual elements included in the multi-element compound, such as a binary compound and a ternary compound, may be present in a particle thereof at a uniform or non-uniform concentration. The Formula may refer to the types of elements included in a compound, and the element ratio in the compound may be different.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. In case that the FWHM of the quantum dot is within any of the above ranges, color purity or color reproducibility may be improved. Light emitted through a quantum may be emitted in all directions, so that an optical viewing angle may be improved.

In an embodiment, the quantum dot may be in the form of a spherical particle, a pyramidal particle, a multi-arm particle, a cubic nanoparticle, a nanotube particle, a nanowire particle, a nanofiber particle, or a nanoplate particle.

By adjusting the size of the quantum dot or the element ratio in the quantum dot compound, the energy band gap may also be adjusted, thereby obtaining light of various wavelengths in the quantum dot emission layer. Therefore, by using the quantum dots (of various sizes or different element ratios in the quantum dot compound), a light-emitting device that may emit light of various wavelengths may be realized. In embodiments, the size of the quantum dot or the adjustment of the element ratio in the quantum dot compound may be selected such that the quantum dot may emit red, green, and/or blue light. The quantum dot may be selected such that the quantum dot may emit white light by combining various light colors.

### [Electron Transport Region in Interlayer 130]

The electron transport region may have a structure consisting of a layer consisting of a single material, a structure consisting of a layer including different materials, or a structure having multiple layers including different materials.

The electron transport region may include a buffer layer, a hole blocking layer, an electron control layer, an electron transport layer, or an electron injection layer.

In embodiments, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein the layers of each structure may be stacked on an emission layer in its respective stated order, but the structure of the electron transport region is not limited thereto.

The electron transport region (e.g., a buffer layer, a hole blocking layer, an electron control layer, or an electron transport layer in the electron transport region) may include a metal-free compound including at least one π electron-deficient nitrogen-containing C₁-C₆₀ cyclic group.

In embodiments, the electron transport region may include a compound represented by Formula 601:

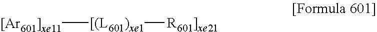

In Formula 601,

Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xe11 may be 1, 2, or 3,

xe1 may be 0, 1, 2, 3, 4, or 5,

R₆₀₁ may be C₃-C₆₀ carbocyclic group unsubstituted or substituted with at least one R₁₀ₐ, a C₁-C₆₀ heterocyclic group unsubstituted or substituted with at least one R10a, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),

wherein Q₆₀₁ to Q₆₀₃ may each independently be the same as described in connection with Q₁ described herein,

xe21 may be 1, 2, 3, 4, or 5, and

at least one of Ar₆₀₁, L₆₀₁, and R₆₀₁ may each independently be a π electron-deficient nitrogen-containing C₁-C₆₀ cyclic group unsubstituted or substituted with at least one R₁₀ₐ.

For example, in Formula 601, in case that xe11 is 2 or greater, at least two Ar₆₀₁ (s) may be bound to each other via a single bond.

In embodiments, in Formula 601, Ar₆₀₁ may be a substituted or unsubstituted anthracene group.

In embodiments, the electron transport region may include a compound represented by Formula 601-1:

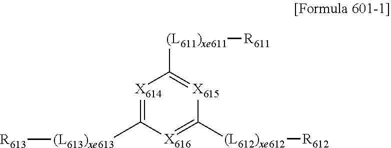

In Formula 601-1,

X₆₁₄ may be N or C(R₆₁₄), X₆₁₅ may be N or C(R₆₁₅), X₆₁₆ may be N or C(R₆₁₆), and at least one of X₆₁₄ to X₆₁₆ may each be N,

L₆₁₁ to L₆₁₃ may each independently be the same as described in connection with L₆₀₁ described herein,

xe611 to xe613 may each independently be the same as described in connection with xe1 described herein,

R₆₁₁ to R₆₁₃ may each independently be the same as described in connection with R₆₀₁ described herein, and

R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In embodiments, in Formulae 601 and 601-1, xe1 and xe611 to xe613 may each independently be 0, 1, or 2.

In embodiments, an electron transport region may include one of Compounds ET1 to ET45, 2,9-dimethyl-4,7-diphenyl-1,10-phenanthroline (BCP), 4,7-diphenyl-1,10-phenanthroline (Bphen), Alq₃, BAIq, TAZ, NTAZ, TSPO1, TPBI, or any combination thereof:

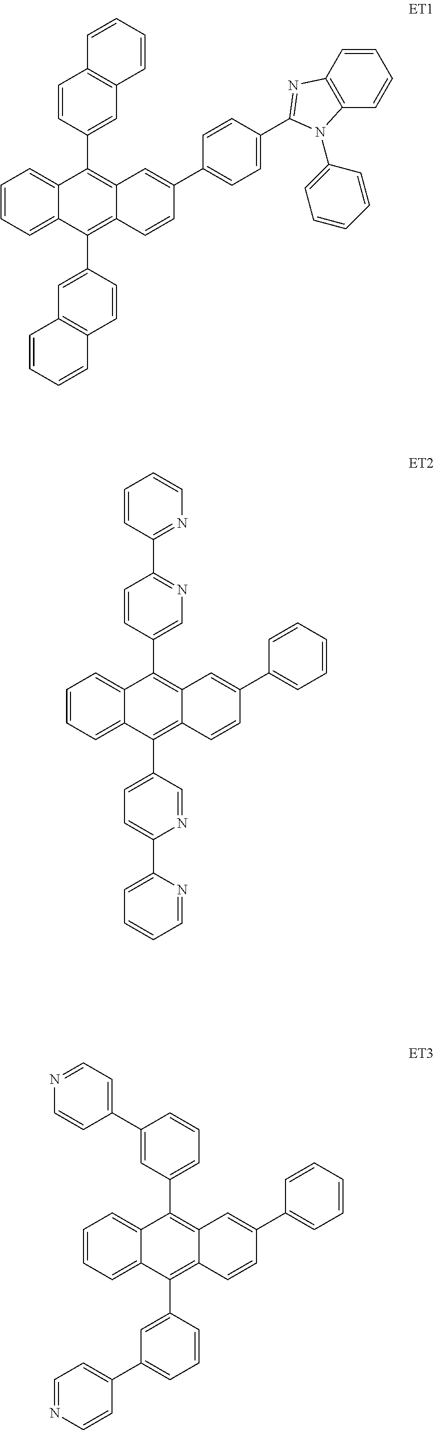 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

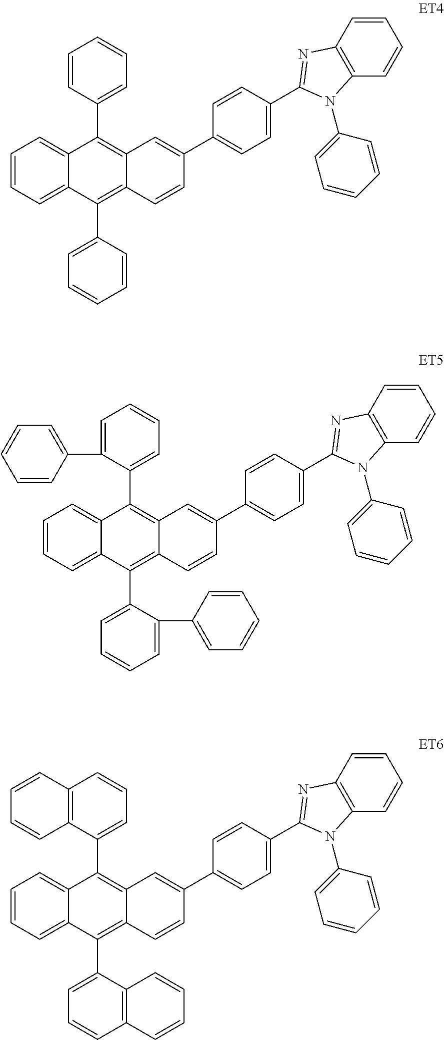 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

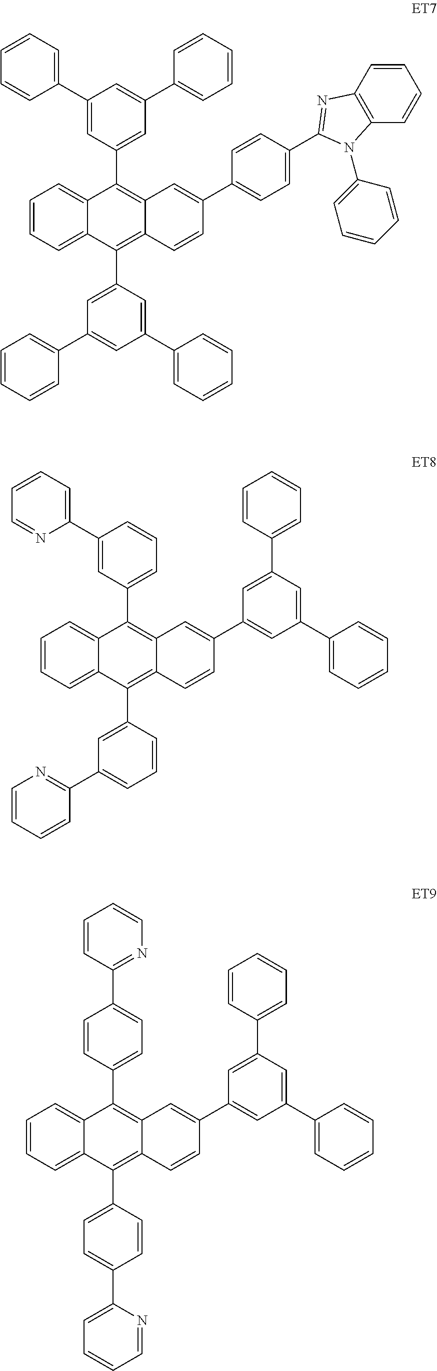 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

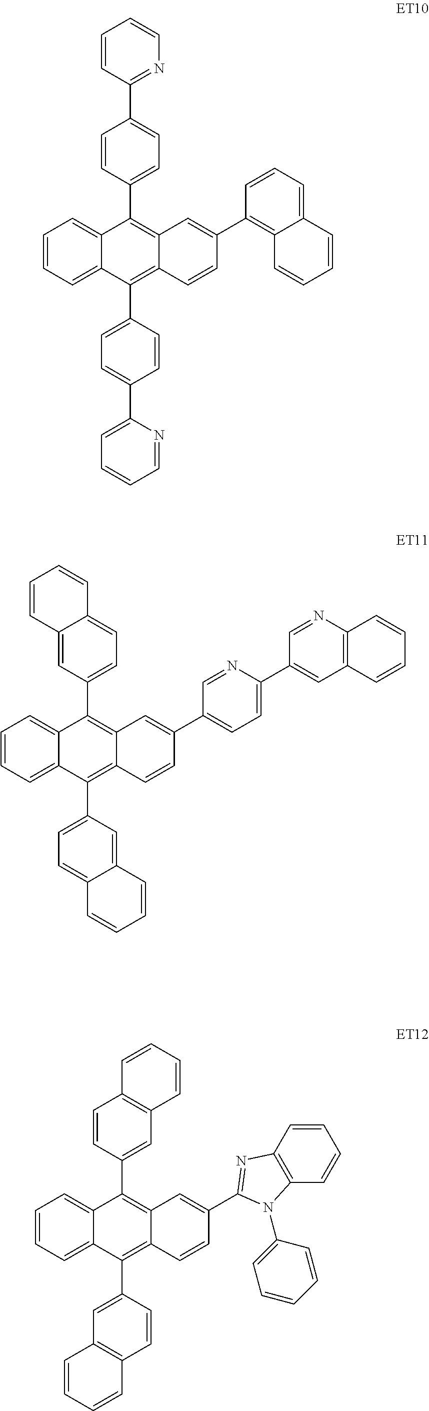 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

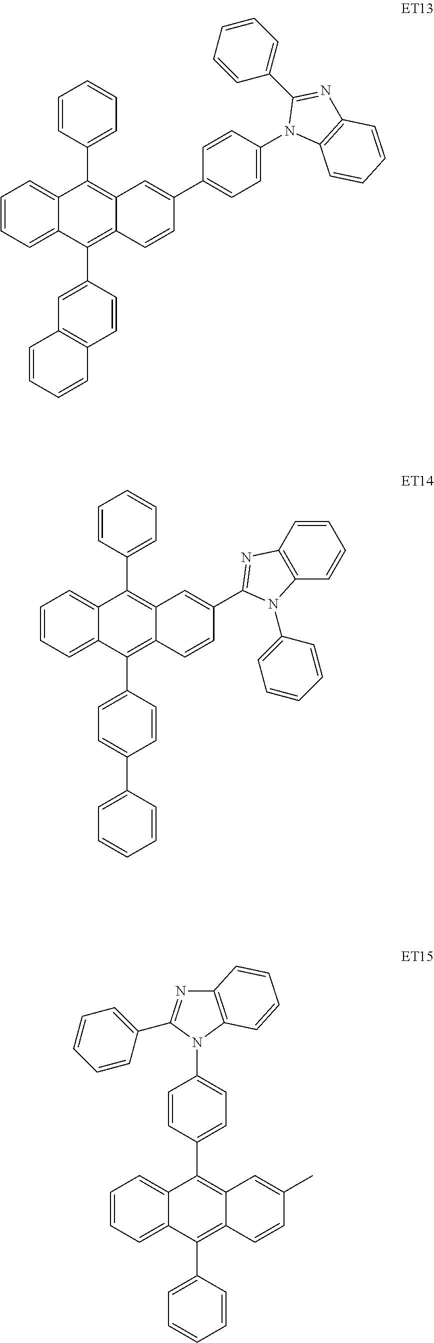 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

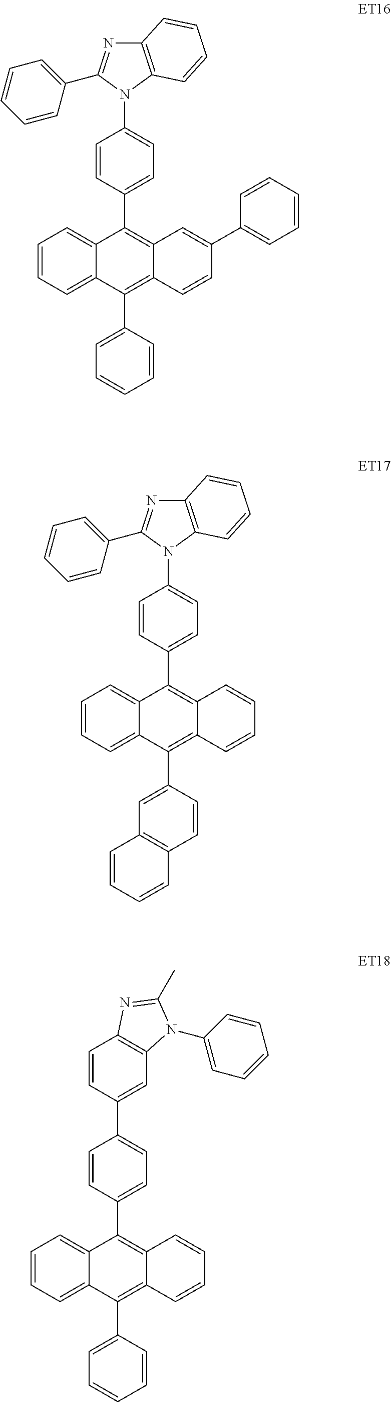 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

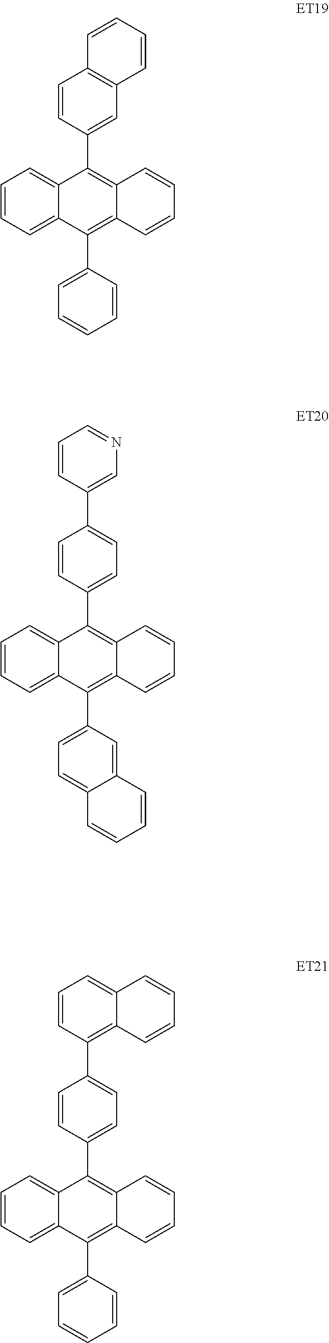

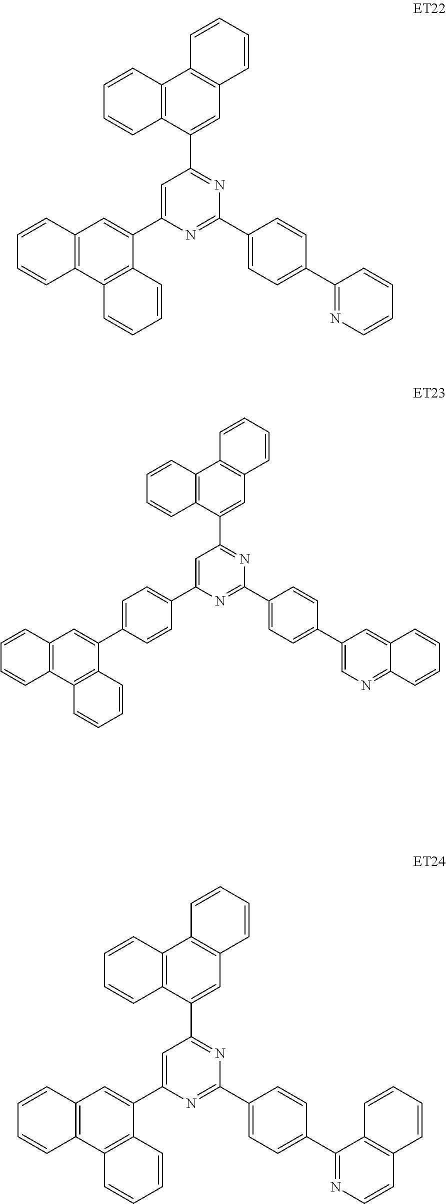 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

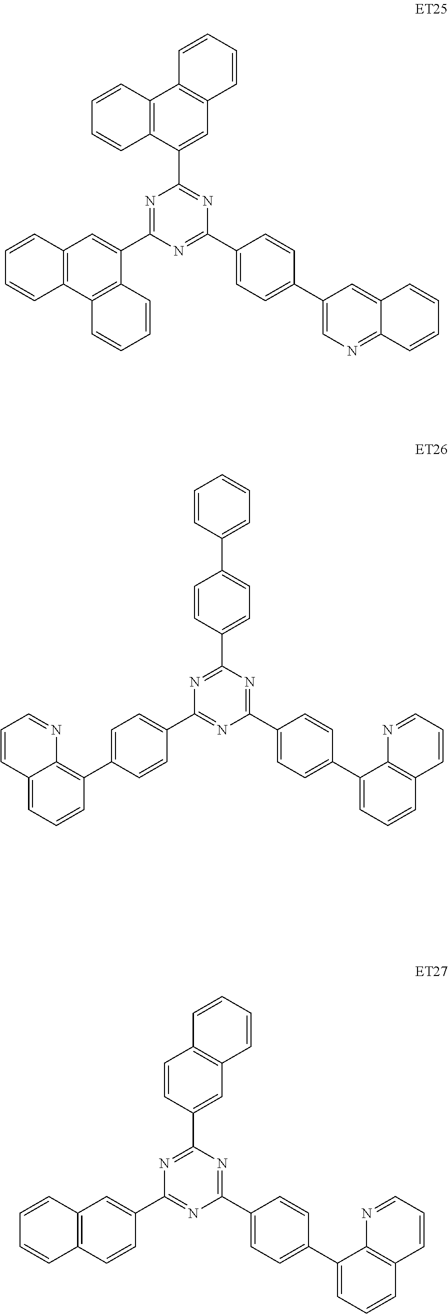 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

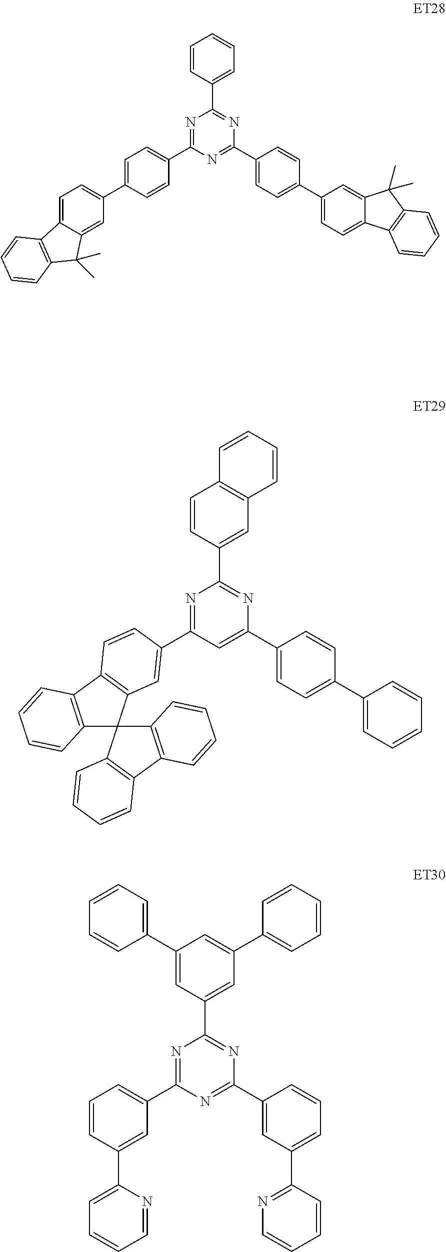 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

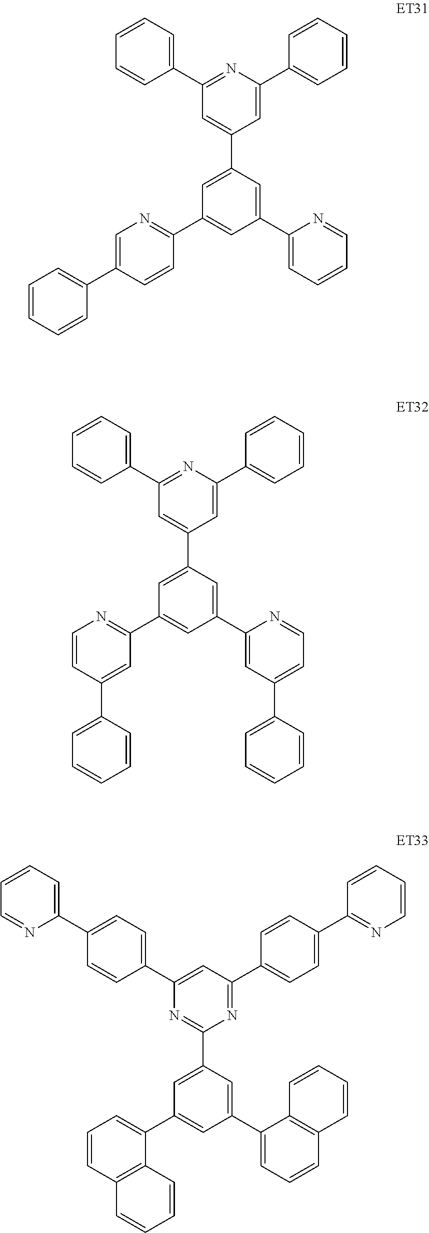 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

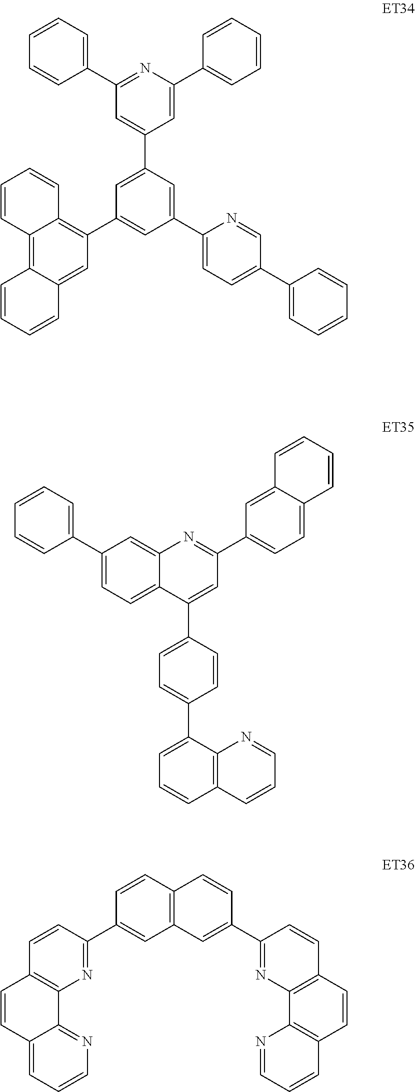 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

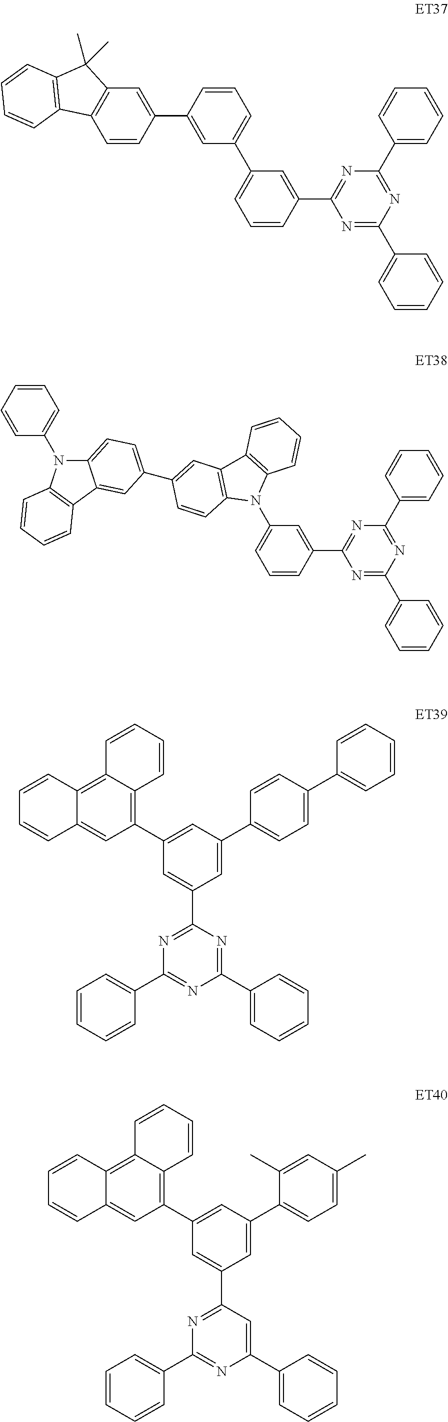 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1]

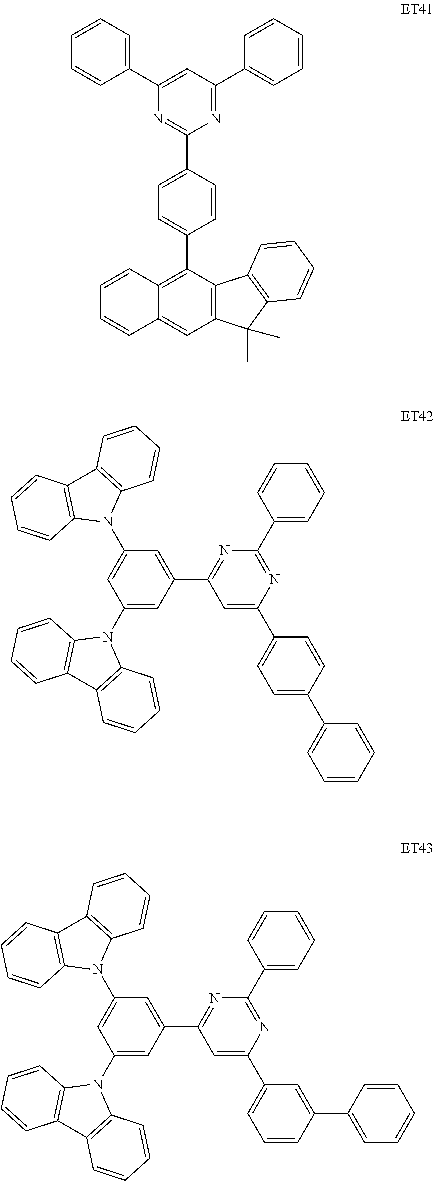 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

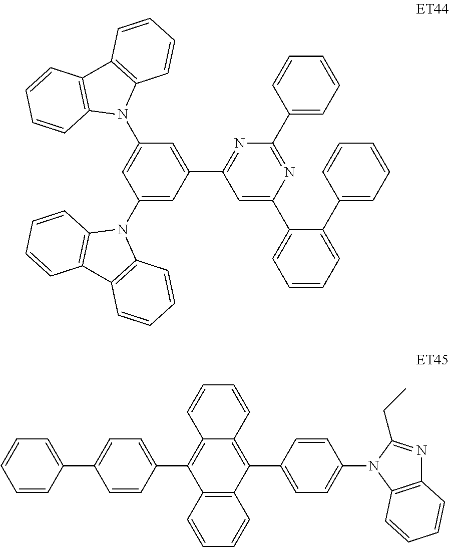 [SMILES: c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

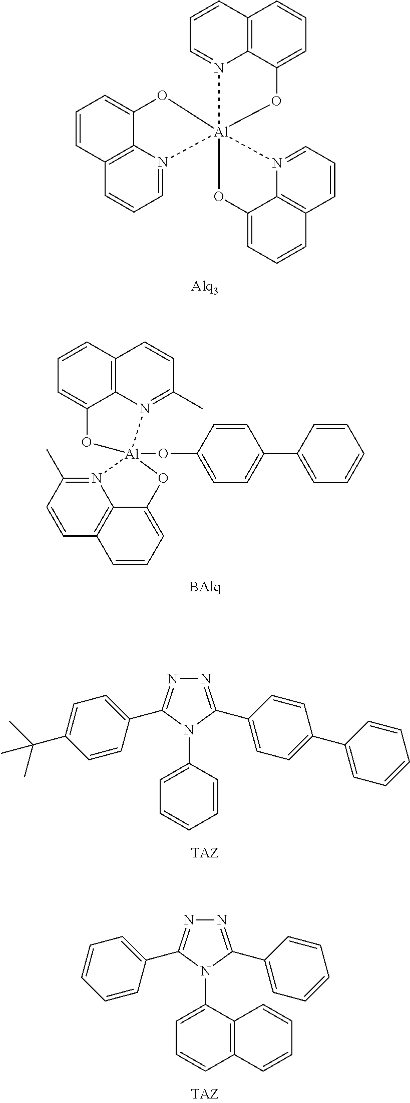

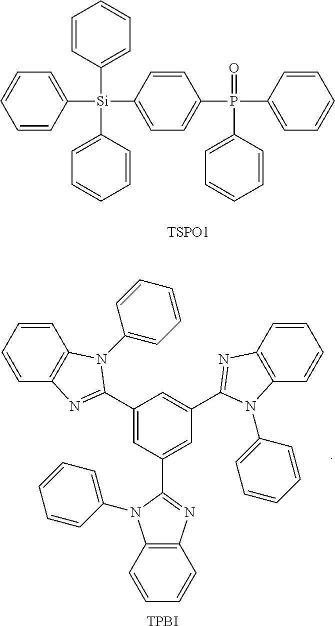

A thickness of an electron transport region may be in a range of about 160 Angstroms (Å) to about 5,000 Å. For example, a thickness of the electron transport region may be in a range of about 100 Å to about 4,000 Å. In case that the electron transport region includes a buffer layer, a hole blocking layer, an electron control layer, an electron transport layer, or any combination thereof, the thicknesses of the buffer layer, the hole blocking layer, or the electron control layer may each independently be in a range of about 20 Å to about 1,000 Å, and the thickness of the electron transport layer may be in a range of about 100 Å to about 1,000 Å. For example, the thicknesses of the buffer layer, the hole blocking layer, or the electron control layer may each independently be in a range of about 30 Å to about 300 Å. For example, the thickness of the electron transport layer may be in a range of about 150 Å to about 500 Å. In case that the thicknesses of the buffer layer, the hole blocking layer, the electron control layer, the electron transport layer, and/or the electron transport layer are each within these ranges, excellent electron transport characteristics may be obtained without a substantial increase in driving voltage.

The electron transport region (for example, an electron transport layer in the electron transport region) may further include, in addition to the materials described above, a metal-containing material.

The metal-containing material may include an alkali metal complex, an alkaline earth metal complex, or any combination thereof. A metal ion of the alkali metal complex may be a lithium (Li) ion, a sodium (Na) ion, a potassium (K) ion, a rubidium (Rb) ion, or a cesium (Cs) ion. A metal ion of the alkaline earth metal complex may be a beryllium (Be) ion, a magnesium (Mg) ion, a calcium (Ca) ion, a strontium (Sr) ion, or a barium (Ba) ion. Each ligand coordinated with the metal ion of the alkali metal complex and the alkaline earth metal complex may each independently be a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

For example, the metal-containing material may include a Li complex. The Li complex may include, e.g., Compound ET-D1 (LiQ) or Compound ET-D2:

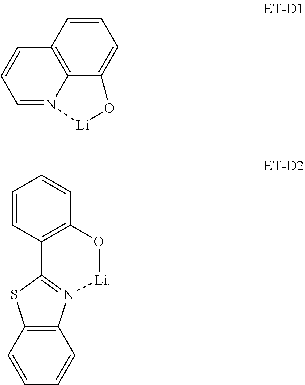

An electron transport region may include an electron injection layer that facilitates injection of electrons from the second electrode 150. An electron injection layer may be in direct contact with the second electrode 150.

The electron injection layer may have a structure consisting of a layer consisting of a single material, a structure consisting of a layer including different materials, or a structure having multiple layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may be Li, Na, K, Rb, Cs, or any combination thereof. The alkaline earth metal may be Mg, Ca, Sr, Ba, or any combination thereof. The rare earth metal may be Sc, Y, Ce, Tb, Yb, Gd, or any combination thereof.

The alkali metal-containing compound, the alkaline earth metal-containing compound, and the rare earth metal-containing compound may each be oxides, halides (e.g., fluorides, chlorides, bromides, or iodides), tellurides, or any combination thereof of each of the alkali metal, the alkaline earth metal, and the rare earth metal.

The alkali metal-containing compound may be alkali metal oxides such as Li₂O, Cs₂O, or K₂O, alkali metal halides such as LiF, NaF, CsF, KF, Lil, NaI, CsI, or KI, or any combination thereof. The alkaline earth-metal-containing compound may include alkaline earth-metal oxides, such as BaO, SrO, CaO, BaₓSr₁₋ₓO (wherein x is a real number satisfying 0<x<1), or BaₓCa₁₋ₓO (wherein x is a real number satisfying 0<x<1). The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In embodiments, the rare earth metal-containing compound may include a lanthanide metal telluride.

Examples of a lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and Lu₂Te₃.

The alkali metal complex, the alkaline earth metal complex, and the rare earth metal complex may include: an alkali metal ion, an alkaline earth metal ion, or a rare earth metal ion; and a ligand bond to the metal ion (e.g., a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof).

The electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In embodiments, the electron injection layer may further include an organic material (e.g., a compound represented by Formula 601).

In embodiments, the electron injection layer may consist of an alkali metal-containing compound (e.g., alkali metal halide), or the electron injection layer may consist of an alkali metal-containing compound (e.g., alkali metal halide), and an alkali metal, an alkaline earth metal, a rare earth metal, or any combination thereof. For example, an electron injection layer may be a KI:Yb co-deposition layer, a RbI:Yb co-deposition layer, and the like.

In case that an electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth metal complex, the rare earth metal complex, or any combination thereof may be homogeneously or non-homogeneously dispersed in a matrix including the organic material.

A thickness of an electron injection layer may be in a range of about 1 Å to about 100 Å. For example, a thickness of the electron injection layer may be in a range of about 3 Å to about 90 Å. In case that the thickness of an electron injection layer is within any of these ranges, excellent electron injection characteristics may be obtained without a substantial increase in driving voltage.

### [Second Electrode 150]

The second electrode 150 may be on the interlayer 130. In an embodiment, the second electrode 150 may be a cathode that is an electron injection electrode. A material for forming the second electrode 150 may be a material having a low work function, for example, a metal, an alloy, an electrically conductive compound, or a combination thereof.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a semi-transmissive electrode, or a reflective electrode.

The second electrode 150 may have a single-layered structure, or a multi-layered structure.

### [Capping Layer]

The light-emitting device 10 may include a first capping layer outside the first electrode 110, and/or a second capping layer outside the second electrode 150. In embodiments, the light-emitting device 10 may have a structure in which the first capping layer, the first electrode 110, the interlayer 130, and the second electrode 150 are stacked in this stated order, a structure in which the first electrode 110, the interlayer 130, the second electrode 150, and the second capping layer are stacked in this stated order, or a structure in which the first capping layer, the first electrode 110, the interlayer 130, the second electrode 150, and the second capping layer are stacked in this stated order.

In the light-emitting device 10, light emitted from the emission layer in the interlayer 130 may pass through the first electrode 110 (which may be a semi-transmissive electrode or a transmissive electrode) and through the first capping layer to the outside. In the light-emitting device 10, light emitted from the emission layer in the interlayer 130 may pass through the second electrode 150 (which may be a semi-transmissive electrode or a transmissive electrode) and through the second capping layer to the outside.

The first capping layer and the second capping layer may each improve the external luminescence efficiency based on the principle of constructive interference. Accordingly, the optical extraction efficiency of the light-emitting device 10 may be increased, thus improving the luminescence efficiency of the light-emitting device 10.

The first capping layer and the second capping layer may each include a material having a refractive index greater than or equal to about 1.6 (with respect to a wavelength of about 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with a substituent of O, N, S, Se, Si, F, Cl, Br, I, or any combination thereof.

In embodiments, at least one of the first capping layer and the second capping layer may each independently include an amine group-containing compound.

In embodiments, at least one of the first capping layer and the second capping layer may each independently include the compound represented by Formula 201, a compound represented by Formula 202, or any combination thereof.

In embodiments, at least one of the first capping layer and the second capping layer may each independently include one of Compounds HT28 to HT33, one of Compounds CP1 to CP6, β-NPB, or any combination thereof:

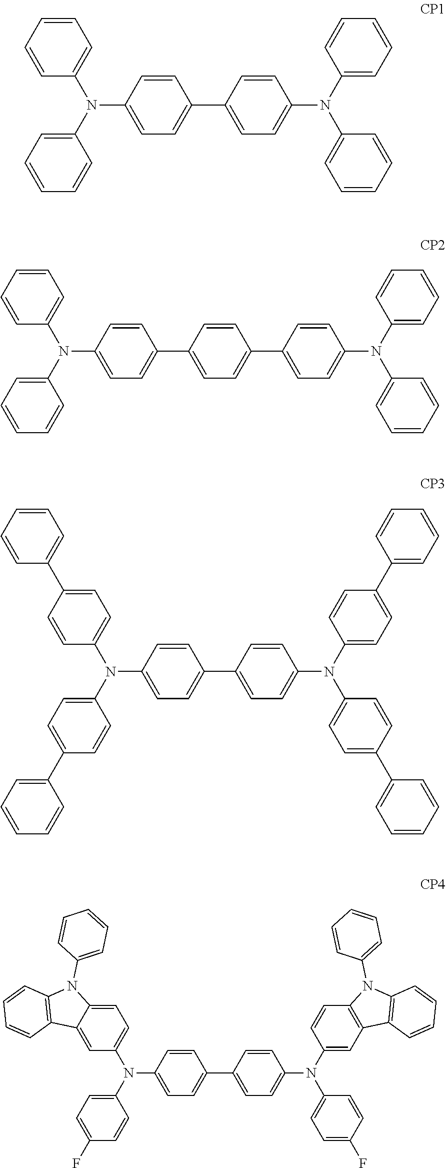 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

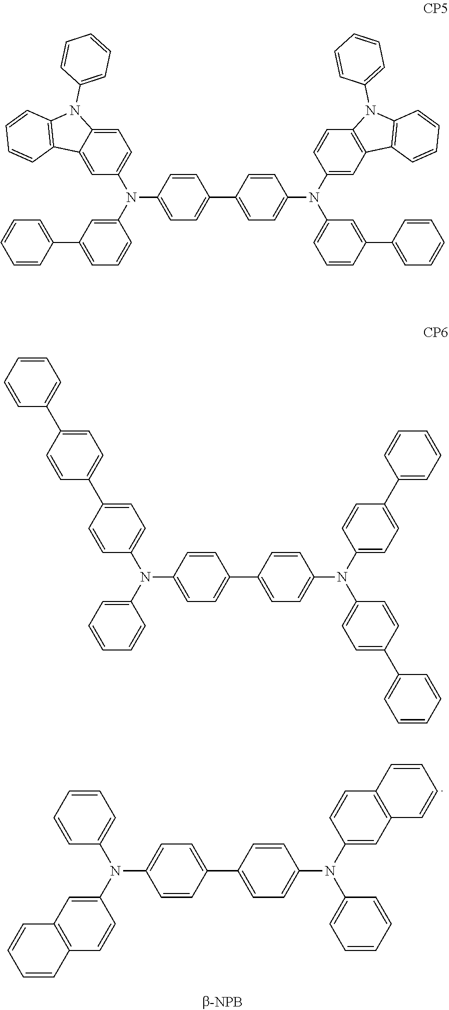 [SMILES: c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### [Electronic Apparatus]

The light-emitting device may be included in various electronic apparatuses. In embodiments, an electronic apparatus including the light-emitting device may be a light-emitting apparatus or an authentication apparatus.

The electronic apparatus (e.g., a light-emitting apparatus) may further include, in addition to the light-emitting device, a color filter, a color conversion layer, or a color filter and a color conversion layer. The color filter and/or the color conversion layer may be disposed on at least one traveling direction of light emitted from the light-emitting device. In embodiments, light emitted from the light-emitting device may be blue light or white light. The light-emitting device may be a light-emitting device as described herein. In embodiments, the color conversion layer may include quantum dots. The quantum dot may be, for example, the quantum dot described herein.

The electronic apparatus may include a first substrate. The first substrate may include subpixels, the color filter may include color filter areas respectively corresponding to the plurality of subpixels, and the color conversion layer may include color conversion areas respectively corresponding to the subpixels.

A pixel-defining film may be between the subpixels to define each subpixel.

The color filter may further include color filter areas and light-blocking patterns between the plurality of color filter areas, and the color conversion layer may further include color conversion areas and light-blocking patterns between the plurality of color conversion areas.

The color filter areas (or color conversion areas) may include a first area emitting first color light, a second area emitting second color light, and/or a third area emitting third color light, and the first color light, the second color light, and/or the third color light may have different maximum emission wavelengths. In embodiments, the first color light may be red light, the second color light may be green light, and the third color light may be blue light. In embodiments, the color filter areas (or the color conversion areas) may each include quantum dots. For example, the first area may include red quantum dots, the second area may include green quantum dots, and the third area may not include a quantum dot. The quantum dot may be a quantum dot described herein. The first area, the second area, and/or the third area may each further include a scatterer.

In embodiments, the light-emitting device may emit first light, the first area may absorb the first light to emit first-first color light, the second area may absorb the first light to emit second-first color light, and the third area may absorb the first light to emit third-first color light. In this embodiment, the first-first color light, the second-first color light, and the third-first color light may each have a different maximum emission wavelength from one another. For example, the first light may be blue light, the first-first color light may be red light, the second-first color light may be green light, and the third-first light may be blue light.

The electronic apparatus may further include a thin-film transistor, in addition to the light-emitting device. The thin-film transistor may include a source electrode, a drain electrode, and an active layer, wherein one of the source electrode and the drain electrode may be electrically connected to one of the first electrode and the second electrode of the light-emitting device.

The thin-film transistor may further include a gate electrode, a gate insulating film, or the like.

The active layer may include a crystalline silicon, an amorphous silicon, an organic semiconductor, and an oxide semiconductor.

The electronic apparatus may further include an encapsulation unit for sealing the light-emitting device. The encapsulation unit may be between the color filter and/or the color conversion layer, and the light-emitting device. The encapsulation unit may allow light to pass to the outside from the light-emitting device and may prevent air and moisture from permeating into the light-emitting device at the same time. The encapsulation unit may be a sealing substrate including transparent glass or a plastic substrate. The encapsulation unit may be a thin-film encapsulating layer including an organic layer and/or an inorganic layer. In case that the encapsulation unit is a thin-film encapsulating layer, the electronic apparatus may be flexible.

In addition to the color filter and/or the color conversion layer, various functional layers may be included on the encapsulation unit depending on the use of an electronic apparatus. Examples of a functional layer may include a touch screen layer, a polarizing layer, or the like. The touch screen layer may be a resistive touch screen layer, a capacitive touch screen layer, or an infrared beam touch screen layer. The authentication apparatus may be, for example, a biometric authentication apparatus that identifies an individual according to biometric information (e.g., a fingertip, a pupil, or the like).

The authentication apparatus may further include a biometric information collecting unit, in addition to the light-emitting device described above.

The electronic apparatus may be applied to various displays, an optical source, lighting, a personal computer (e.g., a mobile personal computer), a cellphone, a digital camera, an electronic organizer, an electronic dictionary, an electronic game console, a medical device (e.g., an electronic thermometer, a blood pressure meter, a glucometer, a pulse measuring device, a pulse wave measuring device, an electrocardiograph recorder, an ultrasonic diagnosis device, or an endoscope display), a fish finder, various measurement devices, gauges (e.g., gauges of an automobile, an airplane, or a ship), and a projector.

### [Electronic Apparatus]

The light-emitting device may be included in various electronic apparatuses.

In embodiments, an electronic apparatus including the light-emitting device may include a flat panel display, a curved display, a computer monitor, a medical monitor, a television (TV), an advertisement board, an indoor light, an outdoor light, a signaling light, a head-up display, a fully transparent display, a partially transparent display, a flexible display, a rollable display, a foldable display, a stretchable display, a laser printer, a telephone, a cell phone, a tablet, a phablet, a personal digital assistant (PDAs), a wearable device, a laptop computer, a digital camera, a camcorder, a viewfinder, a microdisplay, a three-dimensional (3D) display, a virtual reality display, an augmented reality display, a vehicle, a video wall including multiple displays tiled together, a theater screen, a stadium screen, a phototherapy device, or a sign.

As the light-emitting device may have excellent luminescence efficiency and long lifespan, the electronic apparatus including the light-emitting device may have characteristics such as high luminance, high resolution, and low power consumption.

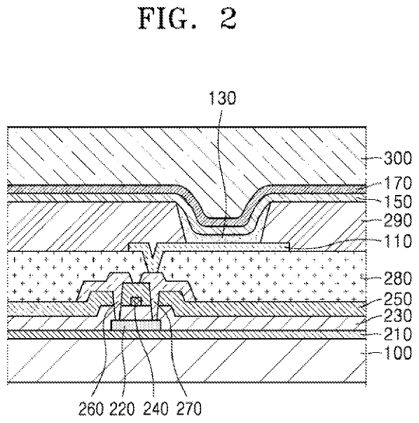

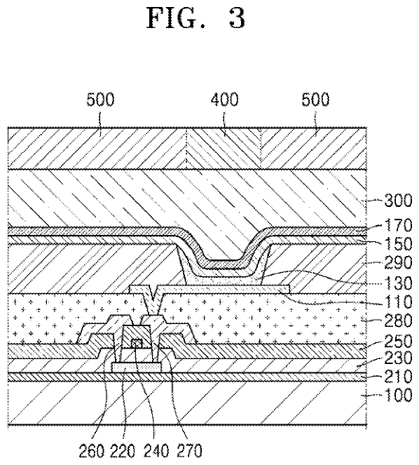

### [Descriptions of FIGS. 2 and 3]

FIG. 2 is a schematic cross-sectional view of an electronic apparatus according to an embodiment.

The electronic apparatus of FIG. 2 may include a substrate 100, a thin-film transistor, a light-emitting device, and an encapsulation unit 300 sealing the light-emitting device.

The substrate 100 may be a flexible substrate, a glass substrate, or a metal substrate. A buffer layer 210 may be on the substrate 100. The buffer layer 210 may prevent penetration of impurities through the substrate 100 and may provide a flat surface on the substrate 100.

A thin-film transistor may be on the buffer layer 210. The thin-film transistor may include an active layer 220, a gate electrode 240, a source electrode 260, and a drain electrode 270.

The active layer 220 may include an inorganic semiconductor such as silicon or polysilicon, an organic semiconductor, or an oxide semiconductor and include a source area, a drain area, and a channel area.

A gate insulating film 230 for insulating the active layer 220 and the gate electrode 240 may be on the active layer 220, and the gate electrode 240 may be on the gate insulating film 230.

An interlayer insulating film 250 may be on the gate electrode 240. The interlayer insulating film 250 may be between the gate electrode 240 and the source electrode 260 to insulate the gate electrode 240 from the source electrode 260 and between the gate electrode 240 and the drain electrode 270 the gate electrode 240 from the drain electrode 270.

The source electrode 260 and the drain electrode 270 may be on the interlayer insulating film 250. The interlayer insulating film 250 and the gate insulating film 230 may be formed to expose a source area and a drain area of the active layer 220, and the source electrode 260 and the drain electrode 270 may respectively be adjacent to the exposed source area and the exposed drain area of the active layer 220.

Such a thin-film transistor may be electrically connected to a light-emitting device to drive the light-emitting device and may be protected by a passivation layer 280. The passivation layer 280 may include an inorganic insulating film, an organic insulating film, or a combination thereof. A light-emitting device may be on the passivation layer 280. The light-emitting device may include a first electrode 110, an interlayer 130, and a second electrode 150.

The first electrode 110 may be on the passivation layer 280. The passivation layer 280 may not completely cover the drain electrode 270 and may expose an area of the drain electrode 270. The first electrode 110 may be electrically connected to the exposed area of the drain electrode 270.

A pixel-defining film 290 may be on the first electrode 110. The pixel-defining film 290 may expose a selected area of the first electrode 110, and the interlayer 130 may be formed in the exposed area of the first electrode 110. The pixel-defining film 290 may be a polyimide-based organic film or a polyacrylic-based organic film. Although not shown in FIG. 2, at least some layers of the interlayer 130 may extend to the upper portion of the pixel-defining film 290 to be provided in the form of a common layer.

The second electrode 150 may be on the interlayer 130, and a capping layer 170 may be further included on the second electrode 150. The capping layer 170 may be formed to cover the second electrode 150.

The encapsulation unit 300 may be on the capping layer 170. The encapsulation unit 300 may be on the light-emitting device to protect a light-emitting device from moisture and/or oxygen. The encapsulation unit 300 may include an inorganic film including silicon nitride (SiNₓ), silicon oxide (SiOₓ), indium tin oxide, indium zinc oxide, or any combination thereof; an organic film including PET, polyethylene naphthalate, polycarbonate, polyimide, polyethylene sulfonate, polyoxy methylene, poly arylate, hexamethyl disiloxane, an acrylic resin (e.g., polymethyl methacrylate, polyacrylic acid, and the like), an epoxy resin (e.g., aliphatic glycidyl ether (AGE) and the like), or any combination thereof; or a combination of the inorganic film and the organic film.

FIG. 3 is a schematic cross-sectional view of an electronic apparatus according to another embodiment.

The electronic apparatus shown in FIG. 3 may differ from the electronic apparatus shown in FIG. 2, at least in that a light-shielding pattern 500 and a functional area 400 are further included on the encapsulation unit 300. The functional area 400 may be a color filter area, a color-conversion area, or a combination of a color filter area and a color-conversion area. In embodiments, the light-emitting device shown in FIG. 3 included in the electronic apparatus may be a tandem light-emitting device.

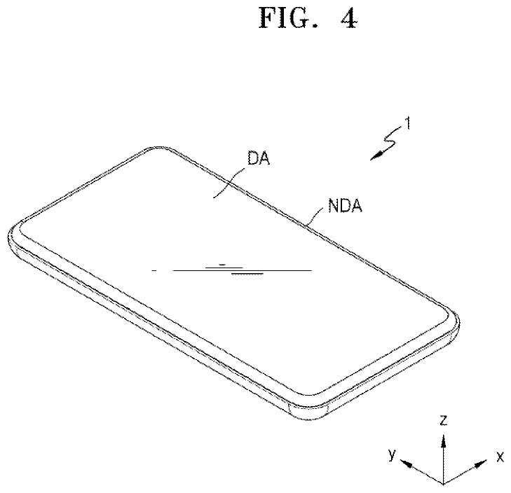

### [Description of FIG. 4]

FIG. 4 is a schematic perspective view of an electronic equipment 1 including the light-emitting device according to an embodiment.

The electronic equipment 1, which may be an apparatus for displaying a moving image or still image, may be any product such as a television, a laptop, a monitor, an advertisement board, or internet of things (IOT), as well as a portable electronic device such as a mobile phone, a smart phone, a tablet personal computer (PC), a mobile communication terminal, an electronic notebook, an electronic book, and a portable multimedia player (PMP) or navigation device, an ultra-mobile PC (UMPC), or a part thereof.

The electronic equipment 1 may be a wearable device such as a smart watch, a watch phone, a glasses display, or a head mounted display (HMD), or a part thereof, but embodiments are not limited thereto.

For example, the electronic equipment 1 may be a center information display (CID) on an instrument panel and a center fascia or dashboard of a vehicle, a room mirror display instead of a side mirror of a vehicle, an entertainment display for a rear seat of a car or a display placed on the back of a front seat, a head up display (HUD) installed in front of a vehicle or projected on a front window glass, or a computer generated hologram augmented reality head up display (CGH AR HUD). FIG. 4 shows an embodiment where the electronic equipment 1 is a smartphone, for convenience of description.

The electronic equipment 1 may include a display area DA and a non-display area NDA outside the display area DA. A display apparatus may implement an image through a two-dimensional array of pixels that are arranged in the display area DA.

The non-display area NDA may be an area that may not display an image, and may surround the display area DA. A driver for providing an electrical signal or power to the display devices in the display area DA may be arranged in the non-display area NDA. A pad, which is an area to which an electronic device or a printed circuit board may be electrically connected, may be arranged in the non-display area NDA.

In the electronic equipment 1, a length in an x-axis direction and a length in a y-axis direction may be different from each other. In an embodiment, as shown in FIG. 4, the length in the x-axis direction may be shorter than the length in the y-axis direction. In embodiments, the length in the x-axis direction may be the same as the length in the y-axis direction. In still other embodiments, the length in the x-axis direction may be longer than the length in the y-axis direction.

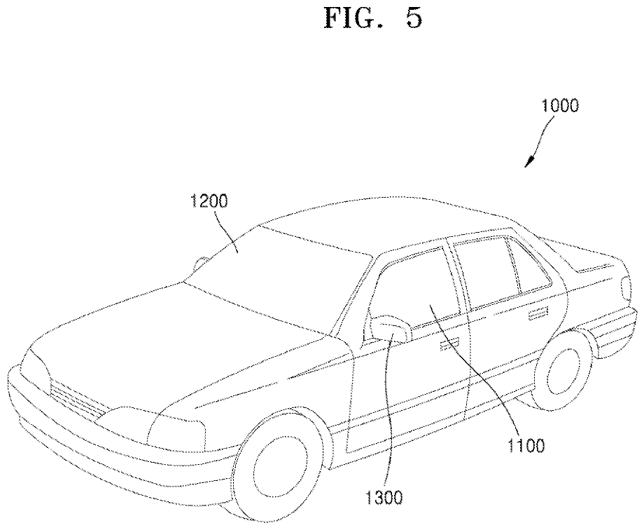

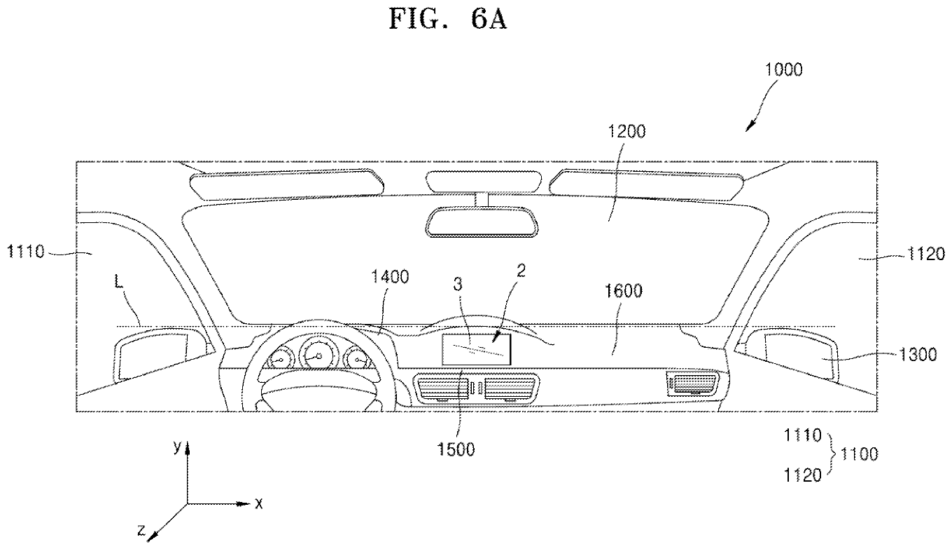

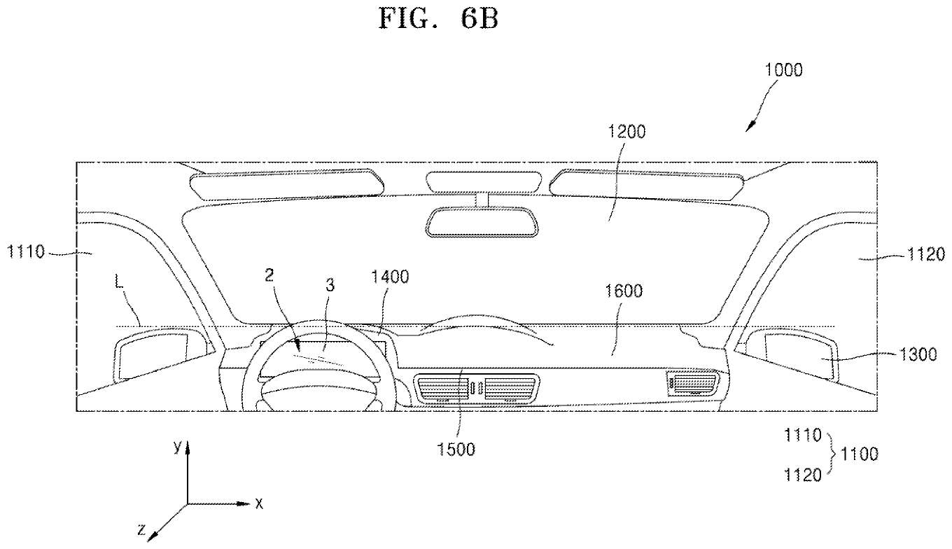

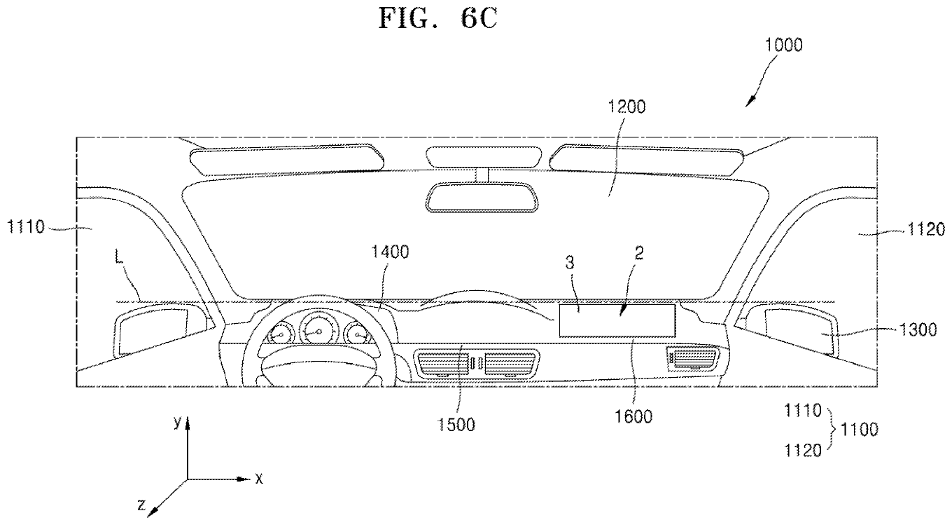

### [Descriptions of FIGS. 5 and 6A to 6C]

FIG. 5 is a schematic perspective view of an exterior of a vehicle 1000 as an electronic equipment including a light-emitting device according to an embodiment.

FIGS. 6A to 6C are each a schematic diagram of an interior of a vehicle 1000 according to embodiments.

In FIGS. 5 and 6A to 6C, the vehicle 1000 may refer to various apparatuses that move a subject to be transported such as a person, an object, or an animal, from a departure point to a destination. Examples of the vehicle 1000 may include a vehicle traveling on a road or track, a vessel moving over a sea or river, and an airplane flying in the sky using the action of air.

The vehicle 1000 may travel on roads or tracks. The vehicle 1000 may move in a given direction according to the rotation of at least one wheel. Examples of the vehicle 1000 may include a three-wheeled or four-wheeled vehicle, a construction machine, a two-wheeled vehicle, a motorbike, a bicycle, and a train running on a track.

The vehicle 1000 may include a body having the interior and the exterior, and a chassis that is a portion excluding the body in which mechanical apparatuses necessary for driving are installed. The exterior of the body of the vehicle may include a front panel, a bonnet, a roof panel, a rear panel, a trunk, and a pillar provided at a boundary between doors. The chassis of the vehicle 1000 may include a power generating apparatus, a power transmitting apparatus, a traveling apparatus, a steering apparatus, a braking apparatus, a suspension apparatus, a transmission apparatus, a fuel apparatus, front, rear, left, and right wheels, and the like.

The vehicle 1000 may include a side window glass 1100, a front window glass 1200, a side mirror 1300, a cluster 1400, a center fascia 1500, a passenger seat dashboard 1600, and a display apparatus 2.

The side window glass 1100 and the front window glass 1200 may be partitioned by a pillar located between the side window glass 1100 and the front window glass 1200.

The side window glass 1100 may be installed on a side of the vehicle 1000. In embodiments, the side window glass 1100 may be installed on a door of the vehicle 1000. Multiple side window glasses 1100 may be provided and may face each other. In embodiments, the side window glass 1100 may include a first side window glass 1110 and a second side window glass 1120. In embodiments, the first side window glass 1110 may be arranged adjacent to the cluster 1400, and the second side window glass 1120 may be arranged adjacent to the passenger seat dashboard 1600.

In embodiments, the side window glasses 1100 may be spaced apart from each other in an x direction or in a −x direction. For example, the first side window glass 1110 and the second side window glass 1120 may be spaced apart from each other in the x direction or in the −x direction. In other words, an imaginary straight line L connecting the side window glasses 1100 may extend in the x direction or the −x direction. For example, the imaginary straight line L connecting the first side window glass 1110 and the second side window glass 1120 to each other may extend in the x direction or in the −x direction.

The front window glass 1200 may be installed on the front of the vehicle 1000. The front window glass 1200 may be between the side window glasses 1100 facing each other.

The side mirror 1300 may provide a view of the rear of the vehicle 1000. The side mirror 1300 may be installed on the exterior of the body of the vehicle. In an embodiment, multiple side mirrors 1300 may be provided. Any one of the side mirrors 1300 may be located outside the first side window glass 1110. Another one of the side mirrors 1300 may be located outside the second side window glass 1120.

The cluster 1400 may be located in front of a steering wheel. The cluster 1400 may include a tachometer, a speedometer, a coolant thermometer, a fuel gauge turn indicator, a high beam indicator, a warning light, a seat belt warning light, an odometer, a hodometer, an automatic shift selector indicator light, a door open warning light, an engine oil warning light, and/or a low fuel warning indicator.

The center fascia 1500 may include a control panel on which buttons for adjusting an audio apparatus, an air conditioning apparatus, and a seat heater are disposed. The center fascia 1500 may be on a side of the cluster 1400.

The passenger seat dashboard 1600 may be spaced apart from the cluster 1400 with the center fascia 1500 interposed therebetween. In an embodiment, the cluster 1400 may be disposed to correspond to a seat of a driver (not shown), and the passenger seat dashboard 1600 may be disposed to correspond to a seat of a passenger (not shown). In an embodiment, the cluster 1400 may be adjacent to the first side window glass 1110, and the passenger seat dashboard 1600 may be adjacent to the second side window glass 1120.

In an embodiment, the display apparatus 2 may include a display panel 3, and the display panel 3 may display an image. The display apparatus 2 may be inside the vehicle 1000. In embodiments, the display apparatus 2 may be between the side window glasses 1100 facing each other. The display apparatus 2 may be in at least one of the cluster 1400, the center fascia 1500, and the passenger seat dashboard 1600.

The display apparatus 2 may include an organic light-emitting display apparatus, an inorganic EL display apparatus, a quantum dot display apparatus, or the like. Hereinafter, as the display apparatus 2 according to an embodiment, an organic light-emitting display apparatus including the light-emitting device according to an embodiment will be described as an example, however, embodiments may include various types of the display apparatus.

As shown in FIG. 6A, the display apparatus 2 may be disposed in the center fascia 1500. In an embodiment, the display apparatus 2 may display navigation information. In an embodiment, the display apparatus 2 may display information of audio settings, video settings, or vehicle settings.

As shown in FIG. 6B, the display apparatus 2 may be disposed in the cluster 1400. In this embodiment, the cluster 1400 may show driving information and the like by the display apparatus 2. For example, the cluster 1400 may digitally implement driving information. The digital cluster 1400 may display vehicle information and driving information as images. For example, a needle and a gauge of a tachometer, and various warning lights may be displayed by digital signal.

As shown in FIG. 6C, the display apparatus 2 may be disposed in the passenger seat dashboard 1600. The display apparatus 2 may be embedded in the passenger seat dashboard 1600 or located on the passenger seat dashboard 1600. In an embodiment, the display apparatus 2 disposed on the passenger seat dashboard 1600 may display an image related to information displayed on the cluster 1400 and/or information displayed on the center fascia 1500. In an embodiment, the display apparatus 2 disposed on the passenger seat dashboard 1600 may display information that is different from information displayed on the cluster 1400 and/or different from information displayed on the center fascia 1500.

### [Manufacturing Method]

The layers constituting the hole transport region, the emission layer, and the layers constituting the electron transport region may be formed in a selected region by using one or more suitable methods such as vacuum deposition, spin coating, casting, Langmuir-Blodgett (LB) deposition, ink-jet printing, laser printing, and laser-induced thermal imaging.

In case that layers constituting the hole transport region, an emission layer, and layers constituting the electron transport region are each independently formed by vacuum-deposition, the vacuum-deposition may be performed at a deposition temperature in a range of about 100° C. to about 500° C., at a vacuum degree in a range of about 10⁻⁸ torr to about 10⁻³ torr, and at a deposition rate in a range of about 0.01 Angstroms per second (Å/sec) to about 100 Å/sec, depending on the material to be included in each layer and the structure of each layer to be formed.

### Definitions of Terms

The term “C₃-C₆₀ carbocyclic group” as used herein may be a cyclic group consisting of carbon atoms as the only ring-forming atoms and having 3 to 60 carbon atoms as ring-forming atoms. The term “C₁-C₆₀ heterocyclic group” as used herein may be a cyclic group having 1 to 60 carbon atoms and further including at least one heteroatom as ring-forming atoms. The C₃-C₆₀ carbocyclic group and the C₁-C₆₀ heterocyclic group may each be a monocyclic group consisting of one ring or a polycyclic group in which at least two rings are condensed. For example, a C₁-C₆₀ heterocyclic group may have 3 to 61 ring-forming atoms.

The term “cyclic group” as used herein may be a C₃-C₆₀ carbocyclic group or the C₁-C₆₀ heterocyclic group.

The term “π electron-rich C₃-C₆₀ cyclic group” may be a cyclic group having 3 to 60 carbon atoms and may not include *—N═*′ as a ring-forming moiety. The term “π electron-deficient nitrogen-containing C₁-C₆₀ cyclic group” as used herein may be a heterocyclic group having 1 to 60 carbon atoms and may include *—N═*′ as a ring-forming moiety.

In embodiments,
a C₃-C₆₀ carbocyclic group may be a T1 group or a group in which at least two T1 groups are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
a C₁-C₆₀ heterocyclic group may be a T2 group, a group in which at least two T2 groups are condensed with each other, or a group in which at least one T2 group is condensed with at least one T1 group (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonapthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and the like),
a π electron-rich C₃-C₆₀ cyclic group may be a T1 group, a group in which at least two T1 groups are condensed with each other, a T3 group, a group in which at least two T3 groups are condensed with each other, or a group in which at least one T3 group is condensed with at least one T1 group (for example, a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonapthothiophene group, a benzonaphthosilole group, a benzofurodibenzofuran group, a benzofurodibenzothiophene group, a benzothienodibenzothiophene group, and the like), and
a π electron-deficient nitrogen-containing C₁-C₆₀ cyclic group may be a T4 group, a group in which at least two T4 groups are condensed with each other, a group in which at least one T4 group is condensed with at least one T1 group, a group in which at least one T4 group is condensed with at least one T3 group, or a group in which at least one T4 group, at least one T1 group, and at least one T3 group are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and the like), wherein
the T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
the T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
the T3 group may be a furan group, a thiophene group, a 1H-pyrrole group, a silole group, or a borole group, and
the T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group”, “C₃-C₆₀ carbocyclic group”, “C₁-C₆₀ heterocyclic group”, “π electron-rich C₃-C₆₀ cyclic group”, or “π electron-deficient nitrogen-containing C₁-C₆₀ cyclic group” as used herein may each be a group condensed with any suitable cyclic group, a monovalent group, or a polyvalent group (e.g., a divalent group, a trivalent group, a tetravalent group, or the like), depending on the structure of the formula to which the term is applied. For example, a “benzene group” may be a benzene ring, a phenyl group, a phenylene group, or the like, and this may be understood by one of ordinary skill in the art, depending on the structure of Formula including the “benzene group”.

Examples of a monovalent C₃-C₆₀ carbocyclic group or a monovalent C₁-C₆₀ heterocyclic group may include a C₃-C₁₀ cycloalkyl group, a C₁-C₁ heterocycloalkyl group, a C₃-C₁₀ cycloalkenyl group, a C₁-C₁ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group. Examples of a divalent C₃-C₆₀ carbocyclic group or a divalent C₁-C₆₀ heterocyclic group may include a C₃-C₁₀ cycloalkylene group, a C₁-C₁ heterocycloalkylene group, a C₃-C₁₀ cycloalkenylene group, a C₁-C₁ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein may be a linear or branched aliphatic hydrocarbon monovalent group having 1 to 60 carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an iso-nonyl group, a sec-nonyl group, a tert-nonyl group, an n-decyl group, an isodecyl group, a sec-decyl group, and a tert-decyl group. The term “C₁-C₆₀ alkylene group” as used herein may be a divalent group having substantially a same structure as the C₁-C₆₀ alkyl group.

The term “C₂-C₆₀ alkenyl group” as used herein may be a hydrocarbon group having at least one carbon-carbon double bond in the middle or at a terminus of a C₂-C₆₀ alkyl group. Examples thereof may include an ethenyl group, a propenyl group, and a butenyl group. The term “C₂-C₆₀ alkenylene group” as used herein may be a divalent group having substantially a same structure as the C₂-C₆₀ alkenyl group.

The term “C₂-C₆₀ alkynyl group” as used herein may be a monovalent hydrocarbon group having at least one carbon-carbon triple bond in the middle or at a terminus of a C₂-C₆₀ alkyl group. Examples thereof may include an ethynyl group and a propynyl group. The term “C₂-C₆₀ alkynylene group” as used herein may be a divalent group having substantially a same structure as the C₂-C₆₀ alkynyl group.

The term “C₁-C₆₀ alkoxy group” as used herein may be a monovalent group represented by —O(A₁₀₁) (wherein A₁₀₁ may be a C₁-C₆₀ alkyl group). Examples thereof may include a methoxy group, an ethoxy group, and an isopropyloxy group.

The term “C₃-C₁₀ cycloalkyl group” as used herein may be a monovalent saturated hydrocarbon monocyclic group including 3 to 10 carbon atoms. Examples of a C₃-C₁₀ cycloalkyl group may include a cyclopropyl group, a cyclobutyl group, a cyclopentyl group, a cyclohexyl group, a cycloheptyl group, a cyclooctyl group, an adamantanyl group, a norbornanyl (bicyclo[2.2.1]heptyl) group, a bicyclo[1.1.1]pentyl group, a bicyclo[2.1.1]hexyl group, or a bicyclo[2.2.2]octyl group. The term “C₃-C₁₀ cycloalkylene group” as used herein may be a divalent group having substantially a same structure as the C₃-C₁₀ cycloalkyl group.

The term “C₁-C₁₀ heterocycloalkyl group” as used herein may be a monovalent cyclic group including at least one heteroatom other than carbon atoms as a ring-forming atom and having 1 to 10 carbon atoms. Examples thereof may include a 1,2,3,4-oxatriazolidinyl group, a tetrahydrofuranyl group, and a tetrahydrothiophenyl group. The term “C₁-C₁₀ heterocycloalkylene group” as used herein may be a divalent group having substantially a same structure as the C₁-C₁₀ heterocycloalkyl group.

The term “C₃-C₁₀ cycloalkenyl group” as used herein may be a monovalent cyclic group that has 3 to 10 carbon atoms and at least one carbon-carbon double bond in its ring, and may not be aromatic. Examples thereof may include a cyclopentenyl group, a cyclohexenyl group, and a cycloheptenyl group. The term “C₃-C₁a cycloalkenylene group” as used herein may be a divalent group having substantially a same structure as the C₃-C₁₀ cycloalkenyl group.

The term “C₁-C₁₀ heterocycloalkenyl group” as used herein may be a monovalent cyclic group including at least one heteroatom other than carbon atoms as a ring-forming atom, 1 to 10 carbon atoms, and at least one double bond in its ring. Examples of a C₁-C₁₀ heterocycloalkenyl group may include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as used herein may be a divalent group having substantially a same structure as the C₁-C₁₀ heterocycloalkenyl group.

The term “C₆-C₆₀ aryl group” as used herein may be a monovalent group having a carbocyclic aromatic system having 6 to 60 carbon atoms. The term “C₆-C₆₀ arylene group” as used herein may be a divalent group having a carbocyclic aromatic system having 6 to 60 carbon atoms. Examples of a C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. In case that the C₆-C₆₀ aryl group and the C₆-C₆₀ arylene group each independently include two or more rings, the respective rings may be fused with each other.

The term “C₁-C₆₀ heteroaryl group” as used herein may be a monovalent group having a heterocyclic aromatic system further including at least one heteroatom other than carbon atoms as a ring-forming atom and 1 to 60 carbon atoms. The term “C₁-C₆₀ heteroarylene group” as used herein may be a divalent group having a heterocyclic aromatic system further including at least one heteroatom other than carbon atoms as a ring-forming atom and 1 to 60 carbon atoms. Examples of a C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. In case that the C₁-C₆₀ heteroaryl group and the C₁-C₆₀ heteroarylene group each independently include two or more rings, the respective rings may be fused.

The term “monovalent non-aromatic condensed polycyclic group” as used herein may be a monovalent group that has two or more condensed rings and only carbon atoms (e.g., 8 to 60 carbon atoms) as ring forming atoms, wherein the molecular structure in case that considered as a whole is non-aromatic. Examples of a monovalent non-aromatic condensed polycyclic group may include an indenyl group, a fluorenyl group, a spiro-bifluorenyl group, a benzofluorenyl group, an indenophenanthrenyl group, and an indenoanthracenyl group. The term “divalent non-aromatic condensed polycyclic group” as used herein may be a divalent group having a same structure as the monovalent non-aromatic condensed polycyclic group.

The term “monovalent non-aromatic condensed heteropolycyclic group” as used herein may be a monovalent group (e.g., 1 to 60 carbon atoms) that has two or more condensed rings and at least one heteroatom other than carbon atoms, as a ring-forming atom, and having non-aromaticity in its entire molecular structure. Examples of a monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzooxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as used herein may be a divalent group having substantially a same structure as the monovalent non-aromatic condensed heteropolycyclic group.

The term “C₆-C₆₀ aryloxy group” as used herein may be a group represented by —O(A₁₀₂) (wherein A₁₀₂ may be a C₆-C₆₀ aryl group). The term “C₆-C₆₀ arylthio group” as used herein may be a group represented by —S(A₁₀₃) (wherein A₁₀₃ may be a C₆-C₆₀ aryl group).

The term “C₇-C₆₀ aryl alkyl group” as used herein may be a group represented by -(A₁₀₄)(A₁₀₅) (wherein A₁₀₄ may be a C₁-C₅₄ alkylene group, and A₁₀₅ may be a C₆-C₅₉ aryl group). The term “C₂-C₆₀ heteroaryl alkyl group” as used herein may be group represented by -(A₁₀₆)(A₁₀₇) (wherein A₁₀₆ may be a C₁-C₅₉ alkylene group, and A₁₀₇ may be a C₁-C₅₉ heteroaryl group).

In the specification, the group “R₁₀ₐ” may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the specification, Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

The term “heteroatom” as used herein may be any atom other than a carbon atom or a hydrogen atom. Examples of a heteroatom may include O, S, N, P, Si, B, Ge, Se, or any combination thereof.

In the specification, examples of a third-row transition metal may include hafnium (Hf), tantalum (Ta), tungsten (W), rhenium (Re), osmium (Os), iridium (Ir), platinum (Pt), and gold (Au).

The term “Ph” used herein represents a phenyl group, the term “Me” used herein represents a methyl group, the term “Et” used herein represents an ethyl group, the terms “tert-Bu” or “Bu^{t}” used herein represents a tert-butyl group, and the term “OMe” used herein represents a methoxy group.

The term “biphenyl group” as used herein may be a phenyl group substituted with a phenyl group. For example, a “biphenyl group” may be a “substituted phenyl group” having a “C₆-C₆₀ aryl group” as a substituent.

The term “terphenyl group” as used herein may be a phenyl group substituted with a biphenyl group. For example, a “terphenyl group” may be a “substituted phenyl group” having, as a substituent, a “C₆-C₆₀ aryl group substituted with a C₆-C₆₀ aryl group”.

The symbols *, *′, *″, and *′″ as used herein, unless defined otherwise, refer to a binding site to an adjacent atom in a corresponding formula or moiety.

In the present specification, the terms “x-axis”, “y-axis”, and “z-axis” are not limited to three axes on the orthogonal coordinates system (e.g., a Cartesian coordinate system), and may be interpreted in a broader sense than the aforementioned three axes in an orthogonal coordinates system. For example, the x-axis, y-axis, and z-axis may describe axes that are orthogonal to each other, or may describe axes that are in different directions that are not orthogonal to each other.

Hereinafter, compounds according to embodiments and a light-emitting device according to embodiments will be described in more detail with reference to the Synthesis Examples and the Examples. The wording “B was used instead of A” used in describing Synthesis Examples refers to that an identical number of molar equivalents of B was used in place of A.

### EXAMPLES

### Synthesis Example 1 (Synthesis of Compound 1)

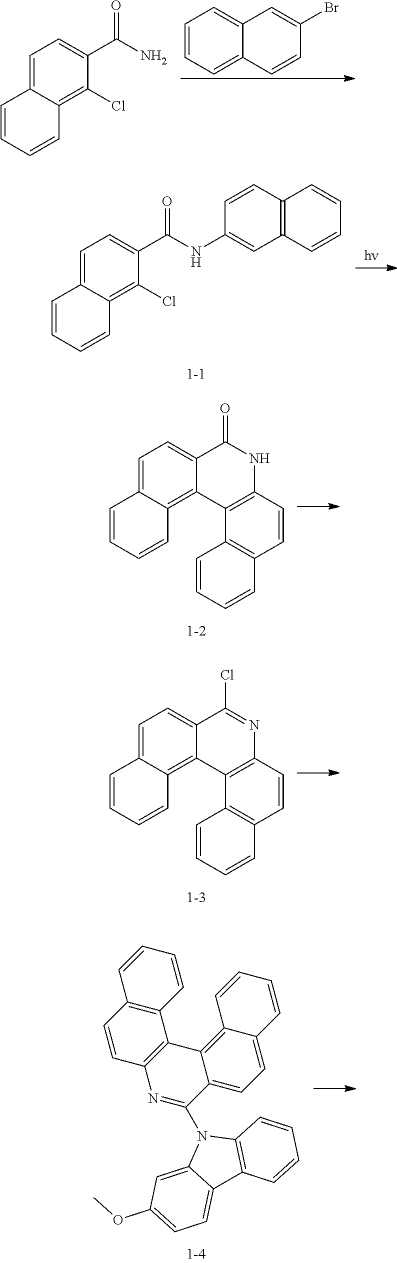

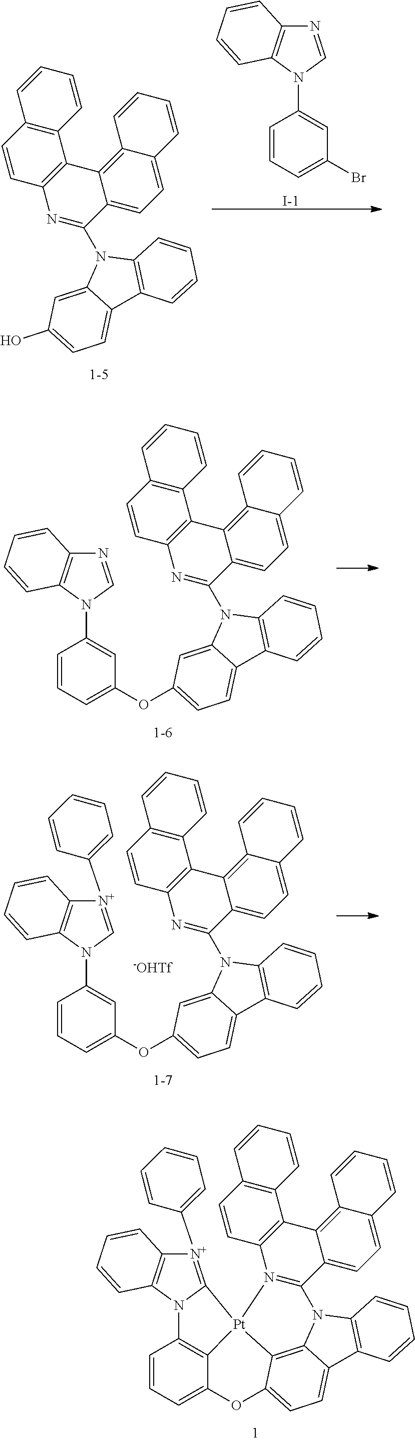

### Synthesis of Intermediate 1-1

10.3 g (50 mmol) of 1-chloro-2-naphthamide, 10.4 g (50 mmol) of 2-bromonaphthalene, 1.15 g (2.0 mmol) of Pd(dba)₂, 1.74 g (3.0 mmol) of Xantphos, and 22.8 g (70 mmol) of cesium carbonate were added to a reaction vessel and suspended in 125 mL of dioxane. The reaction mixture was heated to a temperature of 100° C. and stirred for 12 hours. Once the reaction was complete, the mixture was allowed to cool to room temperature. 100 mL of distilled water was added thereto, and an organic layer was extracted using ethyl acetate. The extracted organic layer was washed with saturated sodium chloride aqueous solution, followed by drying with sodium sulfate. The residue from which the solvent was removed was separated by column chromatography to thereby obtain 12.4 g (37.5 mmol) of the desired compound.

### Synthesis of Intermediate 1-2

1.0 g (3.01 mmol) of Intermediate [1-1] was added to a reaction vessel and suspended in 1.5 mL of acetone. The mixture was loaded into a photoreactor and irradiated until the reaction was complete (for about 3 hours). The residue from which the solvent was removed was separated by column chromatography to thereby obtain 0.35 g (1.17 mmol) of the desired compound.

### Synthesis of Intermediate 1-3

5.0 g (16.9 mmol) of Intermediate [1-2] was added to a reaction vessel and suspended in 64 mL of phosphoryl chloride. The reaction mixture was heated to a temperature of 110° C. and stirred for 24 hours. Once the reaction was complete, ice was poured thereupon, the pH was adjusted to neutral, and the organic layer was extracted with dichloromethane. The extracted organic layer was washed with saturated sodium chloride aqueous solution, followed by drying with sodium sulfate. The residue from which the solvent was removed was separated by column chromatography to thereby obtain 4.3 g (13.8 mmol) of the desired compound.

### Synthesis of Intermediate 1-4

4.3 g (13.8 mmol) of Intermediate [1-3], 3.3 g (16.6 mmol) of 2-methoxy-9H-carbazole, 6.3 g (27.6 mmol) of tripotassium phosphate, 0.51 g (2.76 mmol) of CuI, and 0.31 g (2.76 mmol) of picolinic acid were added to a reaction vessel. The mixture was suspended in 130 mL of dimethylsulfoxide. The reaction mixture was heated to a temperature of 160° C. and stirred for 24 hours. Once the reaction was complete, the mixture was allowed to cool to room temperature. 100 mL of distilled water was added thereto, and an organic layer was extracted using ethyl acetate. The extracted organic layer was washed with saturated sodium chloride aqueous solution, followed by drying with sodium sulfate. The residue from which the solvent was removed was separated by column chromatography to thereby obtain 4.5 g (9.5 mmol) of the desired compound.

### Synthesis of Intermediate 1-5

4.5 g (9.5 mmol) of Intermediate [1-4] was suspended in excess bromic acid. The reaction mixture was heated to a temperature of 110° C. and stirred for 24 hours. Once the reaction was complete, the mixture was cooled to room temperature, and a proper amount of sodium bicarbonate aqueous solution was added thereto for neutralization. 100 mL of distilled water was added thereto, followed by extraction using ethyl acetate. The extracted organic layer was washed with saturated sodium chloride aqueous solution, followed by drying with sodium sulfate. The residue from which the solvent was removed was separated by column chromatography to thereby obtain 3.6 g (7.8 mmol) of the desired compound.

### Synthesis of Intermediate 1-6

3.6 g (7.8 mmol) of Intermediate [1-5], 3.2 g (11.7 mmol) of 1-(3-bromophenyl)-1H-imidazole, 3.6 g (15.7 mmol) of tripotassium phosphate, 0.29 g (0.16 mmol) of CuI, and 0.017 g (0.16 mmol) of picolinic acid were added to a reaction vessel. The mixture was suspended in 50 mL of dimethylsulfoxide. The reaction mixture was heated to a temperature of 160° C. and stirred for 20 hours. Once the reaction was complete, the mixture was allowed to cool to room temperature. 50 mL of distilled water was added thereto, and an organic layer was extracted using ethyl acetate. The extracted organic layer was washed with saturated sodium chloride aqueous solution, followed by drying with sodium sulfate. The residue from which the solvent was removed was separated by column chromatography to thereby obtain 3.7 g (5.7 mmol) of the desired compound.

### Synthesis of Intermediate 1-7

3.7 g (5.7 mmol) of Intermediate [1-6] and 11.4 mmol of diphenyl iodanium were suspended in toluene. The reaction mixture was heated to a temperature of 110° C. and stirred for 24 hours. Once the reaction was complete, the mixture was allowed to cool to room temperature. 100 mL of distilled water was added thereto, and an organic layer was extracted using ethyl acetate. The extracted organic layer was washed with saturated sodium chloride aqueous solution, followed by drying with sodium sulfate. The residue from which the solvent was removed was separated by column chromatography to thereby obtain 3.6 g (4.1 mmol) of the desired compound.

### Synthesis of Compound 1

3.6 g (4.1 mmol) of Intermediate [1-7] and 1.0 g (4.5 mmol) of palladium acetate, and 1.0 g (12.3 mmol) of sodium acetate were suspended in 40 mL of dioxane. The reaction mixture was heated to a temperature of 120° C. and stirred for 24 hours. Once the reaction was complete, the mixture was allowed to cool to room temperature. 100 mL of distilled water was added thereto, and an organic layer was extracted using ethyl acetate. The extracted organic layer was washed with saturated sodium chloride aqueous solution, followed by drying with sodium sulfate. The residue from which the solvent was removed was separated by column chromatography to thereby obtain 1.2 g (1.3 mmol) of the desired compound.

### Synthesis Example 2 (Synthesis of Compound 18)

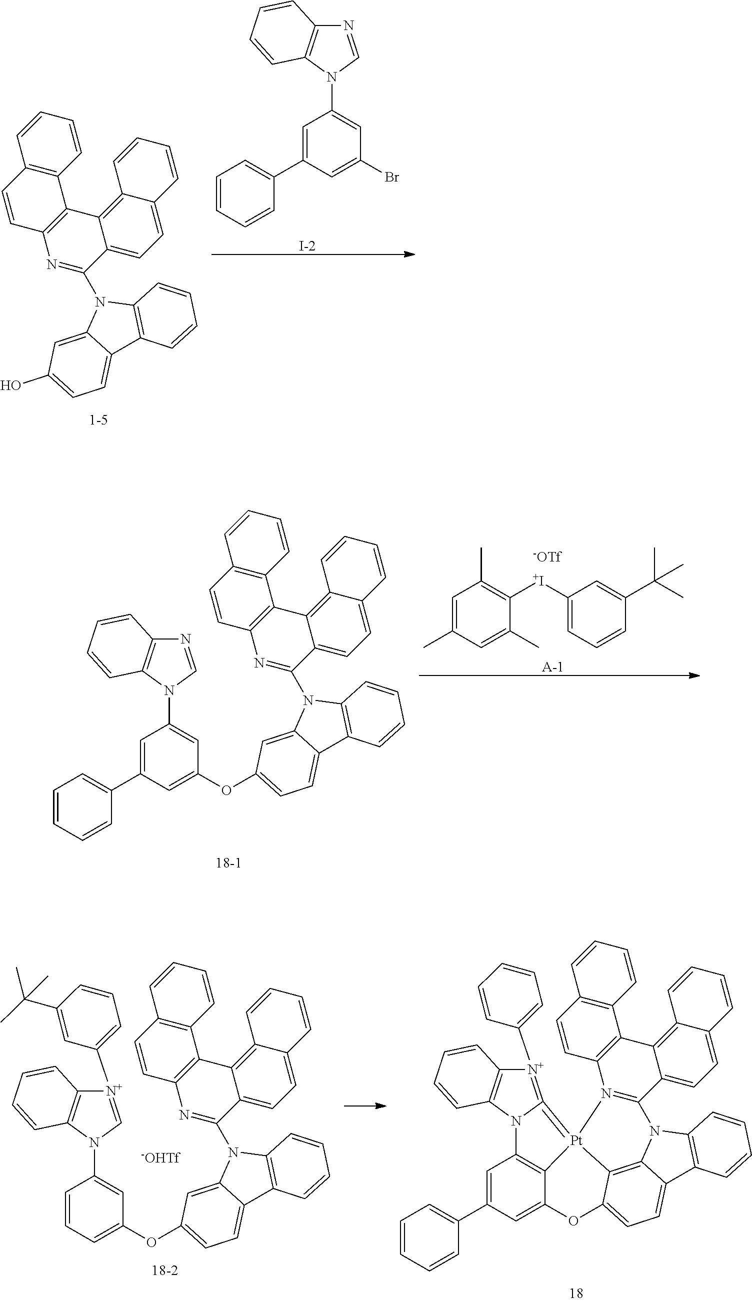

### Synthesis of Intermediate 18-1

3.6 g (7.8 mmol) of Intermediate [1-5], 4.1 g (11.7 mmol) of Intermediate [1-2], 3.6 g (15.7 mmol) of tripotassium phosphate, 0.29 g (0.16 mmol) of CuI, and 0.017 g (0.16 mmol) of picolinic acid were added to a reaction vessel. The mixture was suspended in 50 mL of dimethyl sulfoxide. The reaction mixture was heated to a temperature of 160° C. and stirred for 20 hours. Once the reaction was complete, the mixture was allowed to cool to room temperature. 50 mL of distilled water was added thereto, and an organic layer was extracted using ethyl acetate. The extracted organic layer was washed with saturated sodium chloride aqueous solution, followed by drying with sodium sulfate. The residue from which the solvent was removed was separated by column chromatography to thereby obtain 3.9 g (5.3 mmol) of the desired compound.

### Synthesis of Intermediate 18-2

3.9 g (5.3 mmol) of Intermediate [18-1] and 5.6 g (10.6 mmol) of Intermediate [A-2] were suspended in toluene. The reaction mixture was heated to a temperature of 110° C. and stirred for 24 hours. Once the reaction was complete, the mixture was allowed to cool to room temperature. 100 mL of distilled water was added thereto, and an organic layer was extracted using ethyl acetate. The extracted organic layer was washed with saturated sodium chloride aqueous solution, followed by drying with sodium sulfate. The residue from which the solvent was removed was separated by column chromatography to thereby obtain 3.9 g (3.9 mmol) of the desired compound.

### Synthesis of Compound 18

3.9 g (3.9 mmol) of Intermediate [18-2] and 0.95 g (4.3 mmol) of palladium acetate, and 0.9 g (11.7 mmol) of sodium acetate were suspended in 40 mL of dioxane. The reaction mixture was heated to a temperature of 120° C. and stirred for 24 hours. Once the reaction was complete, the mixture was allowed to cool to room temperature. 100 mL of distilled water was added thereto, and an organic layer was extracted using ethyl acetate. The extracted organic layer was washed with saturated sodium chloride aqueous solution, followed by drying with sodium sulfate. The residue from which the solvent was removed was separated by column chromatography to thereby obtain 1.9 g (1.8 mmol) of the desired compound.

### Synthesis Example 3 (Synthesis of Compound 25)

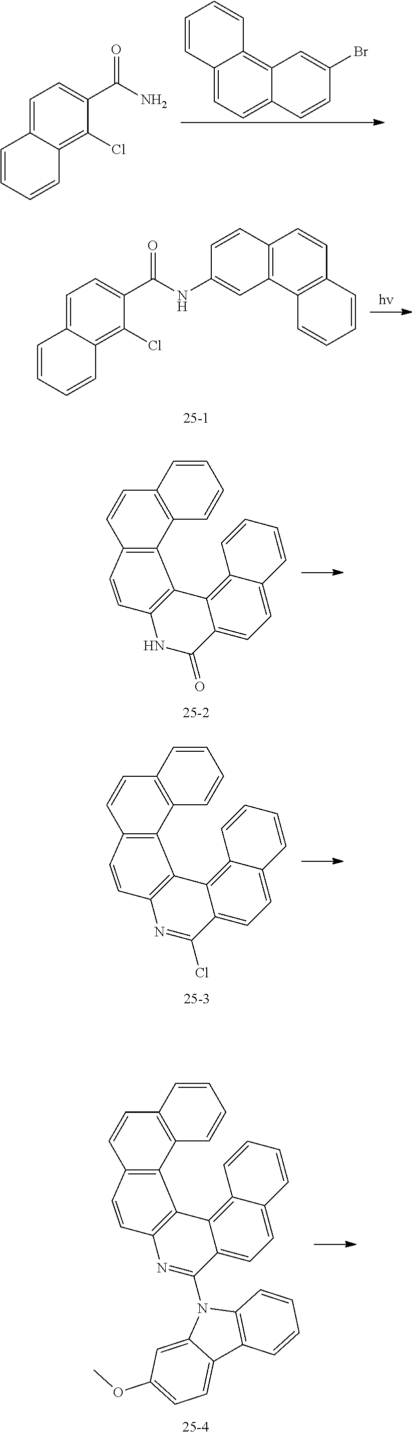 [SMILES: NC(=O)c1ccc2ccccc2c1Cl ; Brc1ccc2ccc3ccccc3c2c1 ; O=C(Nc1ccc2ccc3ccccc3c2c1)c1ccc2ccccc2c1Cl ; O=c1[nH]c2ccc3ccc4ccccc4c3c2c2c1ccc1ccccc12 ; Clc1nc2ccc3ccc4ccccc4c3c2c2c1ccc1ccccc12 ; COc1ccc2c3ccccc3n(-c3nc4ccc5ccc6ccccc6c5c4c4c3ccc3ccccc34)c2c1]

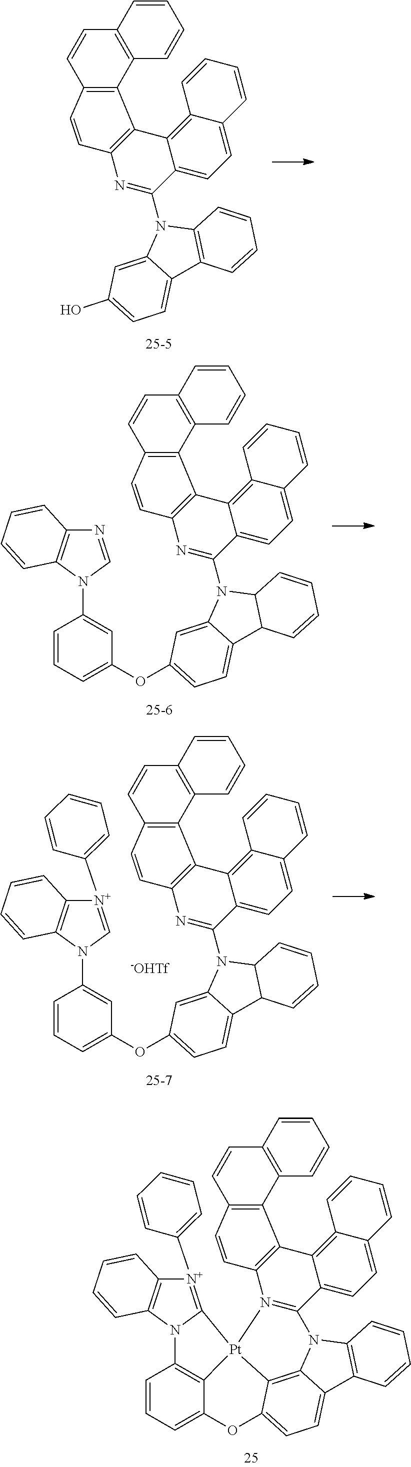

### Synthesis of Intermediate 25-1

10.3 g (50 mmol) of 1-chloro-2-naphthamide, 12.9 g (50 mmol) of 3-bromophenanthrene, 1.15 g (2.0 mmol) of Pd(dba)₂, 1.74 g (3.0 mmol) of Xantphos, and 22.8 g (70 mmol) of cesium carbonate were added to a reaction vessel and suspended in 125 mL of dioxane. The reaction mixture was heated to a temperature of 100° C. and stirred for 12 hours. Once the reaction was complete, the mixture was allowed to cool to room temperature. 100 mL of distilled water was added thereto, and an organic layer was extracted using ethyl acetate. The extracted organic layer was washed with saturated sodium chloride aqueous solution, followed by drying with sodium sulfate. The residue from which the solvent was removed was separated by column chromatography to thereby obtain 13.8 g (36.2 mmol) of the desired compound.

### Synthesis of Intermediate 25-2

1.0 g (2.6 mmol) of Intermediate [25-1] was added to a reaction vessel and suspended in 1.5 mL of acetone. The mixture was loaded into a photoreactor and irradiated until the reaction was complete (for about 3 hours). The residue from which the solvent was removed was separated by column chromatography to thereby obtain 0.66 g (1.9 mmol) of the desired compound.

### Synthesis of Intermediate 25-3

5.0 g (14.4 mmol) of Intermediate [25-2] was added to a reaction vessel and suspended in 54 mL of phosphoryl chloride. The reaction mixture was heated to a temperature of 110° C. and stirred for 24 hours. Once the reaction was complete, ice was poured thereupon, the pH was adjusted to neutral, and the organic layer was extracted with dichloromethane. The extracted organic layer was washed with saturated sodium chloride aqueous solution, followed by drying with sodium sulfate. The residue from which the solvent was removed was separated by column chromatography to thereby obtain 4.4 g (12.1 mmol) of the desired compound.

### Synthesis of Intermediate 25-4

4.4 g (12.1 mmol) of Intermediate [25-3], 2.9 g (14.6 mmol) of 2-methoxy-9H-carbazole, 5.5 g (24.3 mmol) of tripotassium phosphate, 0.45 g (2.43 mmol) of CuI, and 0.27 g (2.43 mmol) of picolinic acid were added to a reaction vessel. The mixture was suspended in 120 mL of dimethylsulfoxide. The reaction mixture was heated to a temperature of 160° C. and stirred for 24 hours. Once the reaction was complete, the mixture was allowed to cool to room temperature. 100 mL of distilled water was added thereto, and an organic layer was extracted using ethyl acetate. The extracted organic layer was washed with saturated sodium chloride aqueous solution, followed by drying with sodium sulfate. The residue from which the solvent was removed was separated by column chromatography to thereby obtain 4.9 g (9.3 mmol) of the desired compound.

### Synthesis of Intermediate 25-5

4.9 g (9.3 mmol) of Intermediate [25-4] was suspended in excess bromic acid. The reaction mixture was heated to a temperature of 110° C. and stirred for 24 hours. Once the reaction was complete, the mixture was cooled to room temperature, and a proper amount of sodium bicarbonate aqueous solution was added thereto for neutralization. 100 mL of distilled water was added thereto, followed by extraction using ethyl acetate. The extracted organic layer was washed with saturated sodium chloride aqueous solution, followed by drying with sodium sulfate. The residue from which the solvent was removed was separated by column chromatography to thereby obtain 4.0 g (7.8 mmol) of the desired compound.

### Synthesis of Intermediate 25-6

4.0 g (7.8 mmol) of Intermediate [25-5], 3.2 g (11.7 mmol) of 1-(3-bromophenyl)-1H-imidazole, 3.6 g (15.7 mmol) of tripotassium phosphate, 0.29 g (0.16 mmol) of CuI, and 0.017 g (0.16 mmol) of picolinic acid were added to a reaction vessel. The mixture was suspended in 50 mL of dimethylsulfoxide. The reaction mixture was heated to a temperature of 160° C. and stirred for 20 hours. Once the reaction was complete, the mixture was allowed to cool to room temperature. 50 mL of distilled water was added thereto, and an organic layer was extracted using ethyl acetate. The extracted organic layer was washed with saturated sodium chloride aqueous solution, followed by drying with sodium sulfate. The residue from which the solvent was removed was separated by column chromatography to thereby obtain 3.9 g (5.5 mmol) of the desired compound.

### Synthesis of Intermediate 25-7

3.9 g (5.5 mmol) of Intermediate [25-6] and 11.0 mmol of diphenyl iodanium were suspended in toluene. The reaction mixture was heated to a temperature of 110° C. and stirred for 24 hours. Once the reaction was complete, the mixture was allowed to cool to room temperature. 100 mL of distilled water was added thereto, and an organic layer was extracted using ethyl acetate. The extracted organic layer was washed with saturated sodium chloride aqueous solution, followed by drying with sodium sulfate. The residue from which the solvent was removed was separated by column chromatography to thereby obtain 3.7 g (4.0 mmol) of the desired compound.

### Synthesis of Compound 25

3.7 g (4.0 mmol) of Intermediate [25-7] and 0.98 g (4.4 mmol) of palladium acetate, and 0.98 g (12.0 mmol) of sodium acetate were suspended in 40 mL of dioxane. The reaction mixture was heated to a temperature of 120° C. and stirred for 24 hours. Once the reaction was complete, the mixture was allowed to cool to room temperature. 100 mL of distilled water was added thereto, and an organic layer was extracted using ethyl acetate. The extracted organic layer was washed with saturated sodium chloride aqueous solution, followed by drying with sodium sulfate. The residue from which the solvent was removed was separated by column chromatography to thereby obtain 1.3 g (1.3 mmol) of the desired compound.

### Synthesis Example 4 (Synthesis of Compound 37)

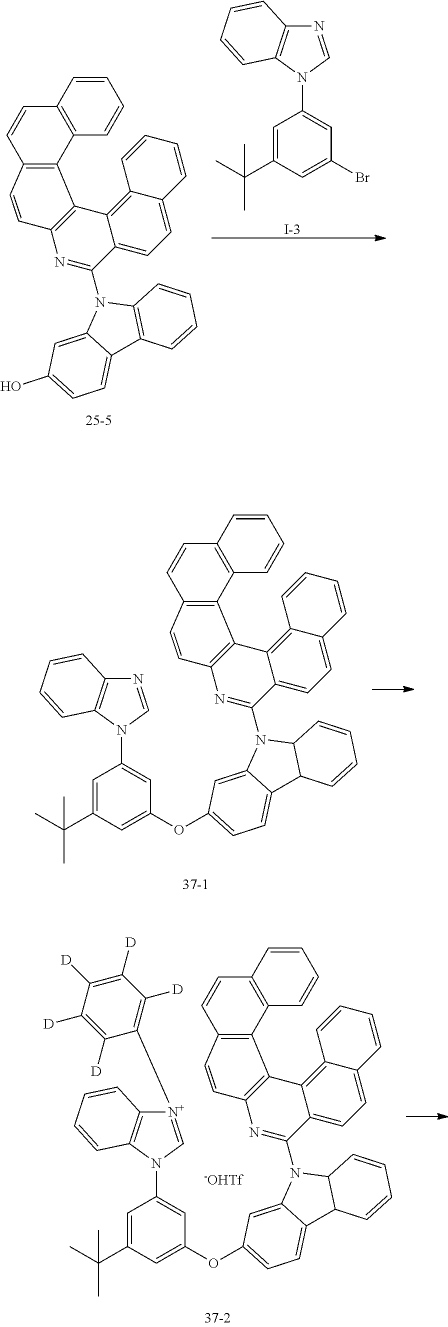

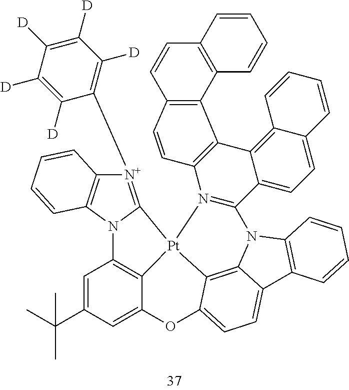

### Synthesis of Intermediate 37-1

4.0 g (7.8 mmol) of Intermediate [25-5], 3.9 g (11.7 mmol) of Intermediate [1-3], 3.6 g (15.7 mmol) of tripotassium phosphate, 0.29 g (0.16 mmol) of CuI, and 0.017 g (0.16 mmol) of picolinic acid were added to a reaction vessel. The mixture was suspended in 80 mL of dimethylsulfoxide. The reaction mixture was heated to a temperature of 160° C. and stirred for 20 hours. Once the reaction was complete, the mixture was allowed to cool to room temperature. 50 mL of distilled water was added thereto, and an organic layer was extracted using ethyl acetate. The extracted organic layer was washed with saturated sodium chloride aqueous solution, followed by drying with sodium sulfate. The residue from which the solvent was removed was separated by column chromatography to thereby obtain 4.2 g (5.5 mmol) of the desired compound.

### Synthesis of Intermediate 37-2

3.9 g (5.3 mmol) of Intermediate [37-1] and 11.0 mmol of deuterated diphenyl iodanium were suspended in toluene. The reaction mixture was heated to a temperature of 110° C. and stirred for 24 hours. Once the reaction was complete, the mixture was allowed to cool to room temperature. 100 mL of distilled water was added thereto, and an organic layer was extracted using ethyl acetate. The extracted organic layer was washed with saturated sodium chloride aqueous solution, followed by drying with sodium sulfate. The residue from which the solvent was removed was separated by column chromatography to thereby obtain 3.7 g (3.7 mmol) of the desired compound.

### Synthesis of Compound 37

3.7 g (3.7 mmol) of Intermediate [37-2] and 0.9 g (4.1 mmol) of palladium acetate, and 0.9 g (11.1 mmol) of sodium acetate were suspended in 40 mL of dioxane. The reaction mixture was heated to a temperature of 120° C. and stirred for 24 hours. Once the reaction was complete, the mixture was allowed to cool to room temperature. 100 mL of distilled water was added thereto, and an organic layer was extracted using ethyl acetate. The extracted organic layer was washed with saturated sodium chloride aqueous solution, followed by drying with sodium sulfate. The residue from which the solvent was removed was separated by column chromatography to thereby obtain 1.6 g (1.5 mmol) of the desired compound.

### Synthesis Example 5 (Synthesis of Compound 41)

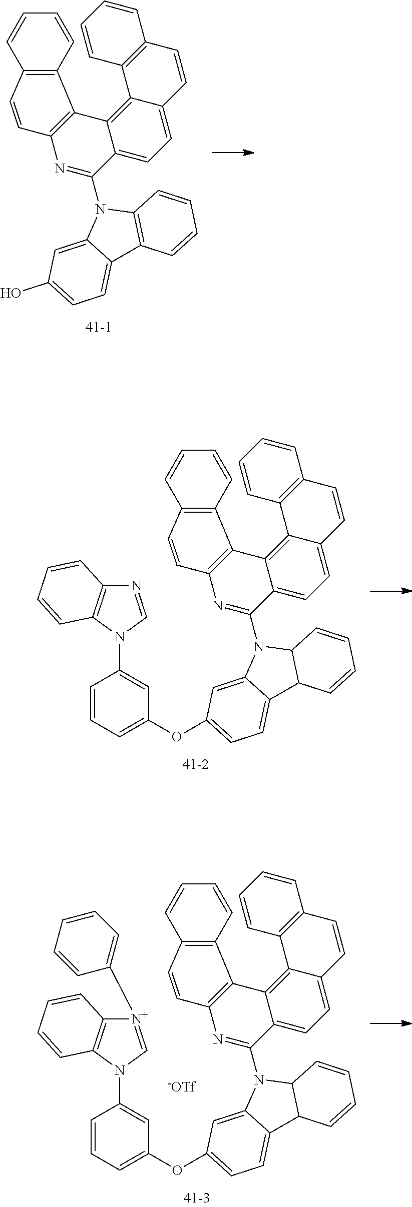 [SMILES: Oc1ccc2c3ccccc3n(-c3nc4ccc5ccccc5c4c4c3ccc3ccc5ccccc5c34)c2c1 ; C1=CC2c3ccc(Oc4cccc(-n5cnc6ccccc65)c4)cc3N(c3nc4ccc5ccccc5c4c4c3ccc3ccc5ccccc5c34)C2C=C1 ; C1=CC2c3ccc(Oc4cccc(-n5c[n+](-c6ccccc6)c6ccccc65)c4)cc3N(c3nc4ccc5ccccc5c4c4c3ccc3ccc5ccccc5c34)C2C=C1 ; "-OTf"]

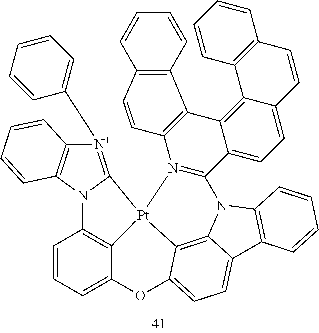

### Synthesis of Intermediate 41-2

The desired compound was obtained in the same manner as in Synthesis of Intermediate [1-6] in Synthesis Example 1, except that Intermediate [41-1] was used instead of Intermediate [1-5].

### Synthesis of Intermediate 41-3

The desired compound was obtained in the same manner as in Synthesis of Intermediate [1-7] in Synthesis Example 1, except that Intermediate [41-2] was used instead of Intermediate [1-6].

### Synthesis of Compound 41

The desired compound 1.4 g (1.4 mmol) was obtained in the same manner as in Synthesis of Compound 1 in Synthesis Example 1, except that Intermediate [41-3] was used instead of Intermediate [1-7].

### Synthesis Example 6 (Synthesis of Compound 42)

1.1 g (1.2 mmol) of the desired compound was obtained in the same manner as in Synthesis of Compound 1 in Synthesis Example 1, except that 2-methoxy-3,6-dimethyl-9H-carbazole was used instead of 2-methoxy-9H-carbazole.

### Synthesis Example 7 (Synthesis of Compound 43)

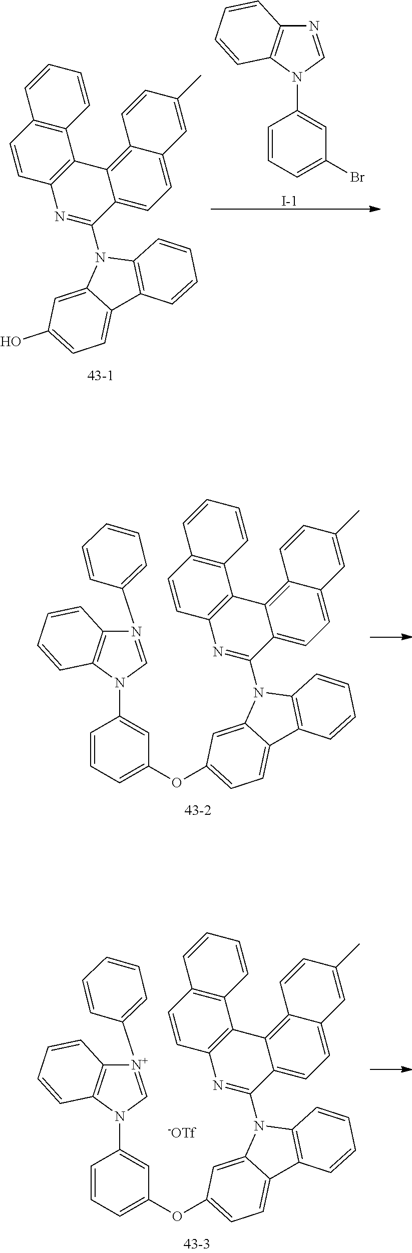

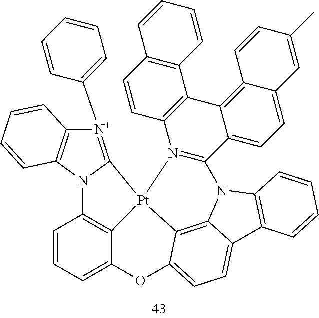

### Synthesis of Intermediate 43-2

The desired compound was obtained in the same manner as in Synthesis of Intermediate [1-6] in Synthesis Example 1, except that Intermediate [43-1] was used instead of Intermediate [1-5].

### Synthesis of Intermediate 43-3

The desired compound was obtained in the same manner as in Synthesis of Intermediate [1-7] in Synthesis Example 1, except that Intermediate [43-2] was used instead of Intermediate [1-6].

### Synthesis of Compound 43

1.1 g (1.2 mmol) of the desired compound was obtained in the same manner as in Synthesis of Compound 1 in Synthesis Example 1, except that Intermediate [43-3] was used instead of Intermediate [1-7].

### Synthesis Example 8 (Synthesis of Compound 44)

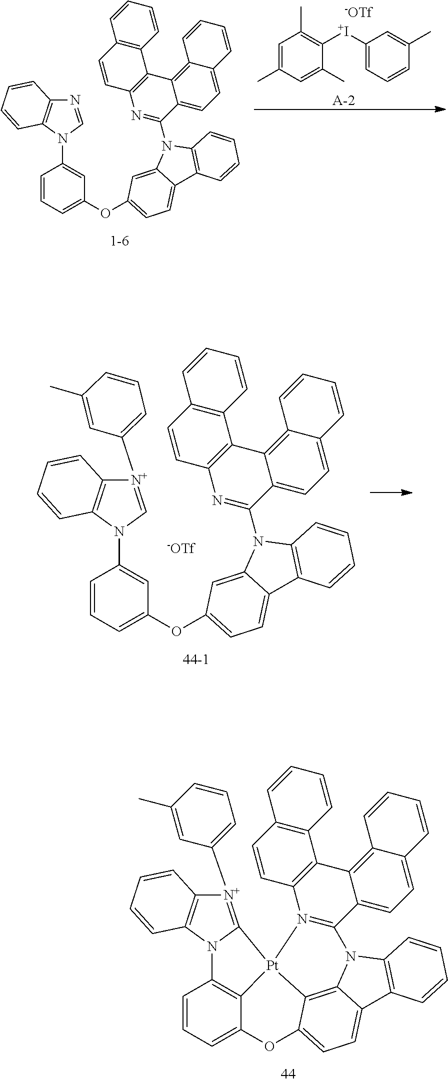

### Synthesis of Intermediate 44-1

The desired compound was obtained in the same manner as in Synthesis of Intermediate [1-7] in Synthesis Example 1, except that Intermediate [A-2] was used instead of Intermediate [A-1].

### Synthesis of Compound 44

1.3 g (1.4 mmol) of the desired compound was obtained in the same manner as in Synthesis of Compound 1 in Synthesis Example 1, except that Intermediate [44-1] was used instead of Intermediate [1-7].

### Synthesis Example 9 (Synthesis of Compound 45)

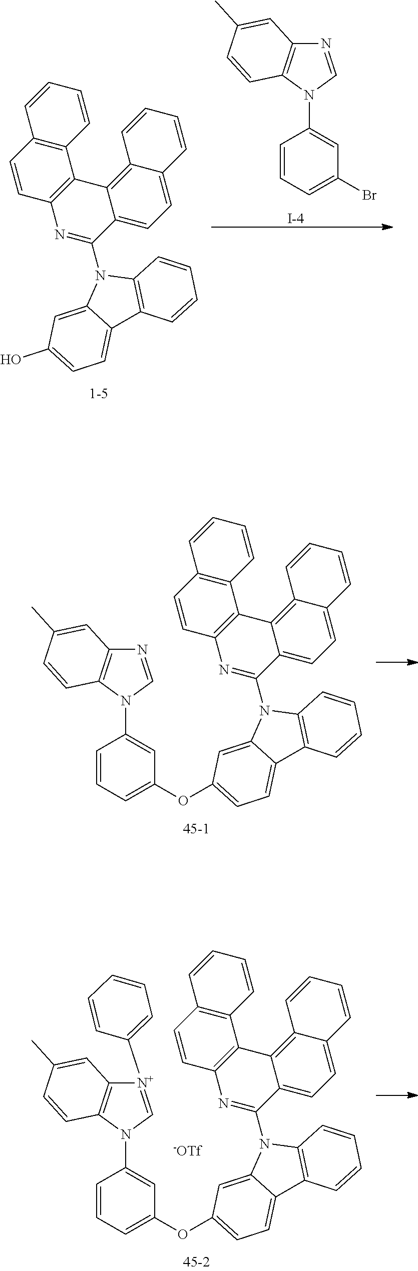

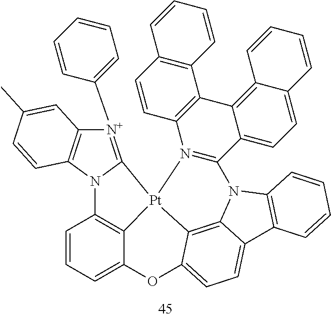

### Synthesis of Intermediate 45-1

The desired compound was obtained in the same manner as in Synthesis of Intermediate [1-6] in Synthesis Example 1, except that Intermediate [1-4] was used instead of Intermediate [1-1].

### Synthesis of Intermediate 45-2

The desired compound was obtained in the same manner as in Synthesis of Intermediate [1-7] in Synthesis Example 1, except that Intermediate [45-1] was used instead of Intermediate [1-6].

### Synthesis of Compound 45

1.4 g (1.5 mmol) of the desired compound was obtained in the same manner as in Synthesis of Compound 1 in Synthesis Example 1, except that Intermediate [45-2] was used instead of Intermediate [1-7].

Compounds synthesized in Synthesis Examples 1 to 9 were identified by ¹H nuclear magnetic resonance (NMR) and mass spectroscopy/fast atom bombardment (MS/FAB). The results thereof are shown in Table 1. Methods of synthesizing compounds other than the compounds synthesized in Synthesis Examples 1 to 9 may be readily understood to those skilled in the art by referring to the synthesis pathways and raw materials described above.

TABLE 1

| | | MS/FAB | |
|---|---|---|---|
| Compound | ¹H-NMR (CDCl₃, 500 MHZ) | calc. | Found |
| 1 | δ 8.54(d, 2 H), 8.39(d, 1 H), 8.19(d, 1 H), 8.08-7.99(m, 5 H), | 921.2068 | 921.2071 |
| | 7.63-7.36(m, 10 H), 7.20-7.14(m, 4 H), 7.00-6.90(m, 5 H), | | |
| | 6.69-6.66(m, 2 H) | | |
| 18 | δ 8.54(d, 2 H), 8.39(d, 1 H), 8.19(d, 1 H), 8.08-7.99(m, 5 H), | 1053.3007 | 1053.3002 |
| | 7.63-7.36(m, 13 H), 7.20-7.07(m, 5 H), 6.99-6.95(m, 4 H), | | |
| | 6.80(m, 1 H), | | |
| | 6.69(d, 1 H), 1.26 (s, 9 H) | | |
| 25 | δ 8.97(d, 1 H), 8.54(d, 1 H), 8.39(d, 1 H), 8.19-8.08(m, 3 H), | 971.2224 | 971.2219 |
| | 7.99-7.36(m, 15 H), 7.20-7.14(m, 4 H), 7.00-6.90(m, 5 H), | | |
| | 6.69-6.66(m, 2 H) | | |
| 37 | δ 8.97(d, 1 H), 8.54(d, 1 H), 8.39(d, 1 H), 8.19-8.08(m, 3 H), | 1032.3164 | 1032.3167 |
| | 7.99-7.50(m, 12 H), 7.20-7.12(m, 4 H), 6.96-6.95(m, 2 H), | | |
| | 6.70-6.69(m, 2 H), 1.32 (s, 9 H) | | |
| 41 | δ 8.98(d, 1 H), 8.54(d, 1 H), 8.39-8.34(m, 2 H), 8.19-8.07(m, | 971.2224 | 971.2228 |
| | 4 H), 7.81-7.75(m, 2 H), 7.68-7.36(m, 11 H), 7.20-7.14(m, | | |
| | 4 H), 7.00-6.90(m, 5 H), 6.69-6.66(m, 2 H), | | |
| 42 | δ 8.76(s, 1 H), 8.54(d, 2 H), 8.08-7.99(m, 6 H), 7.68-7.53(m, | 949.2381 | 949.2390 |
| | 6 H), 7.41-7.38(m, 4 H), 7.17-7.14(m, 3 H), 7.00-6.90(m, | | |
| | 5 H), 6.66(d, 1 H), 2.46 (s, 3 H), 2.15 (s, 3 H) | | |
| 43 | δ 8.54(d, 1 H), 8.39(d, 1 H), 8.19-8.08(m, 2 H), 7.99-7.97(m, | 935.2224 | 935.2220 |
| | 2 H), 7.84-7.80(m, 2 H), 7.60-7.36(m, 10 H), 7.20-7.14(m, | | |
| | 4 H), 7.00-6.90(m, 5 H), 6.69-6.66(m, 2 H), 2.66 (s, 3 H) | | |
| 44 | δ 8.54(d, 2 H), 8.39(d, 1 H), 8.19(d, 1 H), 8.08-7.99(m, 5 H), | 935.2224 | 935.2221 |
| | 7.63-7.50(m, 7 H), 7.20-7.14(m, 6 H), 7.00-6.90(m, 4 H), | | |
| | 6.79(d, 1 H), | | |
| | 6.69-6.66(m, 2 H), 2.27 (s, 3 H) | | |
| 45 | δ 8.54(d, 2 H), 8.39(d, 1 H), 8.19(d, 1 H), 8.08-7.99(m, 5 H), | 935.2224 | 935.2219 |
| | 7.61-7.36(m, 9 H), 7.20-7.09(m, 4 H), 7.01-7.00(m, 2 H), | | |
| | 6.79(d, 1 H), 6.60 (d, 1 H), 6.81 (d, 1 H), 6.69-6.66(m, 2 H), | | |
| | 2.28 (s, 3 H) | | |

### Evaluation Example 1: Material Property Evaluation

The highest occupied molecular orbital (HOMO) energy level, lowest unoccupied molecular orbital (LUMO) energy level (unit: electron volts (eV)), maximum emission wavelength (nm), and a presence rate (%) of triplet metal-to-ligand charge transfer state (³MLCT) of Compounds 1, 18, 25, 37, 41, 42, 43, 44, and 45, and Compounds C1 and C2 as comparative compounds were evaluated by using a density functional theory (DFT) method of the Gaussian09 program which is structure-optimized at the B3LYP/6-311g(d,p)/LANL2DZ. The results thereof are shown in Table 2.

TABLE 2

| Compound | HOMO | LUMO | λₘₐₓ | ³MLCT |
|---|---|---|---|---|
| No. | (eV) | (eV) | (nm) | (%) |
| 1 | −4.97 | −2.25 | 510 | 25.93 |
| 18 | −4.91 | −2.30 | 522 | 26.12 |
| 25 | −4.97 | −2.32 | 519 | 24.41 |
| 37 | −4.92 | −2.32 | 525 | 25.67 |
| 41 | −4.98 | −2.26 | 515 | 20.01 |
| 42 | −4.92 | −2.21 | 516 | 16.02 |
| 43 | −4.95 | −2.20 | 511 | 30.39 |
| 44 | −4.96 | −2.25 | 515 | 22.35 |
| 45 | −4.94 | −2.23 | 513 | 21.82 |
| C1 | −4.99 | −2.05 | 494 | 13.26 |
| C2 | −4.97 | −2.22 | 502 | 23.22 |

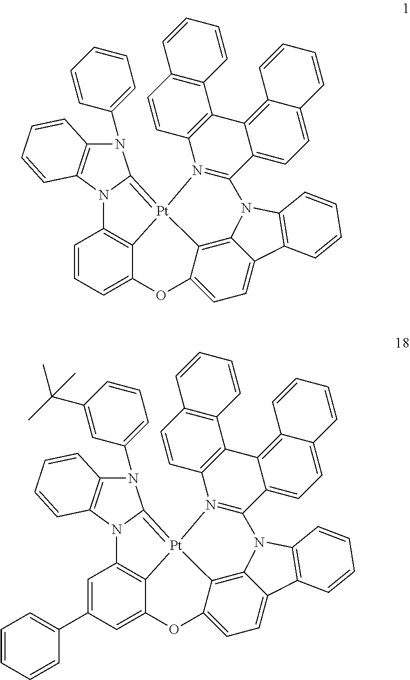

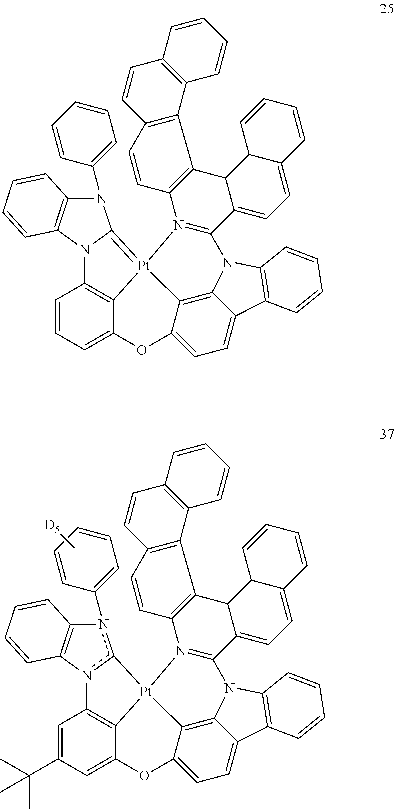

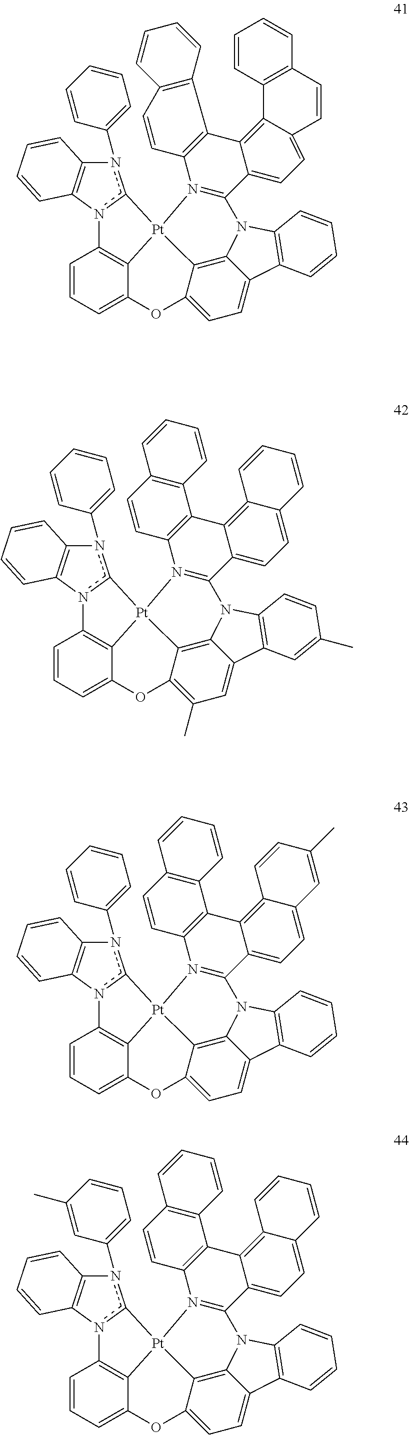

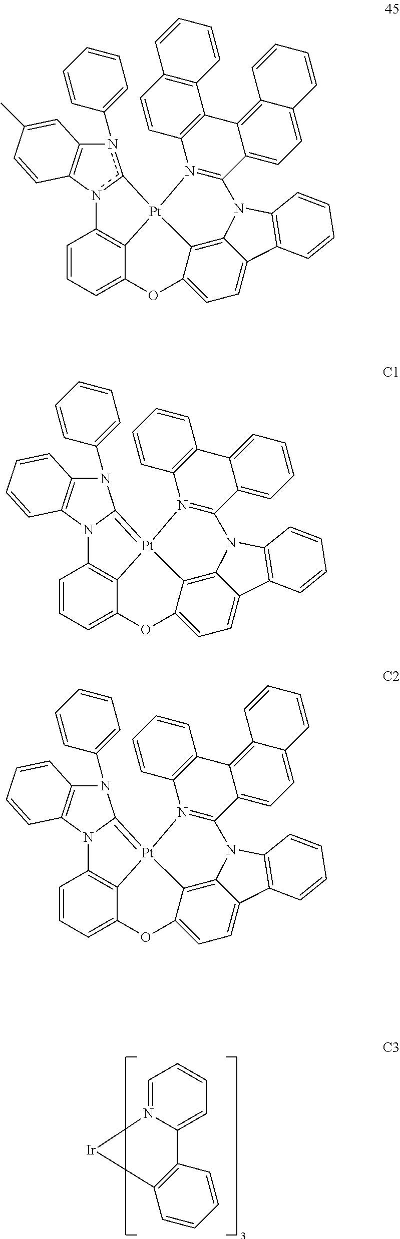

Referring to the results of Table 2, Compounds 1, 18, 25, 37, 41, 42, 43, 44, and 45, as compared with Compounds C1 and C2, were found to have 510 nm or greater λₘₐₓ value. Thus, it was found that Compounds 1, 18, 25, 37, 41, 42, 43, 44, and 45 had improved color-coordinate. Compounds 1, 18, 25, 37, 41, 42, 43, 44, and 45 were also found to have 3MLCT values equal to or better than Compounds C1 and C2.

### Example 1

As an anode, a 15 Ohms per square centimeter (Ω/cm²) (1,200 Å) ITO glass substrate (available from Corning Co., Ltd) was cut to a size of 50 millimeters (mm)×50 mm×0.7 mm, sonicated in isopropyl alcohol and pure water for 5 minutes in each solvent, cleaned with ultraviolet rays for 30 minutes, and then ozone, and was mounted on a vacuum deposition apparatus.

2-TNATA was vacuum-deposited on the anode to form a hole injection layer having a thickness of 600 Å, and 4,4′-bis[N-(1-naphthyl)-N-phenylamino]biphenyl (hereinafter, referred to as “NPB”) was vacuum-deposited on the hole injection layer to form a hole transport layer having a thickness of 300 Å.

Compound ETH2 (the second compound), Compound HTH29 (the third compound), and Compound 1 (dopant, the first compound) were vacuum-deposited on the hole transport layer to form an emission layer having a thickness of 400 Å. Here, the content of Compound 1 was 10 wt %, based on 100 wt % of the total weight of the emission layer, and the weight ratio of Compound ETH2 to Compound HTH29 was 3:7.

Compound ETH2 was vacuum-deposited on the emission layer to form a hole blocking layer having a thickness of 50 Å, Alq₃ was vacuum-deposited on the hole blocking layer to form an electron transport layer having a thickness of 300 Å, LiF was vacuum-deposited on the electron transport layer to form an electron injection layer having a thickness of 10 Å, and Al was vacuum-deposited on the electron injection layer having a thickness of 3,000 Å, thereby completing the manufacture of an organic light-emitting device.

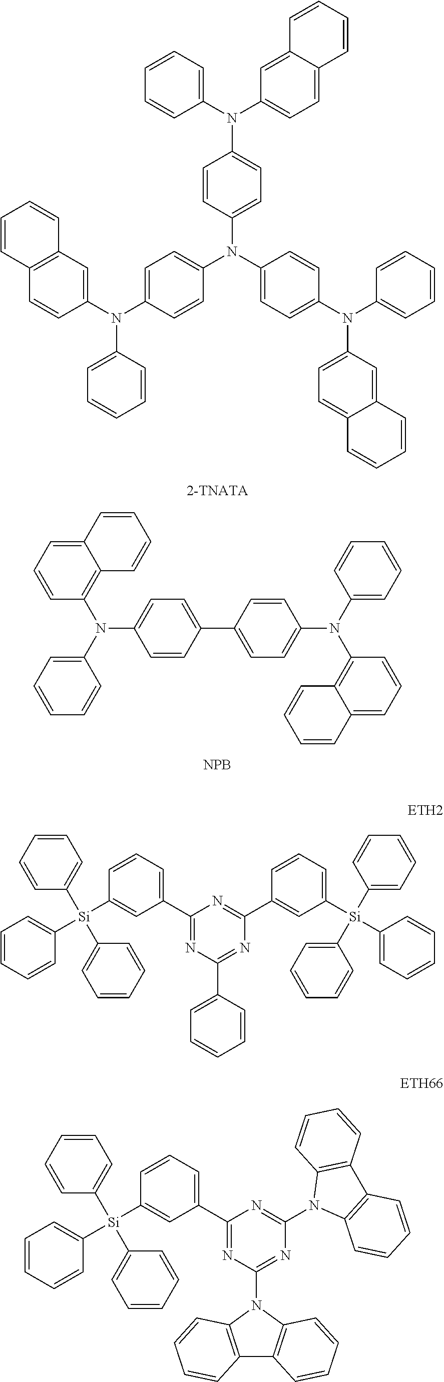 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1 ; "NPB" ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

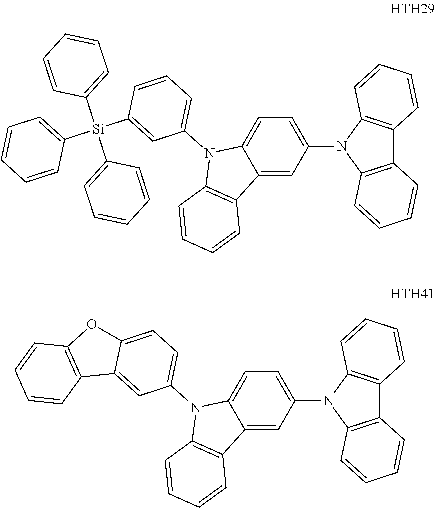 [SMILES: c1ccc([Si](c2ccccc2)(c2ccccc2)c2cccc(-n3c4ccccc4c4cc(-n5c6ccccc6c6ccccc65)ccc43)c2)cc1 ; c1ccc2c(c1)oc1ccc(-n3c4ccccc4c4cc(-n5c6ccccc6c6ccccc65)ccc43)cc12]

### Examples 2 to 9 and Comparative Examples 1 to 3

Organic light-emitting devices were manufactured in the same manner as in Example 1, except that compounds shown in Table 3 were used instead of Compound 1 in formation of an emission layer.

### Evaluation Example 2: Device Performance Evaluation

The performance of each of the organic light-emitting devices of Examples 1 to 9 and Comparative Examples 1 to 3 was evaluated. The driving voltage, luminance, luminescence efficiency, maximum emission wavelength, and lifespan at a current density of 50 mA/cm² were measured by using Keithley 236 source-measure unit (SMU) and a PR650 luminance meter. The results thereof are shown in Table 3.

TABLE 3

| | | | | | Maximum | |
|---|---|---|---|---|---|---|
| Light- | | Driving | | Luminescence | emission | Lifespan |
| emitting | Dopant | voltage | Luminance | efficiency | wavelength | (RT_{80%}@ J = 40 |
| device | compound | [V] | [cd/m²] | [cd/A] | [nm] | mA/cm²) [hr] |
| Example 1 | 1 | 4.9 | 3980 | 7.94 | 515 | 301 |
| Example 2 | 18 | 4.8 | 4170 | 8.33 | 530 | 460 |
| Example 3 | 25 | 5.1 | 4015 | 8.01 | 523 | 342 |
| Example 4 | 37 | 5.3 | 4130 | 8.25 | 527 | 438 |
| Example 5 | 41 | 5.4 | 3995 | 7.98 | 518 | 310 |
| Example 6 | 42 | 5.0 | 3960 | 7.90 | 520 | 280 |
| Example 7 | 43 | 5.2 | 4060 | 8.12 | 515 | 316 |
| Example 8 | 44 | 4.9 | 4030 | 8.05 | 519 | 308 |
| Example 9 | 45 | 5.0 | 3985 | 7.95 | 517 | 295 |
| Comparative | C1 | 4.9 | 3655 | 7.28 | 492 | 109 |
| Example 1 | | | | | | |
| Comparative | C2 | 5.1 | 3780 | 7.53 | 503 | 135 |
| Example 2 | | | | | | |
| Comparative | C3 | 6.74 | 3870 | 7.74 | 516 | 278 |
| Example 3 | | | | | | |

Referring to the results shown in Table 3, it was found that the organic light-emitting devices manufactured in Examples 1 to 9 exhibited high luminance, excellent luminescence efficiency, and long lifespan characteristics, as compared with those of the organic light-emitting devices manufactured in Comparative Examples 1 to 3.

As apparent from the foregoing description, the organometallic compound of Formula 1 was found to have improved structural stability and emit green light with improved color-coordinate.

An electroluminescent device including the organometallic compound may have high luminance, high efficiency, and long lifespan.

Embodiments have been disclosed herein, and although terms are employed, they are used and are to be interpreted in a generic and descriptive sense only and not for purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light-emitting device comprising:
a first electrode;
a second electrode facing the first electrode;
an organic layer between the first electrode and the second electrode and comprising an emission layer; and
at least one organometallic compound represented by Formula 1: 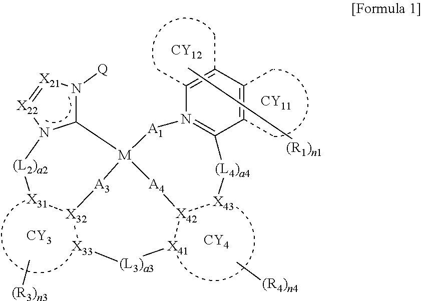
wherein in Formula 1,
M is a transition metal,
ring CY₁₁ and ring CY₁₂ are each independently a C₆-C₆₀ aromatic ring or a C₁-C₆₀ heteroaromatic ring,
ring CY₃ and ring CY₄ are each independently a C₆-C₆₀ carbocyclic group or a C₁-C₆₀ heterocyclic group,
A₁, A₃, and A₄ are each independently a direct bond, O, or S,
L₂, L₃, and L₄ are each independently a direct bond, O, or S,
a2, a3, and a4 are each independently an integer from 1 to 4,
when L₂ is a direct bond, a2 is 1,
when L₃ is a direct bond, a3 is 1,
when L₄ is a direct bond, a4 is 1,
when a2 is 2 or greater, at least two L₂(s) are identical to or different from each other,
when a3 is 2 or greater, at least two L₃(s) are identical to or different from each other, and
when a4 is 2 or greater, at least two L₄(s) are identical to or different from each other,
X₂₁ and X₂₂ are each independently C(R) or N,
X₃₁, X₃₂, X₃₃, X₄₁, X₄₂, and X₄₃ are each independently C or N,
R and Q are each independently hydrogen, deuterium, —F, —Cl, —Br, —I, a hydroxyl group, a cyano group, a nitro group, a C₁-C₆₀ alkyl group unsubstituted or substituted with at least one R₂, a C₂-C₆₀ alkenyl group unsubstituted or substituted with at least one R₂, a C₂-C₆₀ alkynyl group unsubstituted or substituted with at least one R₂, a C₁-C₆₀ alkoxy group unsubstituted or substituted with at least one R₂, a C₃-C₆₀ carbocyclic group unsubstituted or substituted with at least one R₂, a C₁-C₆₀ heterocyclic group unsubstituted or substituted with at least one R₂, a C₆-C₆₀ aryloxy group unsubstituted or substituted with at least one R₂, a C₆-C₆₀ arylthio group unsubstituted or substituted with at least one R₂, a C₇-C₆₀ aryl alkyl group unsubstituted or substituted with at least one R₂, a C₂-C₆₀ heteroaryl alkyl group unsubstituted or substituted with at least one R₂,
R(s) are optionally bound to each other to form a C₃-C₆₀ carbocyclic group unsubstituted or substituted with at least one R₂ or a C₁-C₆₀ heterocyclic group unsubstituted or substituted with at least one R₂,
R₁, R₂, R₃, and R₄ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ aryl alkyl group unsubstituted or substituted with at least one R₁₀ₐ, a C₂-C₆₀ heteroaryl alkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
n1 is an integer from 0 to 20,
when n1 is 2 or greater, at least two R₁(s) are identical to or different from each other,
n3 and n4 are each independently an integer from 0 to 10,
when n3 is 2 or greater, at least two R₃(s) are identical to or different from each other,
when n4 is 2 or greater, at least two R₄(s) are identical to or different from each other,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
wherein Q₁ to Q₃, Q₁₁ to Q₁₃, Q₂₁ to Q₂₃, and Q₃₁ to Q₃₃ are each independently:
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group; or
a C₃-C₆₀ carbocyclic group, a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆₀ alkoxy group, a phenyl group, a biphenyl group, or a combination thereof.

2. The light-emitting device of claim 1, wherein the emission layer comprises the organometallic compound.

3. The light-emitting device of claim 1, wherein
the emission layer comprises a host and a dopant, and
the dopant comprises the organometallic compound.

4. The light-emitting device of claim 1, wherein the emission layer emits light having a maximum emission wavelength in a range of about 490 nm to about 530 nm.

5. The light-emitting device of claim 1, wherein
the first electrode is an anode,
the second electrode is a cathode,
the organic layer further comprises:
a hole transport region between the first electrode and the emission layer; and
an electron transport region between the emission layer and the second electrode,
the hole transport region comprises a hole injection layer, a hole transport layer, an electron blocking layer, a buffer layer, or a combination thereof, and
the electron transport region comprises a hole blocking layer, an electron transport layer, an electron injection layer, or a combination thereof.

6. An electronic apparatus comprising a light-emitting device of claim 1.

7. The electronic apparatus of claim 6, further comprising:
a thin-film transistor; and
a color filter, a color-conversion layer, a touchscreen layer, a polarizing layer, or a combination thereof, wherein
the thin-film transistor comprises a source electrode and a drain electrode, and
the first electrode of the light-emitting device is electrically connected to the source electrode or the drain electrode.

8. An electronic equipment comprising the light-emitting device of claim 1, wherein
the electronic equipment is a flat panel display, a curved display, a computer monitor, a medical monitor, a television, an advertisement board, an indoor light, an outdoor light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a 3D display, a virtual reality display, an augmented reality display, a vehicle, a video wall comprising multiple displays tiled together, a theater screen, a stadium screen, a phototherapy device, or a sign.

9. An organometallic compound represented by Formula 1: 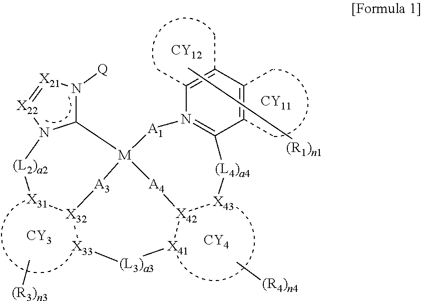
wherein in Formula 1,
M is a transition metal,
ring CY₁₁ and ring CY₁₂ are each independently a C₆-C₆₀ aromatic ring or a C₁-C₆₀ heteroaromatic ring,
ring CY₃ and ring CY₄ are each independently a C₆-C₆₀ carbocyclic group or a C₁-C₆₀ heterocyclic group,
A₁, A₃, and A₄ are each independently a direct bond, O, or S,
L₂, L₃, and L₄ are each independently a direct bond, O, or S,
a2, a3, and a4 are each independently an integer from 1 to 4,
when L₂ is a direct bond, a2 is 1,
when L₃ is a direct bond, a3 is 1,
when L₄ is a direct bond, a4 is 1,
when a2 is 2 or greater, at least two L₂(s) are identical to or different from each other,
when a3 is 2 or greater, at least two L₃(s) are identical to or different from each other, and
when a4 is 2 or greater, at least two L₄(s) are identical to or different from each other,
X₂₁ and X₂₂ are each independently C(R) or N,
X₃₁, X₃₂, X₃₃, X₄₁, X₄₂, and X₄₃ are each independently C or N,
R and Q are each independently hydrogen, deuterium, —F, —Cl, —Br, —I, a hydroxyl group, a cyano group, a nitro group, a C₁-C₆₀ alkyl group unsubstituted or substituted with at least one R₂, a C₂-C₆₀ alkenyl group unsubstituted or substituted with at least one R₂, a C₂-C₆₀ alkynyl group unsubstituted or substituted with at least one R₂, a C₁-C₆₀ alkoxy group unsubstituted or substituted with at least one R₂, a C₃-C₆₀ carbocyclic group unsubstituted or substituted with at least one R₂, a C₁-C₆₀ heterocyclic group unsubstituted or substituted with at least one R₂, a C₆-C₆₀ aryloxy group unsubstituted or substituted with at least one R₂, a C₆-C₆₀ arylthio group unsubstituted or substituted with at least one R₂, a C₇-C₆₀ aryl alkyl group unsubstituted or substituted with at least one R₂, a C₂-C₆₀ heteroaryl alkyl group unsubstituted or substituted with at least one R₂,
R(s) are optionally bound to each other to form a C₃-C₆₀ carbocyclic group unsubstituted or substituted with at least one R₂ or a C₁-C₆₀ heterocyclic group unsubstituted or substituted with at least one R₂,
R₁, R₂, R₃, and R₄ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ aryl alkyl group unsubstituted or substituted with at least one R₁₀ₐ, a C₂-C₆₀ heteroaryl alkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
n1 is an integer from 0 to 20,
when n1 is 2 or greater, at least two R₁(s) are identical to or different from each other,
n3 and n4 are each independently an integer from 0 to 10,
when n3 is 2 or greater, at least two R₃(s) are identical to or different from each other,
when n4 is 2 or greater, at least two R₄(s) are identical to or different from each other,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
wherein Q₁ to Q₃, Q₁₁ to Q₁₃, Q₂₁ to Q₂₃, and Q₃₁ to Q₃₃ are each independently:
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group, or
a C₃-C₆₀ carbocyclic group, a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆₀ alkoxy group, a phenyl group, a biphenyl group, or a combination thereof.

10. The organometallic compound of claim 9, wherein M is iridium (Ir), platinum (Pt), osmium (Os), titanium (Ti), zirconium (Zr), hafnium (Hf), europium (Eu), terbium (Tb), thulium (Tm), rhodium (Rh), palladium (Pd), or gold (Au).

11. The organometallic compound of claim 9, wherein ring CY₁₁, ring CY₁₂, ring CY₃, and ring CY₄ are each independently:
a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzotriazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group.

12. The organometallic compound of claim 9, wherein the organometallic compound is represented by one of Formulae 1-1 to 1-3: 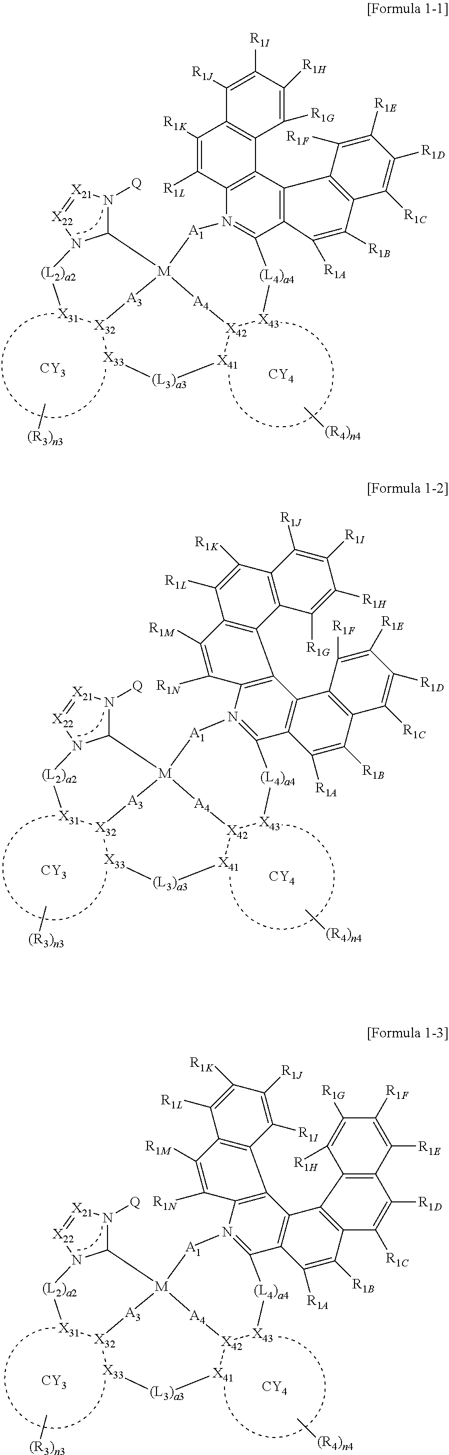
wherein in Formulae 1-1 to 1-3,
M, ring CY₃, ring CY₄, A₁, A₃, A₄, L₂, L₃, L₄, a2, a3, a4, X₂₁, X₂₂, X₃₁, X₃₂, X₃₃, X₄₁, X₄₂, X₄₃, Q, R₃, R₄, n3, and n4 are each as defined in Formula 1, and
R_{1A} to R_{1N} are each independently the same as defined in connection with R₁ in Formula 1.

13. The organometallic compound of claim 9, wherein the organometallic compound is represented by Formula 2: 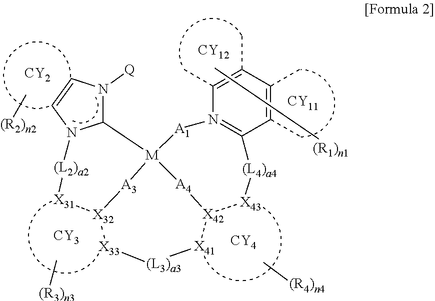
wherein in Formula 2,
M, ring CY₁₁, ring CY₁₂, ring CY₃, ring CY₄, A₁, A₃, A₄, L₂, L₃, L₄, a2, a3, a4, X₃₁, X₃₂, X₃₃, X₄₁, X₄₂, X₄₃, Q, R₁, R₃, R₄, n1, n3, and n4 are each as defined in Formula 1,
ring CY₂ is a C₆-C₃₀ aromatic ring or a C₁-C₃₀ heteroaromatic ring,
R₂ is the same as defined in connection with R₂ in Formula 1, and
n2 is an integer from 0 to 10.

14. The organometallic compound of claim 9, wherein the organometallic compound is represented by Formula 2-1: 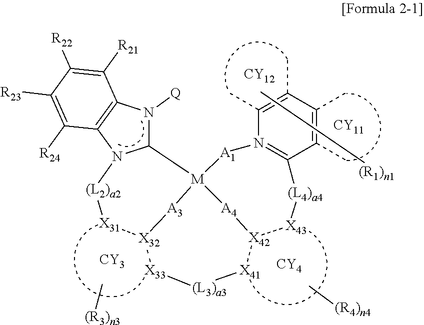
wherein in Formula 2-1,
M, ring CY₁₁, ring CY₁₂, ring CY₃, ring CY₄, A₁, A₃, A₄, L₂, L₃, L₄, a2, a3, a4, X₃₁, X₃₂, X₃₃, X₄₁, X₄₂, X₄₃, Q, R₁, R₃, R₄, n1, n3, and n4 are each as defined in Formula 1, and
R₂₁ to R₂₄ are each independently the same as defined in connection with R₂ in Formula 1.

15. The organometallic compound of claim 9, wherein
Q is a moiety represented by 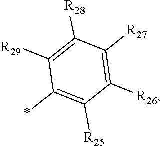
R₂₅ to R₂₉ are each independently the same as defined in connection with R₂ in Formula 1, and
* indicates a binding site to a nitrogen atom.

16. The organometallic compound of claim 15, wherein R₂₅ to R₂₉ are each independently hydrogen, deuterium, a C₁-C₂₀ alkyl group unsubstituted or substituted with at least one R₁₀ₐ, or a C₁-C₂₀ aryl group unsubstituted or substituted with at least one R₁₀ₐ.

17. The organometallic compound of claim 9, wherein
ring CY₃ is a moiety represented by 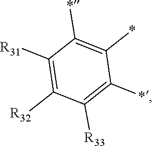
R₃₁, R₃₂, and R₃₃ are each independently the same as defined in connection with R₃ in Formula 1, and
* indicates a binding site to A₃,
*′ indicates a binding site to L₃, and
*″ indicates a binding site to L₂.

18. The organometallic compound of claim 9, wherein
ring CY₄ is a moiety represented by 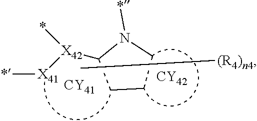
R₄, n4, X₄₁, and X₄₂ are each as defined in Formula 1,
ring CY₄₁ and ring CY₄₂ are each independently a C₆-C₃₀ aromatic ring or a C₁-C₆₀ heteroaromatic ring,
* indicates a binding site to A₄,
*′ indicates a binding site to L₃, and
*″ indicates a binding site to L₄.

19. The organometallic compound of claim 9, wherein
ring CY₄ is a moiety represented by 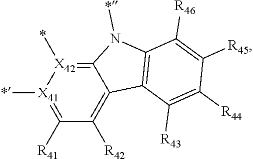
X₄₁ and X₄₂ are each as defined in Formula 1,
R₄₁ to R₄₆ are each independently the same as defined in connection with R₄ in Formula 1,
* indicates a binding site to A₄,
*′ indicates a binding site to L₃, and
*″ indicates a binding site to L₄.

20. The organometallic compound of claim 9, wherein the organometallic compound is one of Compounds 1 to 47: 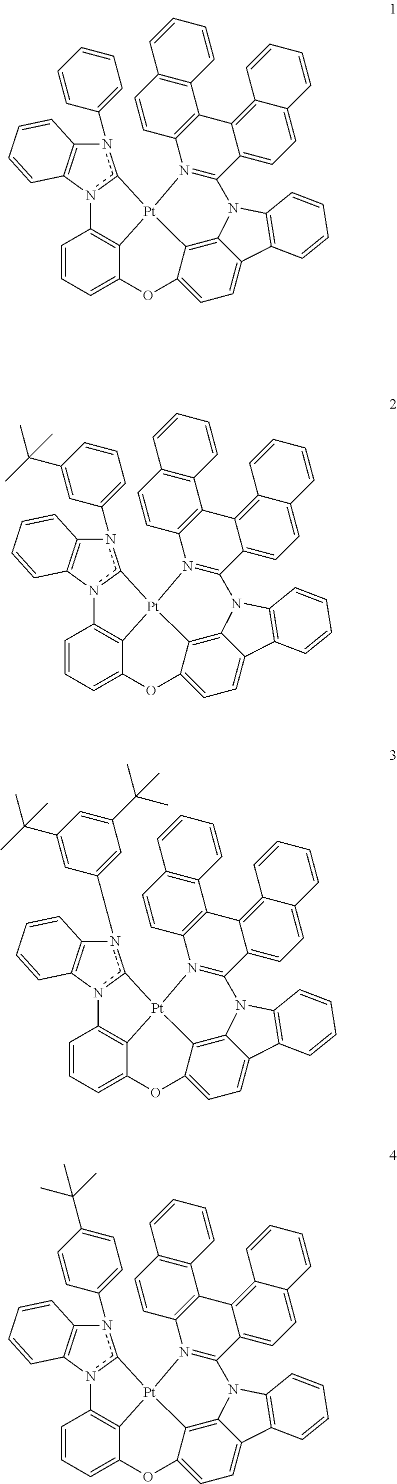 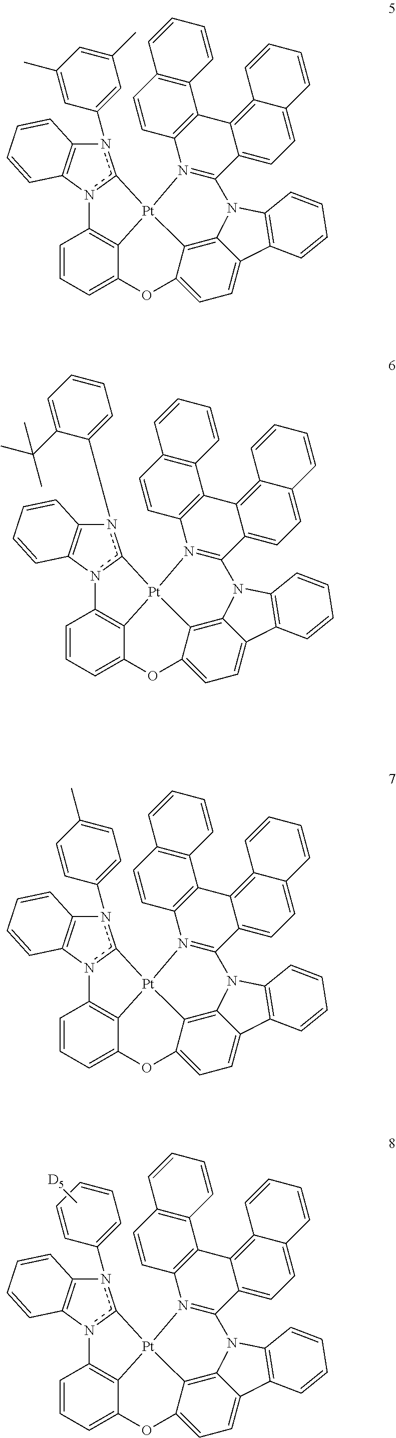 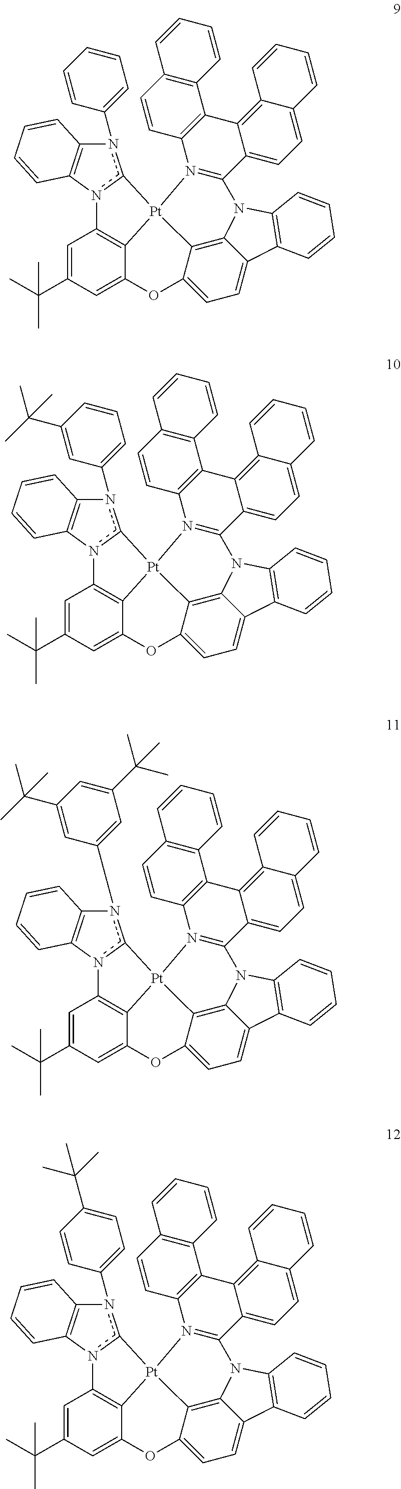 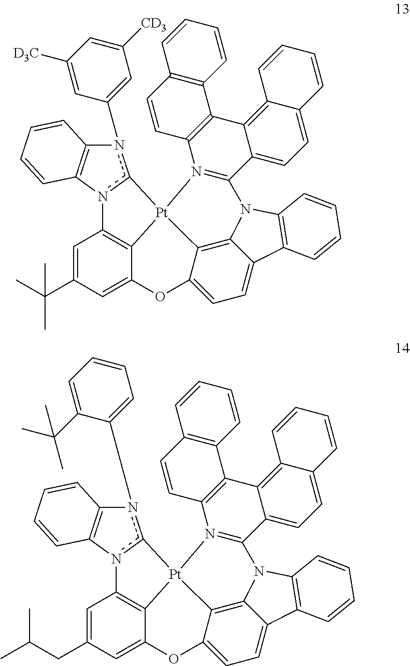 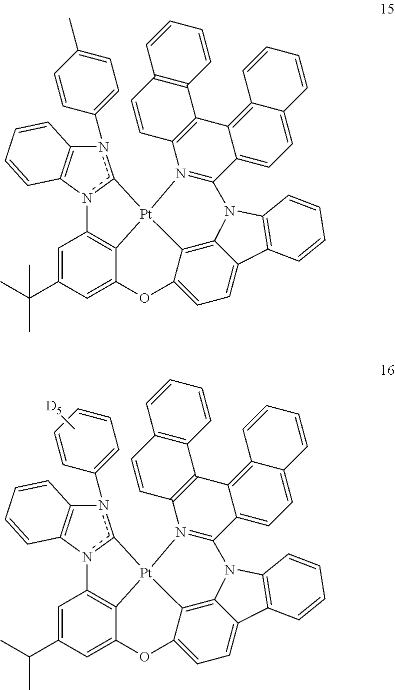 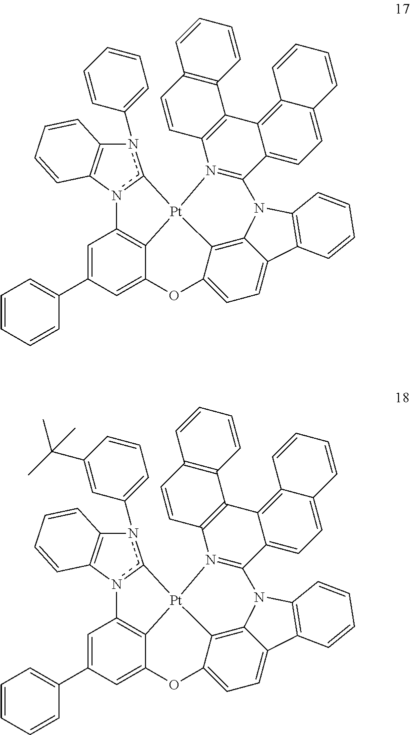 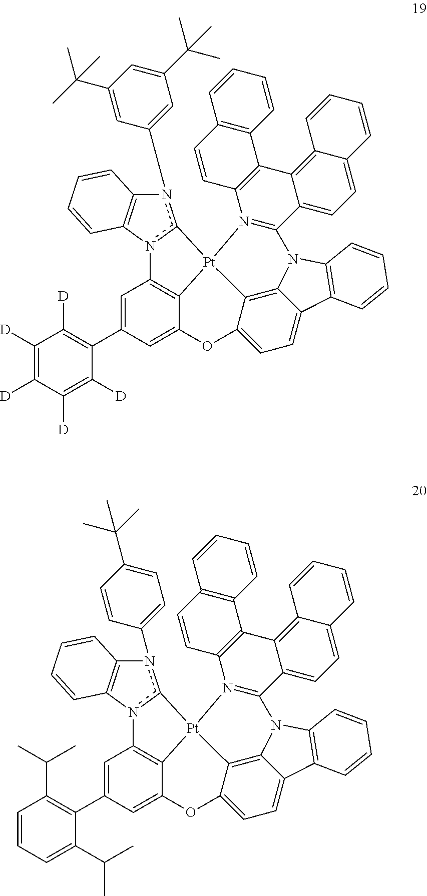 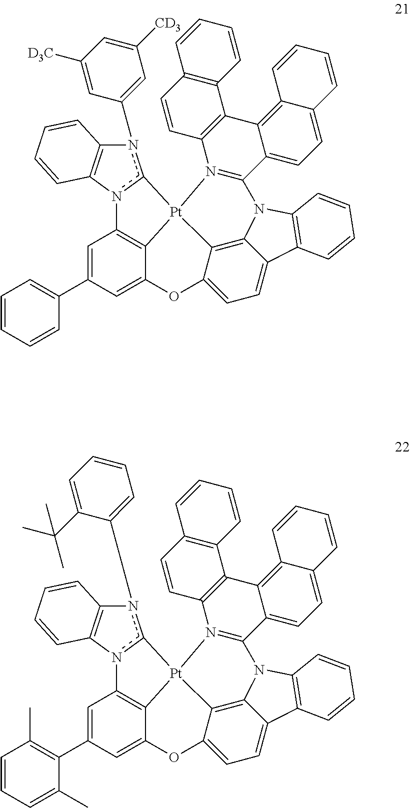 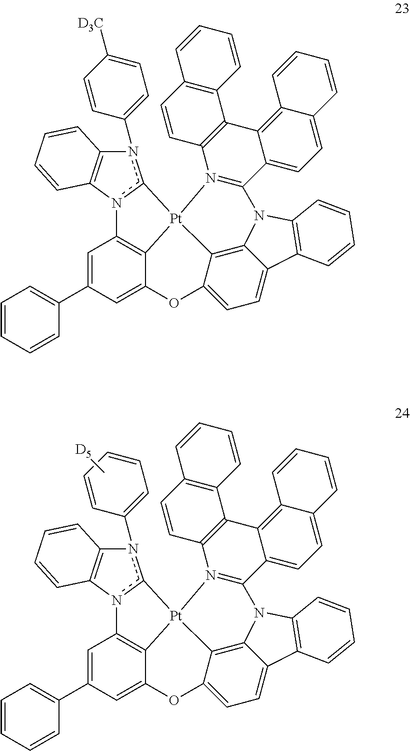 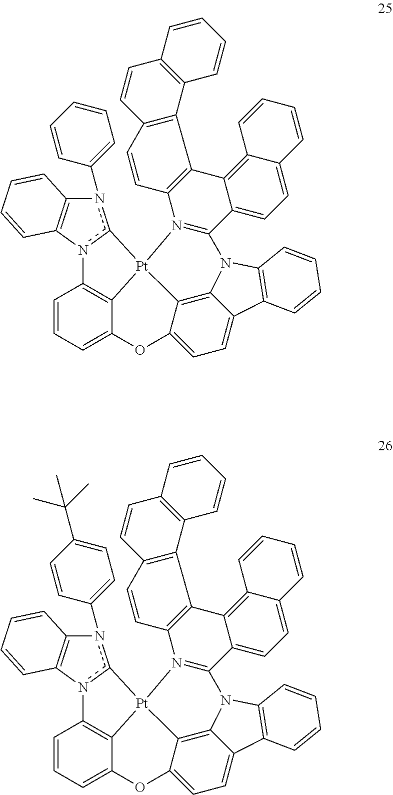 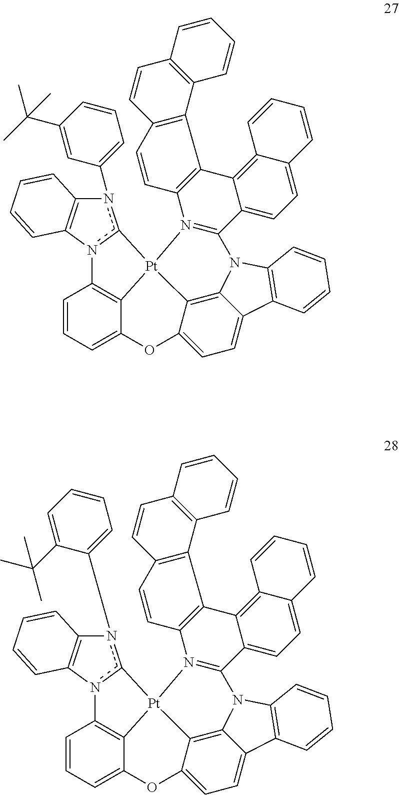 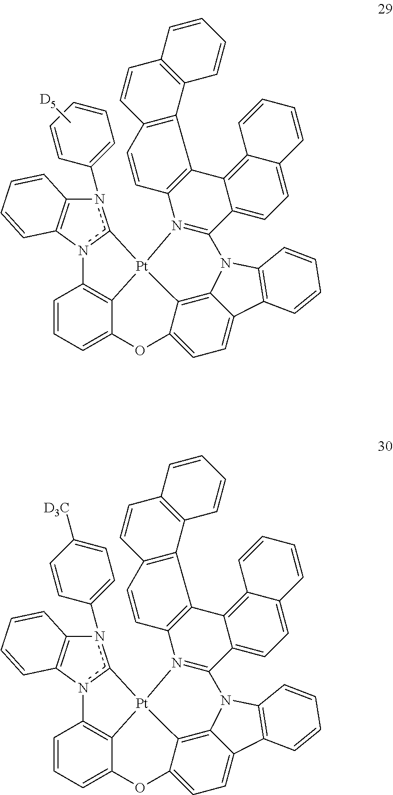 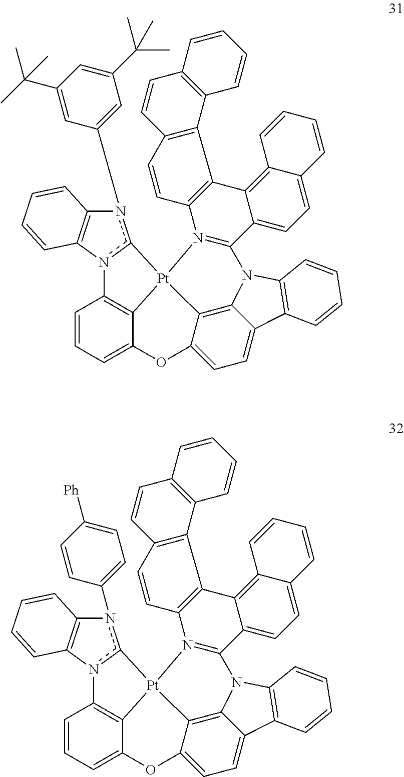 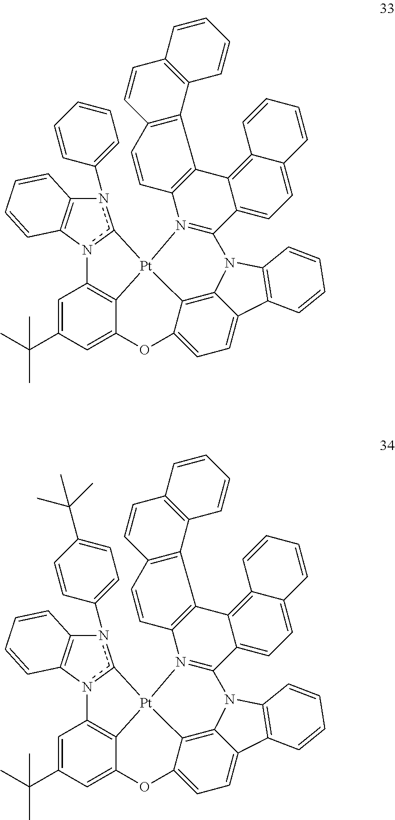 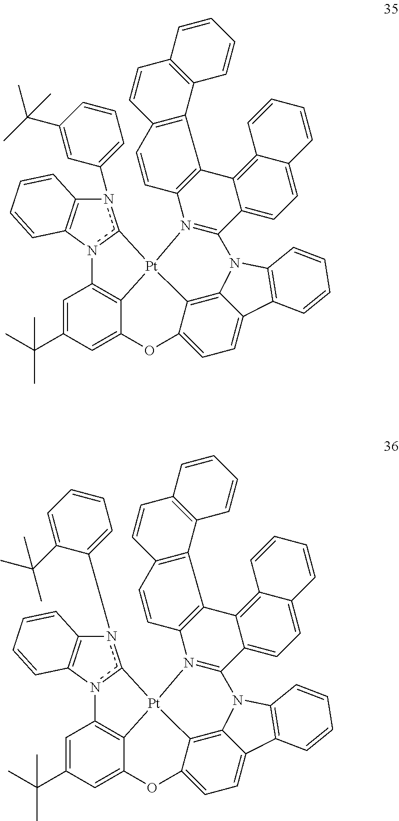 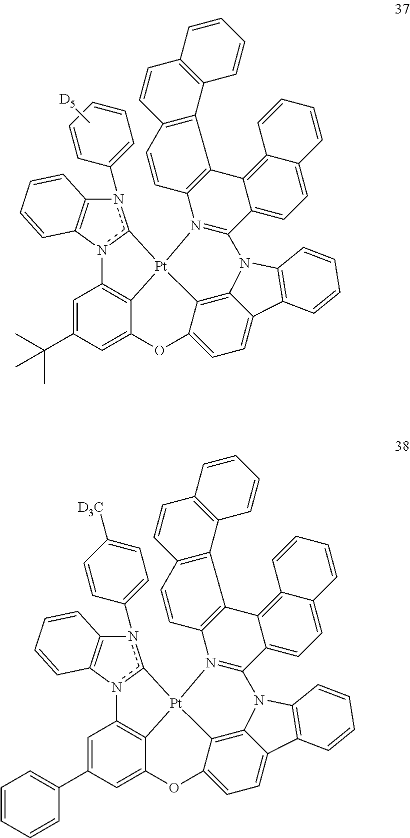 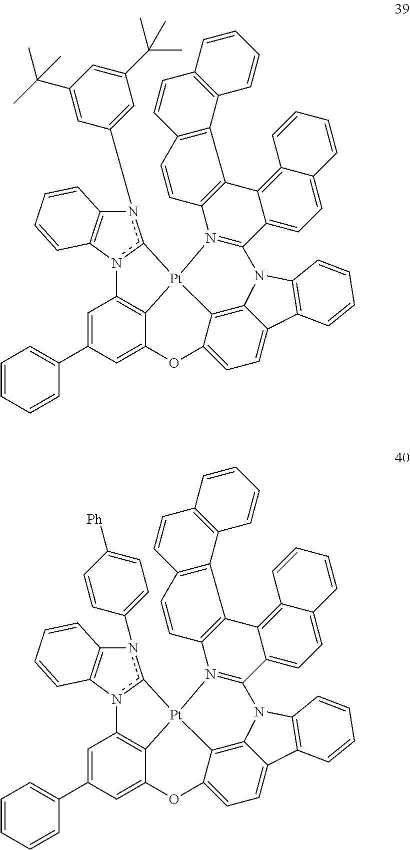 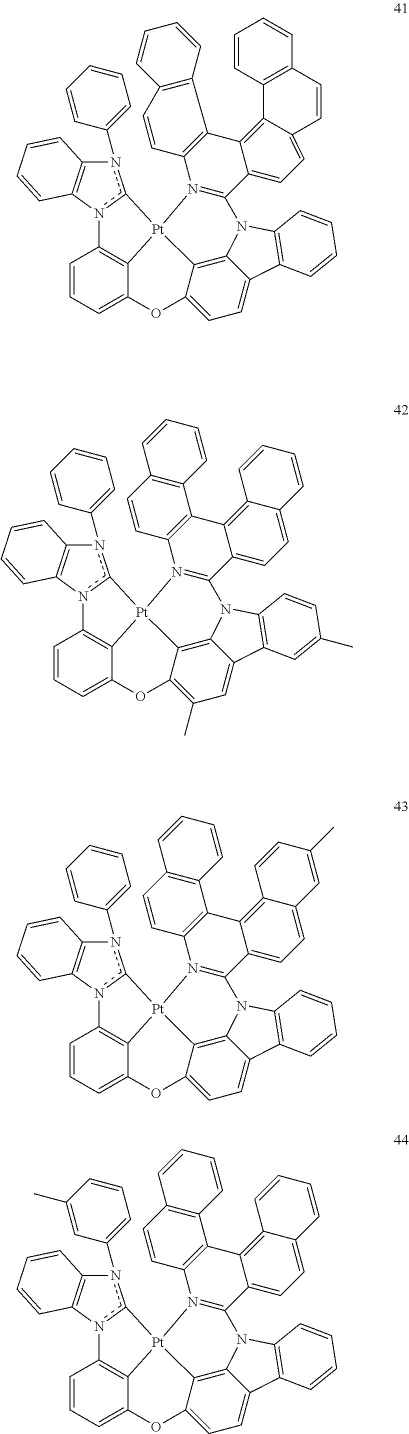 [chemical structure]
